(19) United States
(12) Patent Application Publication
(10) Pub. No.: US 2025/0372034 A1
(43) Pub. Date: Dec. 4, 2025

(54) PIXEL CIRCUIT, DRIVING METHOD, DISPLAY SUBSTRATE, AND DISPLAY DEVICE

(71) Applicants: Chongqing BOE Display Technology Co., Ltd., Chongqing (CN); BOE Technology Group Co., Ltd., Beijing (CN)

(72) Inventors: Rui WANG, Beijing (CN); Chao ZENG, Beijing (CN); Ming HU, Beijing (CN); Haijun QIU, Beijing (CN)

(21) Appl. No.: 18/869,474

(22) PCT Filed: Mar. 7, 2024
(86) PCT No.: PCT/CN2024/080601

§ 371 Date: Nov. 26, 2024

(51) Int. Cl. G09G 3/3233

(52) U.S. Cl. CPC G09G 3/3233; G09G 2300/0426; G09G 2300/0465; G09G 2300/0819; G09G 2300/0852; G09G 2300/0861; G09G 2310/08

(57) ABSTRACT

A pixel circuit, a driving method, a display substrate and a display device are provided. The pixel circuit includes: a first sub-pixel driving circuit configured to drive a first sub-pixel and including a first light emitting sub-element; a second sub-pixel driving circuit configured to drive a second sub-pixel and including a second light emitting sub-element, and the second sub-pixel is adjacent to the first sub-pixel in a first direction or a second direction; and a first data signal line configured to provide a data signal to the first sub-pixel driving circuit and the second sub-pixel driving circuit, where the data signal includes a first data sub-signal generated by the first data signal line in a third time period and a second data sub-signal generated by the first data signal line in a fourth time period, and the third time period does not overlap with the fourth time period.

### CROSS-REFERENCE TO RELATED APPLICATION(S)

This application is a Section 371 National Stage Application of International Application No. PCT/CN2024/080601, filed on Mar. 7, 2024, entitled “PIXEL CIRCUIT, DRIVING METHOD, DISPLAY SUBSTRATE, AND DISPLAY DEVICE”, the content of which is incorporated herein by reference in its entirety.

### TECHNICAL FIELD

The present disclosure relates to a field of display technology, and in particular to a pixel circuit, a driving method, a display substrate and a display device.

### BACKGROUND

With a development of display technology, a full display may provide an ultimate visual experience, hence a market demand for display products with extremely narrow bezels and low costs is gradually increasing. A display product with a high pixel density may have a large number of wires and via holes, which results in a large wire density and requires a high device stability. A common display product has numerous data signal lines, which require a large number of IC channels and lead to high IC costs.

How to optimize a pixel circuit of a display product, reduce the number of wires and lower costs is one of important research topics for R&D personnel.

The above information disclosed in this section is merely for understanding of the background of the technical concept of the present disclosure. Therefore, the above information may contain information that does not constitute a related art.

### SUMMARY

In an aspect, a pixel circuit is provided, including: a first sub-pixel driving circuit configured to drive a first sub-pixel, where the first sub-pixel includes a first light emitting sub-element; a second sub-pixel driving circuit configured to drive a second sub-pixel, where the second sub-pixel includes a second light emitting sub-element, and the second sub-pixel is adjacent to the first sub-pixel in a first direction or a second direction intersecting with the first direction; and a first data signal line configured to provide a data signal to the first sub-pixel driving circuit and the second sub-pixel driving circuit, where the data signal includes a first data sub-signal generated by the first data signal line in a third time period and a second data sub-signal generated by the first data signal line in a fourth time period, and the third time period does not overlap with the fourth time period.

According to some exemplary embodiments, the pixel circuit includes a data writing sub-circuit, the data writing sub-circuit is coupled to a data signal terminal, a first scanning signal terminal and a second node, the data signal terminal is coupled to the first data signal line, and the data writing sub-circuit is configured to write a data signal received at the data signal terminal to the second node in response to a first scanning signal received at the first scanning signal terminal; and the first sub-pixel driving circuit and the second sub-pixel driving circuit are coupled to the second node, and the data writing sub-circuit is configured to write the first data sub-signal to the first pixel driving sub-circuit through the second node and write the second data sub-signal to the second sub-pixel driving circuit through the second node.

According to some exemplary embodiments, the first sub-pixel driving circuit includes: a first driving sub-circuit, where the first driving sub-circuit is coupled to a first sub-node of first node, the second node and a first sub-node of third node, the first driving sub-circuit is configured to generate a first driving current in response to a voltage of the first sub-node of first node, and the first driving current is configured to drive the first light emitting sub-element to emit light; and a first compensation sub-circuit, where the first compensation sub-circuit is coupled to a second scanning signal terminal, the first sub-node of first node and the first sub-node of third node, and the first compensation sub-circuit is configured to transmit the first data sub-signal from the data signal terminal to the first sub-node of first node in response to a second scanning signal received at the second scanning signal terminal.

According to some exemplary embodiments, the second sub-pixel driving circuit includes: a second driving sub-circuit, where the second driving sub-circuit is coupled to a second sub-node of first node, the second node and a second sub-node of third node, the second driving sub-circuit is configured to generate a second driving current in response to a voltage of the second sub-node of first node, and the second driving current is configured to drive the second light emitting sub-element to emit light; and a second compensation sub-circuit, where the second compensation sub-circuit is coupled to a third scanning signal terminal, the second sub-node of first node and the second sub-node of third node, and the second compensation sub-circuit is configured to transmit the second data sub-signal from the data signal terminal to the second sub-node of first node in response to a third scanning signal received at the third scanning signal terminal.

According to some exemplary embodiments, the data writing sub-circuit, the first driving sub-circuit and the second driving sub-circuit are coupled to the second node.

According to some exemplary embodiments, the first sub-pixel driving circuit further includes: a first light-emission control sub-circuit, where the first light-emission control sub-circuit is coupled to a first voltage terminal, a light-emission control terminal and the second node, and the first light-emission control sub-circuit is configured to write a first voltage received at the first voltage terminal to the second node in response to a light-emission control signal received at the light-emission control terminal; and a first storage sub-circuit, where the first storage sub-circuit is coupled to the first sub-node of first node and the first voltage terminal; and the second sub-pixel driving circuit further includes: a third light-emission control sub-circuit, where the third light-emission control sub-circuit is coupled to a second voltage terminal, a light-emission control terminal and the second node, and the third light-emission control sub-circuit is configured to write a second voltage received at the second voltage terminal to the second node in response to a light-emission control signal received at the light-emission control terminal; and a second storage sub-circuit, where the second storage sub-circuit is coupled to the second sub-node of first node and the second voltage terminal.

According to some exemplary embodiments, the pixel circuit includes: a first light-emission control sub-circuit, where the first light-emission control sub-circuit is coupled to a first voltage terminal, a light-emission control terminal and the second node, and the first light-emission control sub-circuit is configured to write a first voltage received at the first voltage terminal to the first sub-pixel driving circuit and the second sub-pixel driving circuit respectively through the second node in response to a light-emission control signal received at the light-emission control terminal; a first storage sub-circuit, where the first storage sub-circuit is coupled to the first sub-node of first node and the first voltage terminal, and the first storage sub-circuit is configured to store a storage voltage in the first sub-pixel driving circuit; and a second storage sub-circuit, where the second storage sub-circuit is coupled to the second sub-node of first node and the first voltage terminal, and the second storage sub-circuit is configured to store a storage voltage in the second sub-pixel driving circuit.

According to some exemplary embodiments, the first sub-pixel driving circuit further includes: a first initialization sub-circuit, where the first initialization sub-circuit is coupled to a first reset signal terminal, a first initialization signal terminal and the first sub-node of first node, and the first initialization sub-circuit is configured to transmit a first initialization signal received at the first initialization signal terminal to the first sub-node of first node to initialize a potential of the first sub-node of first node in response to a first reset signal received at the first reset signal terminal; a second initialization sub-circuit, where the second initialization sub-circuit is coupled to a second reset signal terminal, a second initialization signal terminal, and a first electrode of the first light emitting sub-element, and the second initialization sub-circuit is configured to transmit a second initialization signal received at the second initialization signal terminal to the first electrode of the first light emitting sub-element to initialize a potential of the first electrode of the first light emitting sub-element in response to a second reset signal received at the second reset signal terminal; and a second light-emission control sub-circuit, where the second light-emission control sub-circuit is coupled to the first sub-node of third node, a light-emission control terminal, and the first electrode of the first light emitting sub-element, and the second light-emission control sub-circuit is configured to output the first driving current transmitted to the first sub-node of third node to the first light emitting sub-element in response to a light-emission control signal received at the light-emission control terminal.

According to some exemplary embodiments, the second sub-pixel driving circuit further includes: a third initialization sub-circuit, where the third initialization sub-circuit is coupled to a first reset signal terminal, a first initialization signal terminal, and the second sub-node of first node, and the third initialization sub-circuit is configured to transmit a first initialization signal received at the first initialization signal terminal to the second sub-node of first node to initialize a potential of the second sub-node of first node in response to a first reset signal received at the first reset signal terminal; a fourth initialization sub-circuit, where the fourth initialization sub-circuit is coupled to a second reset signal terminal, a second initialization signal terminal, and a first electrode of the second light emitting sub-element, and the fourth initialization sub-circuit is configured to transmit a second initialization signal received at the second initialization signal terminal to the first electrode of the second light emitting sub-element to initialize a potential of the first electrode of the second light emitting sub-element in response to a second reset signal received at the second reset signal terminal; and a fourth light-emission control sub-circuit, where the fourth light-emission control sub-circuit is coupled to the second sub-node of third node, a light-emission control terminal, and the first electrode of the second light emitting element, and the fourth light-emission control sub-circuit is configured to output the second driving current transmitted to the second sub-node of third node to the second light emitting sub-element in response to a light-emission control signal received at the light-emission control terminal.

According to some exemplary embodiments, the data writing sub-circuit includes a data writing transistor, and the data writing transistor has a control electrode coupled to the first scanning signal terminal, a first electrode coupled to the second node, and a second electrode coupled to the data signal terminal; the first light-emission control sub-circuit includes a first light-emission control transistor, and the first light-emission control transistor has a control electrode coupled to the light-emission control terminal, a first electrode coupled to the first voltage terminal, and a second electrode coupled to the second node; and the third light-emission control sub-circuit includes a third light-emission control transistor, and the third light-emission control transistor has a control electrode coupled to the light-emission control terminal, a first electrode coupled to the second voltage terminal, and a second electrode coupled to the second node.

According to some exemplary embodiments, the data writing sub-circuit includes a data writing transistor, and the data writing transistor has a control electrode coupled to the first scanning signal terminal, a first electrode coupled to the second node, and a second electrode coupled to the data signal terminal; and the first light-emission control sub-circuit includes a light-emission control transistor, and the light-emission control transistor has a control electrode coupled to the light-emission control terminal, a first electrode coupled to the first voltage terminal, and a second electrode coupled to the second node.

According to some exemplary embodiments, the pixel circuit includes: a first light-emission control sub-circuit, where the first light-emission control sub-circuit is coupled to a first voltage terminal, a light-emission control terminal and the second node, the first light-emission control sub-circuit is configured to write a first voltage received at the first voltage terminal to the second node in response to a light-emission control signal received at the light-emission control terminal, where the first sub-pixel driving circuit and the second sub-pixel driving circuit are coupled at the second node, and the first light-emission control sub-circuit is configured to write the first voltage to the first sub-pixel driving circuit and the second sub-pixel driving circuit respectively through the second node; and a first initialization sub-circuit, where the first initialization sub-circuit is coupled to a first reset signal terminal, a first initialization signal terminal and the second node, and the first initialization sub-circuit is configured to transmit a first initialization signal received at the first initialization signal terminal to the second node to initialize a potential of the second node in response to a first reset signal received at the first reset signal terminal.

According to some exemplary embodiments, the first sub-pixel driving circuit further includes: a first data writing sub-circuit, where the first data writing sub-circuit is coupled to a data signal terminal, a first scanning signal terminal and a first sub-node of third node, and the first data writing sub-circuit is configured to write a data signal received at the data signal terminal to the first sub-node of third node in response to a first scanning signal received at the first scanning signal terminal; and the second sub-pixel driving circuit further includes: a second data writing sub-circuit, where the second data writing sub-circuit is coupled to a data signal terminal, a first scanning signal terminal and a second sub-node of third node, the second data writing sub-circuit is configured to write a data signal received at the data signal terminal to the second sub-node of third node in response to a first scanning signal received at the first scanning signal terminal, and the data signal terminal coupled to the first data writing sub-circuit is coupled to the same data signal line as the data signal terminal coupled to the second data writing sub-circuit.

According to some exemplary embodiments, the first sub-pixel driving circuit includes: a first storage sub-circuit, where the first storage sub-circuit is coupled to the first sub-node of first node and a first voltage terminal; a first compensation sub-circuit, where the first compensation sub-circuit is coupled to a second scanning signal terminal, the first sub-node of first node, and the second node, and the first compensation sub-circuit is configured to transmit the first data sub-signal from the data signal terminal to the first sub-node of first node in response to a second scanning signal received at the second scanning signal terminal; and a first driving sub-circuit, where the first driving sub-circuit is coupled to a first sub-node of first node, the second node, and a first sub-node of third node, the first driving sub-circuit is configured to generate a first driving current in response to a voltage of the first sub-node of first node, and the first driving current is configured to drive the first light emitting sub-element to emit light; and the second sub-pixel driving circuit includes: a second storage sub-circuit, where the second storage sub-circuit is coupled to the second sub-node of first node and a first voltage terminal, and the first storage sub-circuit and the second storage sub-circuit are coupled at the first voltage terminal; a second compensation sub-circuit, where the second compensation sub-circuit is coupled to a third scanning signal terminal, the second sub-node of first node, and the second node, and the second compensation sub-circuit is configured to transmit the second data sub-signal from the data signal terminal to the second sub-node of first node in response to a third scanning signal received at the third scanning signal terminal; and a second driving sub-circuit, where the second driving sub-circuit is coupled to a second sub-node of first node, the second node, and a second sub-node of third node, the second driving sub-circuit is configured to generate a second driving current in response to a voltage of the second sub-node of first node, and the second driving current is configured to drive the second light emitting sub-element to emit light.

According to some exemplary embodiments, the first light-emission control sub-circuit includes a light-emission control transistor, and the light-emission control transistor has a control electrode coupled to the light-emission control terminal, a first electrode coupled to the first voltage terminal, and a second electrode coupled to the second node; the first initialization sub-circuit includes an initialization transistor, and the initialization transistor has a control electrode coupled to a first reset signal terminal, a first electrode coupled to the second node, and a second electrode coupled to the first initialization signal terminal; and the first data writing sub-circuit includes a first data writing transistor, the second data writing sub-circuit includes a second data writing transistor, the first data writing transistor has a control electrode coupled to the first scanning signal terminal, a first electrode coupled to the first sub-node of third node, and a second electrode coupled to a first electrode of the second data writing transistor, and the second data writing transistor has a control electrode coupled to the first scanning signal terminal and a second electrode coupled to the second sub-node of third node.

According to some exemplary embodiments, the pixel circuit includes: a first light-emission control sub-circuit, where the first light-emission control sub-circuit is coupled to a first voltage terminal, a light-emission control terminal and the second node, the first light-emission control sub-circuit is configured to write a first voltage received at the first voltage terminal to the second node in response to a light-emission control signal received at the light-emission control terminal, where the first sub-pixel driving circuit and the second sub-pixel driving circuit are electrically connected at the second node, and the first light-emission control sub-circuit is configured to write the first voltage to the first sub-pixel driving circuit through the second node and write the first voltage to the second sub-pixel driving circuit through the second node; and a second reference voltage writing sub-circuit, where the second reference voltage writing sub-circuit is coupled to a second reset signal terminal, a second reference voltage terminal and the second node, and the second reference voltage writing sub-circuit is configured to write a second reference voltage received at the second reference voltage terminal to the second node in response to a second reset signal received at the second reset signal terminal; the first sub-pixel driving circuit further includes: a first data writing sub-circuit, where the first data writing sub-circuit is coupled to a data signal terminal, a second scanning signal terminal and a first sub-node of fourth node, and the first data writing sub-circuit is configured to write a data signal received at the data signal terminal to the first sub-node of fourth node in response to a second scanning signal received at the second scanning signal terminal; a first storage sub-circuit, where the first storage sub-circuit is coupled to the first sub-node of first node and the first sub-node of fourth node; and a third storage sub-circuit, where the third storage sub-circuit is coupled to the first sub-node of fourth node and the first voltage terminal; the second sub-pixel driving circuit further includes: a second data writing sub-circuit, where the second data writing sub-circuit is coupled to a data signal terminal, a third scanning signal terminal and a second sub-node of third node, the second data writing sub-circuit is configured to write a data signal received at the data signal terminal to the second sub-node of third node in response to a third scanning signal received at the third scanning signal terminal, and the first data writing sub-circuit and the second data writing sub-circuit share a data wire; a second storage sub-circuit, where the second storage sub-circuit is coupled to the second sub-node of first node and the second sub-node of fourth node; and a fourth storage sub-circuit, where the fourth storage sub-circuit is coupled to the second sub-node of fourth node and the first voltage terminal; and the pixel driving circuit further includes: a first first-reference voltage writing sub-circuit, where the first first-reference voltage writing sub-circuit is coupled to the first sub-node of fourth node, the second reset signal terminal and a first reference voltage signal terminal, and the first first-reference voltage writing sub-circuit is configured to write a first reference voltage received at the first reference voltage signal terminal to the first sub-node of fourth node in response to a second reset signal received at the second reset signal terminal; and a second first-reference voltage writing sub-circuit, where the second first-reference voltage writing sub-circuit is coupled to the second sub-node of fourth node, the second reset signal terminal and the first reference voltage signal terminal, and the second first-reference voltage writing sub-circuit is configured to write a first reference voltage received at the first reference voltage signal terminal to the second sub-node of fourth node in response to a second reset signal received at the second reset signal terminal.

In another aspect, a pixel driving method applied to the pixel circuit described above is provided, where the pixel driving method includes: in a third time period, turning on a data writing sub-circuit and a first compensation sub-circuit in response to a first scanning signal and a second scanning signal, so that a first data sub-signal from a data signal terminal is transmitted to a first sub-node of first node; and in a fourth time period, turning on the data writing sub-circuit and a second compensation sub-circuit in response to the first scanning signal and a third scanning signal, so that a second data sub-signal from the data signal terminal is transmitted to a second sub-node of first node, where the third time period and the fourth time period are in a writing stage of an image frame, the fourth time period is after the third time period, and the fourth time period does not overlap with the third time period.

According to some exemplary embodiments, the pixel driving method further includes: in a first time period, allowing a first sub-pixel and a second sub-pixel to stop emitting light, and starting to reset a first sub-pixel driving circuit and a second sub-pixel driving circuit, in response to a light-emission control signal of a light-emission control terminal; and in a second time period, turning on a first initialization sub-circuit and a third initialization sub-circuit in response to a first reset signal at the first reset signal terminal, so that a first initialization signal from the first initialization signal terminal is transmitted to a first sub-node of first node and a second sub-node of first node respectively, where the first time period and the second time period are in a reset stage of an image frame, the first time period is before the second time period, the second time period is between the first time period and the third time period, and the first time period, the second time period and the third time period do not overlap with each other.

According to some exemplary embodiments, the pixel driving method further includes: in a first sub-stage of first time period, turning on a first initialization sub-circuit and a first compensation sub-circuit in response to a first reset signal and the second scanning signal, so that a first initialization signal from a first initialization signal terminal is output to the first sub-node of first node; in a second sub-stage of first time period, turning on a third initialization sub-circuit and a second compensation sub-circuit in response to the first reset signal and the third scanning signal, so that the first initialization signal from the first initialization signal terminal is output to the second sub-node of first node, where the first sub-stage of first time period and the second sub-stage of first time period are in a reset stage of an image frame, the first sub-stage of first time period is before the second sub-stage of first time period, and the first sub-stage of first time period does not overlap with the second sub-stage of first time period.

In another aspect, a display substrate is provided, including: a base substrate; the pixel circuit described above on the base substrate, where the pixel circuit includes a first sub-pixel driving circuit and a second sub-pixel driving circuit; and a light emitting element on the base substrate, where the light emitting element includes a first light emitting sub-element coupled to the first sub-pixel driving circuit and a second light emitting sub-element coupled to the second sub-pixel driving circuit.

In another aspect, a display substrate is provided, including: a base substrate; a plurality of sub-pixels on the base substrate, where the plurality of sub-pixels are arranged in an array in a first direction and a second direction intersecting with the first direction, the plurality of sub-pixels include a first sub-pixel and a second sub-pixel, and the first sub-pixel is adjacent to the second sub-pixel in the first direction or the second direction; and a plurality of pixel circuits configured to drive the plurality of sub-pixels, where the plurality of pixel circuits include a first sub-pixel driving circuit configured to drive the first sub-pixel and a second sub-pixel driving circuit configured to drive the second sub-pixel; where the display substrate includes a first semiconductor layer on the base substrate, a first conductive layer on a side of the first semiconductor layer away from the base substrate, a third conductive layer on a side of the first conductive layer away from the base substrate, and a fourth conductive layer on a side of the third conductive layer away from the base substrate; the display substrate further includes a first scanning signal line extending in the first direction and a data signal line extending in the second direction, the first scanning signal line is located in the first conductive layer, and the data signal line is located in the fourth conductive layer; where the first sub-pixel driving circuit and the second sub-pixel driving circuit share a data writing sub-circuit and a data signal line, the data writing sub-circuit includes a data writing transistor, the data writing transistor includes a data writing active layer, a control electrode and a second electrode, the data writing active layer is located in the first semiconductor layer, and the second electrode is located in the third conductive layer; and where an orthographic projection of the data writing active layer on the base substrate overlaps at least partially with an orthographic projection of the first scanning signal line on the base substrate, a portion of the data writing active layer overlapping with the first scanning signal line is the control electrode of the data writing transistor, and the second electrode of the data writing transistor is electrically connected to the data signal line through a first via hole.

According to some exemplary embodiments, the first sub-pixel driving circuit and the second sub-pixel driving circuit share a first light-emission control sub-circuit, the first light-emission control sub-circuit includes a light-emission control transistor, the light-emission control transistor includes a light-emission control active layer, a control electrode and a first electrode, the light-emission control active layer is located in the first semiconductor layer, and the first electrode of the light-emission control transistor is located in the third conductive layer; the display substrate further includes a light-emission control line extending in the first direction, an orthographic projection of the light-emission control active layer on the base substrate overlaps at least partially with an orthographic projection of the light-emission control line on the base substrate, and a portion of the light-emission control active layer overlapping with the light-emission control line is the control electrode of the light-emission control transistor; and the display substrate further includes a first conductive transfer portion in the third conductive layer, the first electrode of the light-emission control transistor is electrically connected to a first power line through the first conductive transfer portion, the first power line includes a first power sub-line and a second power sub-line, the first power sub-line and the second power sub-line are spaced apart in the first direction and extend in the second direction, and the first conductive transfer portion is electrically connected to the first power sub-line through a second via hole and electrically connected to the second power sub-line through a third via hole.

According to some exemplary embodiments, the data writing active layer and the light-emission control active layer extend continuously in the second direction; each of an orthographic projection of the data writing active layer on the base substrate and an orthographic projection of the first light-emission control active layer on the base substrate overlaps at least partially with an orthographic projection of the data signal line on the base substrate; and the orthographic projection of the data signal line on the base substrate falls within a gap between an orthographic projection of the first power sub-line on the base substrate and an orthographic projection of the second power sub-line on the base substrate.

According to some exemplary embodiments, the first conductive transfer portion includes a first conductive transfer sub-portion extending in the second direction and a second conductive transfer sub-portion extending in the first direction, an orthographic projection of the first conductive transfer sub-portion on the base substrate overlaps at least partially with the orthographic projection of the light-emission control active layer on the base substrate, an orthographic projection of the second via hole on the base substrate falls within an orthographic projection of a first end of the second conductive transfer sub-portion on the base substrate, and an orthographic projection of the third via hole on the base substrate falls within an orthographic projection of a second end of the second conductive transfer sub-portion on the base substrate.

According to some exemplary embodiments, the data writing active layer extends in the second direction, the light-emission control active layer extends in the second direction, and the data writing active layer is spaced apart from the light-emission control active layer in the first direction; and an orthographic projection of the data writing active layer on the base substrate falls within an orthographic projection of the second power sub-line on the base substrate, and an orthographic projection of the light-emission control active layer on the base substrate falls within an orthographic projection of the first power sub-line on the base substrate.

According to some exemplary embodiments, the first sub-pixel driving circuit includes a first driving sub-circuit, the first driving sub-circuit includes a first driving transistor, and the first driving transistor includes a first driving active layer; the second sub-pixel driving circuit includes a second driving sub-circuit, the second driving sub-circuit includes a second driving transistor, and the second driving transistor includes a second driving active layer; and the first driving active layer and the second driving active layer extend in polygonal lines in the first direction respectively, and the first driving active layer and the second driving active layer are symmetrical with respect to the data signal line.

According to some exemplary embodiments, the first sub-pixel driving circuit includes a first driving sub-circuit, the first driving sub-circuit includes a first driving transistor, and the first driving transistor includes a first driving active layer; the second sub-pixel driving circuit includes a second driving sub-circuit, the second driving sub-circuit includes a second driving transistor, and the second driving transistor includes a second driving active layer; the first driving active layer extends in a straight line in the first direction, the second driving active layer extends in a straight line in the first direction, and the first driving active layer is spaced apart from the second driving active layer in the second direction; and the light-emission control active layer, the first driving active layer and the second driving active layer are electrically connected to each other.

According to some exemplary embodiments, the display substrate further includes a second conductive layer between the first conductive layer and the third conductive layer; the first sub-pixel driving circuit includes a first storage sub-circuit, the first storage sub-circuit includes a first capacitor, and the first capacitor includes a first plate and a second plate; the second sub-pixel driving circuit includes a second storage sub-circuit, the second storage sub-circuit includes a second capacitor, and the second capacitor includes a third plate and a fourth plate; and the first plate and the third plate are located in the first conductive layer and spaced apart in the first direction, and the second plate and the fourth plate are located in the second conductive layer and electrically connected to each other.

According to some exemplary embodiments, the display substrate further includes a second conductive layer between the first conductive layer and the third conductive layer; the first sub-pixel driving circuit includes a first storage sub-circuit, the first storage sub-circuit includes a first capacitor, and the first capacitor includes a first plate and a second plate; the second sub-pixel driving circuit includes a second storage sub-circuit, the second storage sub-circuit includes a second capacitor, and the second capacitor includes a third plate and a fourth plate; and the first plate and the third plate are located in the first conductive layer and spaced apart in the second direction and overlap at least partially with each other in the first direction, and the second plate and the fourth plate are located in the second conductive layer and electrically connected to each other.

According to some exemplary embodiments, the first conductive transfer portion includes a first conductive transfer sub-portion and a second conductive transfer sub-portion, a first end of the first conductive transfer sub-portion is electrically connected to the first power sub-line through a second via hole, a second end of the first conductive transfer sub-portion is electrically connected to the second plate through a sixth via hole, the second conductive transfer portion is electrically connected to the second power sub-line through a third via hole and electrically connected to the fourth plate through a seventh via hole, and any two of an orthographic projection of the second conductive transfer sub-portion on the base substrate, an orthographic projection of the fourth plate on the base substrate and an orthographic projection of the second power sub-line on the base substrate overlap at least partially with each other.

In another aspect, a display substrate is provided, including: a base substrate; a plurality of sub-pixels on the base substrate, where the plurality of sub-pixels are arranged in an array in a first direction and a second direction intersecting with the first direction, the plurality of sub-pixels include a first sub-pixel and a second sub-pixel, and the first sub-pixel is adjacent to the second sub-pixel in the first direction or the second direction; and a plurality of pixel circuits configured to drive the plurality of sub-pixels, where the plurality of pixel circuits include a first sub-pixel driving circuit configured to drive the first sub-pixel and a second sub-pixel driving circuit configured to drive the second sub-pixel; where the display substrate includes a first semiconductor layer on the base substrate, a first conductive layer on a side of the first semiconductor layer away from the base substrate, a third conductive layer on a side of the first conductive layer away from the base substrate, and a fourth conductive layer on a side of the third conductive layer away from the base substrate; where the display substrate further includes a first reset signal line extending in the first direction, a light-emission control line extending in the first direction, a data signal line extending in the second direction and a first power line extending in the second direction, the first reset signal line and the light-emission control line are located in the first conductive layer, and the data signal line and the first power line are located in the fourth conductive layer; where the first sub-pixel driving circuit and the second sub-pixel driving circuit share a first initialization sub-circuit and a first light-emission control sub-circuit, the first initialization sub-circuit includes an initialization transistor, the initialization transistor includes an initialization active layer extending in the second direction and a control electrode, an orthographic projection of the initialization active layer on the base substrate overlaps at least partially with an orthographic projection of the first reset signal line on the base substrate, and a portion of the initialization active layer overlapping with the first reset signal line is the control electrode of the initialization transistor; and where the first light-emission control sub-circuit includes a light-emission control transistor, the light-emission control transistor includes a light-emission control active layer extending in the second direction and a first electrode, an orthographic projection of the light-emission active layer on the base substrate falls within an orthographic projection of the first power line on the base substrate, and the first electrode of the light-emission control transistor is electrically connected to the first power line through a first conductive transfer portion.

According to some exemplary embodiments, the first sub-pixel driving circuit includes a first data writing sub-circuit, the first data writing sub-circuit includes a first data writing transistor, and the first data writing transistor includes a first data writing active layer and a second electrode; the second sub-pixel driving circuit includes a second data writing sub-circuit, the second data writing sub-circuit includes a second data writing transistor, and the second data writing transistor includes a second data writing active layer and a first electrode; the first data writing active layer includes a body portion extending in the second direction, the second data writing active layer includes a body portion extending in the second direction, and the first data writing active layer and the second data writing active layer share a lap portion extending in the first direction; and the second electrode of the first data writing transistor and the first electrode of the second data writing transistor are electrically connected to the data signal line through a fourth via hole.

According to some exemplary embodiments, the first sub-pixel driving circuit includes a first compensation sub-circuit, the first compensation sub-circuit includes a first compensation transistor, and the first compensation transistor includes a first compensation active layer; the second sub-pixel driving circuit includes a second compensation sub-circuit, the second compensation sub-circuit includes a second compensation transistor, and the second compensation transistor includes a second compensation active layer; and the first compensation active layer and the second compensation active layer extend in the first direction, and the first compensation active layer and the second compensation active layer are spaced apart in the first direction and the second direction.

According to some exemplary embodiments, the first sub-pixel driving circuit includes a first storage sub-circuit, the first storage sub-circuit includes a first capacitor, and the first capacitor includes a first plate and a second plate; the second sub-pixel driving circuit includes a second storage sub-circuit, the second storage sub-circuit includes a second capacitor, and the second capacitor includes a third plate and a fourth plate; and the first plate and the third plate are located in the first conductive layer and spaced apart in the second direction, and the second plate and the fourth plate are located in the second conductive layer and electrically connected to each other.

According to some exemplary embodiments, the first conductive transfer portion is electrically connected to the first power line through a fifth via hole and electrically connected to the fourth plate through an eighth via hole; and the display substrate further includes a third conductive transfer portion in the third conductive layer, the first compensation transistor includes a second electrode, the second compensation transistor includes a first electrode, and the second electrode of the first compensation transistor is electrically connected to the first electrode of the second compensation transistor through the third conductive transfer portion.

According to some exemplary embodiments, the first sub-pixel driving circuit includes a first driving sub-circuit, the first driving sub-circuit includes a first driving transistor, and the first driving transistor includes a first driving active layer; the second sub-pixel driving circuit includes a second driving sub-circuit, the second driving sub-circuit includes a second driving transistor, and the second driving transistor includes a second driving active layer; the first driving active layer extends in a straight line in the first direction, the second driving active layer extends in a straight line in the first direction, and the first driving active layer and the second driving active layer are spaced apart in the second direction; and the light-emission control active layer, the first driving active layer and the second driving active layer are electrically connected to each other.

In another aspect, a display device is provided, including the display substrate described above.

### BRIEF DESCRIPTION OF THE DRAWINGS

By describing in detail exemplary embodiments of the present disclosure with reference to the accompanying drawings, features and advantages of the present disclosure will become more apparent.

FIG. 1 shows a schematic plan view of a display device according to some embodiments of the present disclosure;

FIG. 2 shows a schematic structural diagram of sub-pixels according to some embodiments of the present disclosure;

FIG. 3 shows a structural block diagram of a pixel circuit according to some embodiments of the present disclosure;

FIG. 4A shows an equivalent circuit diagram of a pixel circuit according to some embodiments of the present disclosure;

FIG. 4B shows an equivalent circuit diagram of a pixel circuit according to some embodiments of the present disclosure;

FIG. 5 shows a working sequence diagram of at least one embodiment of a driving method for the pixel shown in FIG. 4A;

FIG. 6 shows a structural block diagram of a pixel circuit according to some embodiments of the present disclosure;

FIG. 7 shows an equivalent circuit diagram of a pixel circuit according to some embodiments of the present disclosure;

FIG. 8 shows a working sequence diagram of at least one embodiment of a driving method for the pixel shown in FIG. 7;

FIG. 9 shows a structural block diagram of a pixel circuit according to some embodiments of the present disclosure;

FIG. 10 shows an equivalent circuit diagram of a pixel circuit according to some embodiments of the present disclosure;

FIG. 11 shows a structural block diagram of a pixel circuit according to some embodiments of the present disclosure;

FIG. 12 shows an equivalent circuit diagram of a pixel circuit according to some embodiments of the present disclosure;

FIG. 13 shows a working sequence diagram of at least one embodiment of a driving method for the pixel shown in FIG. 12;

FIG. 14 shows a structural block diagram of a display substrate according to some embodiments of the present disclosure;

FIG. 15A shows a schematic diagram of a planar structure of a first semiconductor layer in a pixel circuit according to exemplary embodiments of the present disclosure; FIG. 15B shows a schematic diagram of a planar structure of a first conductive layer in a pixel circuit according to exemplary embodiments of the present disclosure; FIG. 15C shows a schematic diagram of a planar structure of a second conductive layer in a pixel circuit according to exemplary embodiments of the present disclosure; FIG. 15D shows a schematic diagram of some via holes according to exemplary embodiments of the present disclosure; FIG. 15E shows a schematic diagram of a planar structure of a third conductive layer in a pixel circuit according to exemplary embodiments of the present disclosure; FIG. 15F shows a schematic diagram of a planar structure of a fourth conductive layer in a pixel circuit according to exemplary embodiments of the present disclosure;

FIG. 16A shows a schematic diagram of a planar structure of a combination of the first semiconductor layer, the first conductive layer, the second conductive layer, the third conductive layer and the fourth conductive layer in a pixel circuit according to exemplary embodiments of the present disclosure; FIG. 16B shows a schematic partial cross-sectional view of the pixel circuit according to embodiments of the present disclosure, taken along line AA′ in FIG. 16A;

FIG. 17A shows a schematic diagram of a planar structure of a first semiconductor layer in a pixel circuit according to exemplary embodiments of the present disclosure; FIG. 17B shows a schematic diagram of a planar structure of a first conductive layer in a pixel circuit according to exemplary embodiments of the present disclosure; FIG. 17C shows a schematic diagram of a planar structure of a second conductive layer in a pixel circuit according to exemplary embodiments of the present disclosure; FIG. 17D shows a schematic diagram of some via holes according to exemplary embodiments of the present disclosure; FIG. 17E shows a schematic diagram of a planar structure of a third conductive layer in a pixel circuit according to exemplary embodiments of the present disclosure; FIG. 17F shows a schematic diagram of a planar structure of a fourth conductive layer in a pixel circuit according to exemplary embodiments of the present disclosure;

FIG. 18 shows a schematic diagram of a planar structure of a combination of the first semiconductor layer, the first conductive layer, the second conductive layer, the third conductive layer and the fourth conductive layer in a pixel circuit according to exemplary embodiments of the present disclosure;

FIG. 19A shows a schematic diagram of a planar structure of a first semiconductor layer in a pixel circuit according to exemplary embodiments of the present disclosure; FIG. 19B shows a schematic diagram of a planar structure of a first conductive layer in a pixel circuit according to exemplary embodiments of the present disclosure; FIG. 19C shows a schematic diagram of a planar structure of a second conductive layer in a pixel circuit according to exemplary embodiments of the present disclosure; FIG. 19D shows a schematic diagram of some via holes according to exemplary embodiments of the present disclosure; FIG. 19E shows a schematic diagram of a planar structure of a third conductive layer in a pixel circuit according to exemplary embodiments of the present disclosure; FIG. 19F shows a schematic diagram of a planar structure of a fourth conductive layer in a pixel circuit according to exemplary embodiments of the present disclosure;

FIG. 20 shows a schematic diagram of a planar structure of a combination of the first semiconductor layer, the first conductive layer, the second conductive layer, the third conductive layer and the fourth conductive layer in a pixel circuit according to exemplary embodiments of the present disclosure;

FIG. 21A shows a schematic diagram of a planar structure of a first semiconductor layer in a pixel circuit according to exemplary embodiments of the present disclosure; FIG. 21B shows a schematic diagram of a planar structure of a first conductive layer in a pixel circuit according to exemplary embodiments of the present disclosure; FIG. 21C shows a schematic diagram of a planar structure of a second conductive layer in a pixel circuit according to exemplary embodiments of the present disclosure; FIG. 21D shows a schematic diagram of some via holes according to exemplary embodiments of the present disclosure; FIG. 21E shows a schematic diagram of a planar structure of a third conductive layer in a pixel circuit according to exemplary embodiments of the present disclosure; FIG. 21F shows a schematic diagram of a planar structure of a fourth conductive layer in a pixel circuit according to exemplary embodiments of the present disclosure; FIG. 21 shows a schematic diagram of a planar structure of a combination of the first semiconductor layer, the first conductive layer, the second conductive layer, the third conductive layer and the fourth conductive layer in a pixel circuit according to exemplary embodiments of the present disclosure.

### DETAILED DESCRIPTION OF EMBODIMENTS

In order to make objectives, technical solutions and advantages of embodiments of the present disclosure clearer, technical solutions of embodiments of the present disclosure will be clearly and completely described below with reference to the accompanying drawings. Obviously, the described embodiments are merely some embodiments rather than all embodiments of the present disclosure. According to the described embodiments of the present disclosure, all additional embodiments obtained by those ordinary skilled in the art without carrying out inventive effort fall within the scope of protection of the present disclosure.

It should be noted that in the accompanying drawings, for clarity and/or description purposes, a size and relative size of an element may be enlarged. Accordingly, the size and relative size of each element need not to be limited to those shown in the figures. In the specification and the accompanying drawings, the same or similar reference numerals represent the same or similar components.

When an element is described as being “on”, “connected to” or “coupled to” another element, the element may be directly on the another element, directly connected to the another element, or directly coupled to the another element, or an intermediate element may be provided. However, when an element is described as being “directly on”, “directly connected to” or “directly coupled to” another element, no intermediate element is provided. Other terms and/or expressions used to describe a relationship between elements, such as “between” and “directly between”, “adjacent to” and “directly adjacent to”, “on” and “directly on”, and so on, should be interpreted in a similar manner. Moreover, the term “connection” may refer to a physical connection, an electrical connection, a communicative connection, and/or a fluid connection. In addition, X-axis, Y-axis and Z-axis are not limited to three axes of a rectangular coordinate system, and may be interpreted in a broader meaning. For example, the X-axis, the Y-axis and the Z-axis may be perpendicular to each other, or may represent different directions that are not perpendicular to each other. For objectives of the present disclosure, “at least one selected from X, Y or Z” and “at least one selected from a group consisting of X, Y and Z” may be interpreted as only X, only Y, only Z, or any combination of two or more of X, Y and Z, such as XYZ, XYY, YZ and ZZ. As used herein, the term “and/or” includes any and all combinations of one or more of the listed related items.

It should be noted that although the terms “first”, “second”, and so on may be used herein to describe various components, members, elements, regions, layers and/or portions, these components, members, elements, regions, layers and/or portions should not be limited by these terms. Rather, these terms are used to distinguish one component, member, element, region, layer and/or portion from another one. Thus, for example, a first component, a first member, a first element, a first region, a first layer and/or a first portion discussed below may be referred to as a second component, a second member, a second element, a second region, a second layer and/or a second portion without departing from teachings of the present disclosure.

For ease of description, spatial relationship terms, such as “upper”, “lower”, “left”, “right”, may be used herein to describe a relationship between an element or feature and another element or feature as shown in the figures. It should be understood that the spatial relationship terms are intended to cover other different orientations of a device in use or operation in addition to the orientation described in the figures. For example, if a device in the figures is turned upside down, an element or feature described as “below” or “under” another element or feature will be oriented “above” or “on” the another element or feature.

Here, the terms “substantially”, “about”, “approximately”, “roughly” and other similar terms are used as terms of approximation rather than terms of degree, and they are intended to explain an inherent deviation of a measured or calculated value that will be recognized by those ordinary skilled in the art. Taking into account a process fluctuation, a measurement problem, an error related to a measurement of a specific quantity (that is, a limitation of a measurement system) and other factors, the terms “about” or “approximately” used herein includes a stated value and means that a specific value determined by those ordinary skilled in the art is within an acceptable range of deviation. For example, “about” may mean being within one or more standard deviations, or within ±30%, ±20%, ±10% or ±5% of the stated value.

It should be noted that the expression “the same layer” herein refers to a layer structure that is formed by firstly forming, using a same film forming process, a film layer used to form a specific pattern, and then patterning, using one-time patterning process, the film layer with a same mask. Depending on different specific patterns, the one-time patterning process may include a plurality of exposure, development or etching processes, and the specific pattern in the formed layer structure may be continuous or discontinuous. That is, a plurality of elements, components, structures and/or portions located in the “same layer” are made of the same material and formed by the same patterning process. Generally, a plurality of elements, components, structures and/or portions located in the “same layer” have substantially the same thickness.

Those skilled in the art should understand that, unless otherwise specified, the expression “height” or “thickness” herein refers to a size in a direction perpendicular to a surface of each film layer provided on the display substrate, that is, a size in a light emitting direction of the display substrate, or called a size in a normal direction of the display device.

Herein, the term “transistor” may be a triode, a thin film transistor, a field effect transistor, or other device with the same characteristics. In embodiments of the present disclosure, in order to distinguish two electrodes other than a control electrode of the transistor, one electrode is referred to as a first electrode and the other electrode is referred to as a second electrode. In actual operation, when the transistor is a thin film transistor or a field effect transistor, the first electrode may be a drain electrode and the second electrode may be a source electrode; or the first electrode may be a source electrode and the second electrode may be a drain electrode.

Embodiments of the present disclosure at least provide a pixel circuit. The pixel circuit includes: a first sub-pixel driving circuit used to drive a first sub-pixel; and a second sub-pixel driving circuit used to drive a second sub-pixel, where the first sub-pixel includes a first light emitting sub-element, the second sub-pixel includes a second light emitting sub-element, and the first sub-pixel is adjacent to the second sub-pixel in a first direction or a second direction intersecting with the first direction. The pixel circuit further includes a first data signal line, which is used to provide a data signal to the first sub-pixel driving circuit and the second sub-pixel driving circuit. The data signal includes a first data sub-signal and a second data sub-signal, the first data sub-signal is generated by the first data signal line in a third time period, the second data sub-signal is generated by the first data signal line in a fourth time period, and the third time period does not overlap with the fourth time period. Through the design of adjacent sub-pixels sharing a data signal line, the number of data signal lines may be reduced by half, and the wiring space may be saved, which helps achieve a narrow-bezel display substrate. Furthermore, reducing the number of data signal lines by half may reduce the number of IC channels required, so that the IC quantity may be reduced by half, and costs may be lowered.

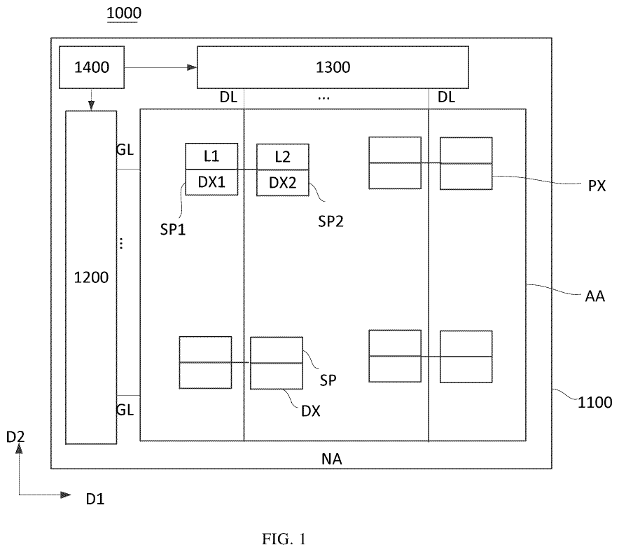

FIG. 1 shows a schematic plan view of a display device according to some embodiments of the present disclosure. For example, the display device may be an OLED display device. Referring to FIG. 1, a display device 1000 may include a display substrate 1100, a gate driver 1200, a data driver 1300 and a controller 1400. The display substrate 1100 may include a plurality of pixels PX and a plurality of pixel circuits used to drive the plurality of pixels PX. The display substrate 1100 may include a display region AA and a non-display region NA, the plurality of pixels PX are arranged in the display region AA in an array in a first direction D1 or a second direction D2, and the first direction D1 intersects with the second direction D2. A signal generated by the gate driver 1200 may be applied to the pixel PX through a signal line such as a scanning signal line GL, and a signal generated by the data driver 1300 may be applied to the pixel PX through a signal line such as a data line DL. For example, the plurality of pixels PX may include a first sub-pixel SP1 and a second sub-pixel SP2 adjacent to each other, the first sub-pixel SP1 may include a first light emitting unit L1 and a first sub-pixel driving circuit DX1, and the second sub-pixel may include a second light emitting unit L2 and a second sub-pixel driving circuit DX2. The first sub-pixel driving circuit DX1 and the second sub-pixel driving circuit DX2 may be electrically connected to the same data signal line and may receive data signals transmitted from the same data signal line.

For example, each pixel PX may include a plurality of sub-pixels, such as a red sub-pixel, a green sub-pixel and a blue sub-pixel, or include a white sub-pixel, a red sub-pixel, a green sub-pixel and a blue sub-pixel.

For example, the display substrate may be an array substrate for an OLED display panel.

The display substrate may further include a driver in the non-display region NA. For example, the driver may be located on at least one side of the display region AA. The driver may be used to drive the pixels in the display substrate for display. For example, the driver may include a gate driver 1200 and a data driver 1300. The data driver 1300 is used to sequentially latch input data according to clock signal timing, convert the latched data into analog signals, and then input the analog signals to data signal lines of the display substrate. The data driver 1300 includes a plurality of IC chips, which are used to write control signals to the plurality of data signal lines. The number of IC chips required is related to the number of data signal lines, and the more data signal lines, the larger the number of IC chips required. The gate driver 1200 is typically implemented by a shift register, which converts clock signals into on/off voltages and outputs the on/off voltages to scanning signal lines of the display substrate.

It should be noted that FIG. 1 shows that the drivers are located on a left side and an upper side of the display region AA. However, embodiments of the present disclosure are not limited thereto, and the driving circuit may be located at any suitable position in the non-display region NA.

Exemplarily, a GOA technology, namely Gate Driver on Array, may be adopted for the driver. In the GOA technology, a gate driving circuit is provided directly on an array substrate to replace an external driver chip. Each GOA unit serves as a stage of shift register, and each stage of shift register is connected to a gate line. Various stages of shift registers may sequentially output on voltages to achieve progressive scanning of pixels. In some embodiments, each stage of shift register may be connected to a plurality of gate lines. In this way, it may adapt to a development trend of high resolution and narrow bezel of display substrates.

It should be noted that a shape of an orthographic projection of the sub-pixel on the base substrate is illustratively shown as a rectangle. However, embodiments of the present disclosure are not limited to this. For example, the shape of the orthographic projection of the sub-pixel on the base substrate may be a rounded rectangle, a hexagon, a pentagon, a square, a circle or other shapes.

A plurality of sub-pixels are arranged on the base substrate 1 in an array in a first direction D1 and a second direction D2. It should be noted that although the first direction D1 and the second direction D2 are perpendicular to each other in the illustrated embodiments, embodiments of the present disclosure are not limited to this.

It should be understood that in embodiments of the present disclosure, each sub-pixel includes a pixel circuit and a light emitting element. For example, the light emitting element may be an OLED light emitting element, including an anode, a light emitting layer and a cathode arranged in a stack. The pixel circuit may include a plurality of thin film transistors and at least one storage capacitor.

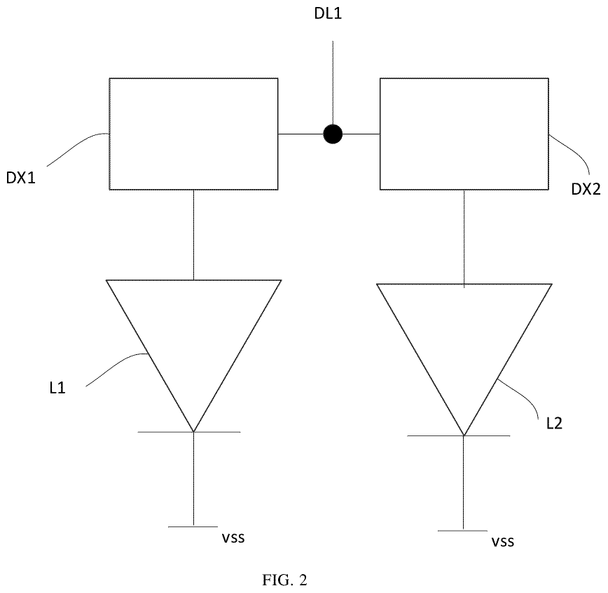

FIG. 2 shows a schematic structural diagram of sub-pixels according to some embodiments of the present disclosure.

As shown in FIG. 2, two adjacent sub-pixels include: a first light emitting sub-element L1 and a first sub-pixel driving circuit DX1 coupled to the first light emitting sub-element L1; as well as a second light emitting sub-element L2 and a second sub-pixel driving circuit DX2 coupled to the second light emitting sub-element L2. The first sub-pixel driving circuit DX1 is used to provide a driving current to the first light emitting sub-element L1 to drive the first light emitting sub-element L1 to operate (i.e., emit light), and the second sub-pixel driving circuit DX2 is used to provide a driving current to the second light emitting sub-element L2 to drive the second light emitting sub-element L2 to operate. The first sub-pixel driving circuit DX1 and the second sub-pixel driving circuit DX2 may be coupled to the same data signal line, such as a first data signal line DL1. The first data signal line DL1 may provide a data signal to the first sub-pixel driving circuit DX1 and the second sub-pixel driving circuit DX2 to respectively control the first light emitting sub-element L1 and the second light emitting sub-element L2 to emit light. The data signal received by the first sub-pixel driving circuit DX1 and the data signal received by the second sub-pixel driving circuit DX2 may be at different times, and may have different sizes.

Exemplarily, the data signal may include a first data sub-signal and a second data sub-signal. The first data sub-signal may be generated by the first data signal line DL1 in a third time period, the second data sub-signal may be generated by the first data signal line DL1 in a fourth time period, and the third time period does not overlap with the fourth time period. A data signal may be provided to two adjacent sub-pixels in different time periods through the same data signal line to light up a plurality of pixels. On the one hand, the number of data signal lines may be reduced and the wiring space may be saved, which helps achieve a narrow-bezel display substrate. On the other hand, reducing the number of data signal lines may help reduce the number of supporting IC chips and lower costs.

Exemplarily, the light emitting element may include a current-driven element. Further, the light emitting element L may be a current-type light emitting diode, such as a micro light emitting diode (Micro LED), a mini light emitting diode (Mini LED), a quantum light emitting diode (QLED) or an organic light emitting diode (OLED). Exemplarily, the first electrode and the second electrode of the light emitting element L refer to an anode and a cathode of the light emitting diode, respectively.

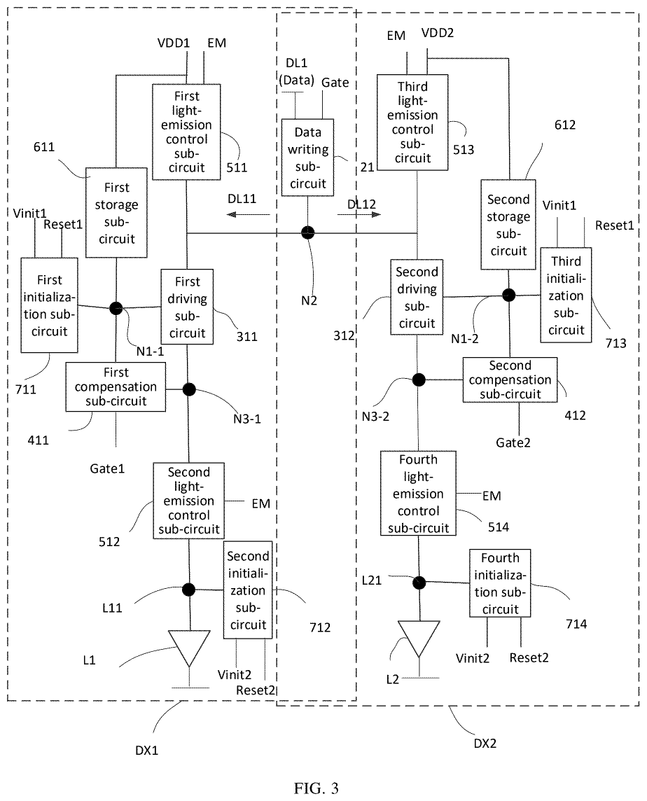

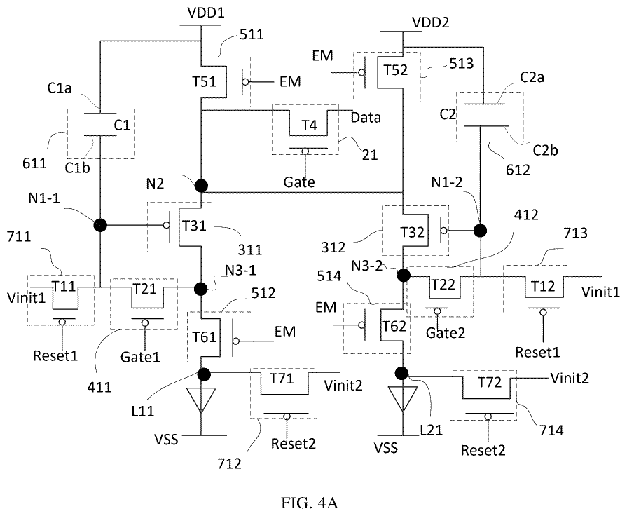

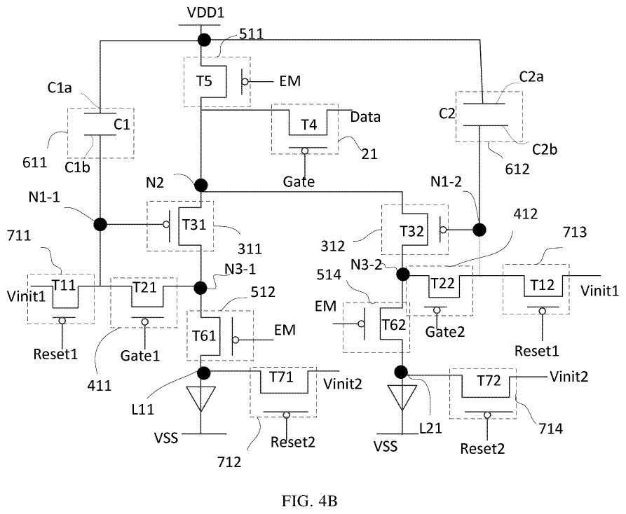

FIG. 3 shows a structural block diagram of a pixel circuit according to some embodiments of the present disclosure. FIG. 4A shows an equivalent circuit diagram of a pixel circuit according to some embodiments of the present disclosure. It should be noted that in the following description, for the driving circuit of a single sub-pixel, a 7T1C pixel circuit is illustrated by way of example in describing a structure of the pixel circuit. However, embodiments of the present disclosure are not limited to the 7T1C pixel circuit, and other known pixel circuit structures may be applied to embodiments of the present disclosure in a case of no conflict.

Exemplarily, in some embodiments of the present disclosure, referring to FIG. 3, the pixel driving circuit includes a first sub-pixel driving circuit DX1 and a second sub-pixel driving circuit DX2. The first sub-pixel driving circuit DX1 and the second sub-pixel driving circuit DX2 share a data writing sub-circuit 21, the data writing sub-circuit 21 is coupled to a data signal terminal Data, a first scanning signal terminal Gate and a second node N2, and the data signal terminal Data is coupled to the first data signal line DL1. The data writing sub-circuit 21 is configured to write a data signal received at the data signal terminal Data to the second node N2 in response to a first scanning signal received at the first scanning signal terminal Gate. The first sub-pixel driving circuit DX1 and the second sub-pixel driving circuit DX2 are coupled to the second node N2, and the data writing sub-circuit 21 may write a first data sub-signal DL11 to the first sub-pixel driving circuit DX1 through the second node N2 and write a second data sub-signal DL12 to the second sub-pixel driving circuit DX2 through the second node N2.

The driving circuits of adjacent sub-pixels may share at least part of the circuit, such as the data writing sub-circuit, and the data writing sub-circuit includes at least a transistor. Through the design of adjacent sub-pixel driving circuits sharing a transistor, the number of transistors and the number of via holes may be reduced, which helps improve a yield of display substrate process section and also helps a layout of subsequent high-resolution product.

Exemplarily, continuing to refer to FIG. 3, the first sub-pixel driving circuit DX1 may further include a first driving sub-circuit 311 and a first compensation sub-circuit 411. The first driving sub-circuit 311 is coupled to a first sub-node of first node N1-1, the second node N2, and a first sub-node of third node N3-1. The first driving sub-circuit 311 is configured to generate a first driving current in response to a voltage of the first sub-node of first node N1-1, and the first driving current is used to drive the first light emitting sub-element L1 to emit light. The first compensation sub-circuit 411 is coupled to a second scanning signal terminal Gate1, the first sub-node of first node N1-1, and the first sub-node of third node N3-1. The first compensation sub-circuit 411 is configured to transmit a first data sub-signal DL11 from the data signal terminal Data to the first sub-node of first node N1-1 in response to a second scanning signal received at the second scanning signal terminal Gate1. The second sub-pixel driving circuit DX2 may further include a second driving sub-circuit 312 and a second compensation sub-circuit 412. The second driving sub-circuit 312 is coupled to a second sub-node of first node N1-2, the second node N2, and a second sub-node of third node N3-2. The second driving sub-circuit 312 is configured to generate a second driving current in response to a voltage of the second sub-node of first node N1-2, and the second driving current is used to drive the second light emitting sub-element L2 to emit light. The second compensation sub-circuit 412 is coupled to a third scanning signal terminal Gate2, the second sub-node of first node N1-2, and the second sub-node of third node N3-2. The second compensation sub-circuit 412 is configured to transmit a second data sub-signal DL12 from the data signal terminal Data to the second sub-node of first node N1-2 in response to a third scanning signal received at the third scanning signal terminal Gate2.

Exemplarily, the data writing sub-circuit 21, the first driving sub-circuit 311 and the second driving sub-circuit 312 are coupled to the second node N2. The data writing sub-circuit 21 may write the data signal to the first driving sub-circuit 311 and the second driving sub-circuit 312 respectively through the second node N2, so as to respectively control the first light emitting sub-element L1 and the second light emitting sub-element L2 to emit light, thereby achieving different display effects.

Exemplarily, continuing to refer to FIG. 3, the first sub-pixel driving circuit DX1 may further include a first light-emission control sub-circuit 511 and a first storage sub-circuit 611. The first light-emission control sub-circuit 511 is coupled to a first voltage terminal VDD1, a light-emission control terminal EM and the second node N2, and the first light-emission control sub-circuit 511 is configured to write a first voltage received at the first voltage terminal VDD1 to the second node N2 in response to a light-emission control signal received at the light-emission control terminal EM. The first storage sub-circuit 611 is coupled to the first sub-node of first node N1-1 and the first voltage terminal VDD, and the first storage sub-circuit 611 may be used to store a storage voltage in the first sub-pixel driving circuit. The second sub-pixel driving circuit DX2 may further include a third light-emission control sub-circuit 513 and a second storage sub-circuit 612. The third light-emission control sub-circuit 513 is coupled to a second voltage terminal VDD2, a light-emission control terminal EM and the second node N2, and the third light-emission control sub-circuit 513 is configured to write a second voltage received at the second voltage terminal VDD2 to the second node N2 in response to a light-emission control signal received at the light-emission control terminal EM. The second storage sub-circuit 612 is coupled to the second sub-node of first node N1-2 and the second voltage terminal VDD2.

Exemplarily, both the first voltage terminal VDD1 and the second voltage terminal VDD2 may provide a high-level voltage, such as a 5V voltage, and the first voltage provided by the first voltage terminal VDD1 may be the same as the second voltage provided by the second voltage terminal VDD2.

Exemplarily, continuing to refer to FIG. 3, the first sub-pixel driving circuit DX1 may further include a first initialization sub-circuit 711, a second initialization sub-circuit 712 and a second light-emission control sub-circuit 512. The first initialization sub-circuit 711 is coupled to a first reset signal terminal Reset1, a first initialization signal terminal Vinit1, and the first sub-node of first node N1-1. The first initialization sub-circuit 711 is configured to transmit a first initialization signal received at the first initialization signal terminal Vinit1 to the first sub-node of first node N1-1 to initialize a potential of the first sub-node of first node N1-1 in response to a first reset signal received at the first reset signal terminal Reset1. The second initialization sub-circuit 712 is coupled to a second reset signal terminal Reset2, a second initialization signal terminal Vinit2, and a first electrode L11 of the first light emitting sub-element L1. The second initialization sub-circuit 712 is configured to transmit a second initialization signal received at the second initialization signal terminal Vinit2 to the first electrode L11 of the first light emitting sub-element L1 to initialize a potential of the first electrode L11 of the first light emitting sub-element L1 in response to a second reset signal received at the second reset signal terminal Reset2. The second light-emission control sub-circuit 512 is coupled to the first sub-node of third node N3-1, the light-emission control terminal EM, and the first electrode L11 of the first light emitting sub-element L1. The second light-emission control sub-circuit 512 is configured to output a first driving current transmitted to the first sub-node of third node N3-1 to the first light emitting sub-element in response to a light-emission control signal received at the light-emission control terminal EM.

Exemplarily, continuing to refer to FIG. 3, the second sub-pixel driving circuit DX2 may further include a third initialization sub-circuit 713, a fourth initialization sub-circuit 714 and a fourth light-emission control sub-circuit 514. The third initialization sub-circuit 713 is coupled to the first reset signal terminal Reset1, the first initialization signal terminal Vinit1, and the second sub-node of first node N1-2. The third initialization sub-circuit 713 is configured to transmit a first initialization signal received at the first initialization signal terminal Vinit1 to the second sub-node of first node N1-2 to initialize a potential of the second sub-node of first node N1-2 in response to a first reset signal received at the first reset signal terminal Reset1. The fourth initialization sub-circuit 714 is coupled to the second reset signal terminal Reset2, the second initialization signal terminal Vinit2, and a first electrode L21 of the second light emitting sub-element L2. The fourth initialization sub-circuit 714 is configured to transmit a second initialization signal received at the second initialization signal terminal Vinit2 to the first electrode L21 of the second light emitting sub-element L2 to initialize a potential of the first electrode L21 of the second light emitting sub-element L2 in response to a second reset signal received at the second reset signal terminal Reset2. The fourth light-emission control sub-circuit 514 is coupled to the second sub-node of third node N3-2, the light-emission control terminal EM, and the first electrode L21 of the second light emitting sub-element L2. The second light-emission control sub-circuit 514 is configured to output a second driving current transmitted to the second sub-node of third node N3-2 to the second light emitting sub-element L2 in response to a light-emission control signal received at the light-emission control terminal EM.

Through the design of the driving circuits of two adjacent sub-pixels sharing a data writing sub-circuit and a data signal line, on the one hand, the number of data signal lines may be reduced, and the wiring space may be saved, which helps achieve a narrow-bezel display substrate; on the other hand, reducing the number of data signal lines may help reduce the number of supporting IC chips and lower costs. Furthermore, adjacent sub-pixel driving circuits may share at least some transistors, such as a data writing transistor, so that the number of transistors and the number of via holes may be reduced, which helps improve the yield of display substrate process section and helps the layout of subsequent high-resolution product.

It should be understood that in the pixel circuit provided in embodiments of the present disclosure, the first sub-node of first node N1-1, the second sub-node of first node N1-2, the second node N2, the first sub-node of third node N3-1, the second sub-node of third node N3-2 and other nodes do not necessarily represent actual components. In some embodiments, these nodes represent convergence points of relevant couplings (i.e., electrical connections) in the equivalent circuit diagram of the pixel circuit, that is, these nodes are equivalent to the convergence points of relevant electrical connections in the circuit diagram.

Exemplarily, in some embodiments of the present disclosure, referring to FIG. 4A, in the first sub-pixel driving circuit DX1, the data writing sub-circuit 21 includes a data writing transistor T4, the first driving sub-circuit 311 includes a first driving transistor T31, the first compensation sub-circuit 411 includes a first compensation transistor T21, the first light-emission control sub-circuit 511 includes a first light-emission control transistor T51, the second light-emission control sub-circuit 512 includes a second light-emission control transistor T61, the first initialization sub-circuit 711 includes a first initialization transistor T11, the second initialization sub-circuit 712 includes a second initialization transistor T71, and the first storage sub-circuit 611 includes a first capacitor C1.

Exemplarily, continuing to refer to FIG. 4A, in the second sub-pixel driving circuit DX2, the data writing sub-circuit 21 includes a data writing transistor T4, the second driving sub-circuit 312 includes a second driving transistor T32, the second compensation sub-circuit includes a second compensation transistor T22, the third light-emission control sub-circuit 513 includes a third light-emission control transistor T52, the fourth light-emission control sub-circuit 514 includes a fourth light-emission control transistor T62, the third initialization sub-circuit 713 includes a third initialization transistor T12, the fourth initialization sub-circuit 714 includes a fourth initialization transistor T72, and the second storage sub-circuit 612 includes a second capacitor C2.

The first sub-pixel driving circuit DX1 and the second sub-pixel driving circuit DX2 share a data writing transistor and a data signal line, so that the number of wires and the number of via holes may be reduced to help achieve a narrow bezel and improve a yield, and the number of IC chips may be reduced to lower costs.

It should be noted that each transistor includes: a control electrode, i.e., a gate electrode of the transistor; a first electrode, i.e., one of a source electrode and a drain electrode of the transistor; and a second electrode, i.e., the other of the source electrode and the drain electrode of the transistor.

The data writing transistor T4 has a control electrode electrically connected to the first scanning signal terminal Gate, a first electrode electrically connected to the second node N2, and a second electrode electrically connected to the data signal terminal Data. For example, the data writing transistor T4 is used to provide a data signal.

The first driving transistor T31 has a control electrode electrically connected to the first sub-node of first node N1-1, a first electrode electrically connected to the second node N2, and a second electrode electrically connected to the first sub-node of third node N3-1.

The first compensation transistor T21 has a control electrode electrically connected to the second scanning signal terminal Gate1, a first electrode electrically connected to the first sub-node of first node N1-1, and a second electrode electrically connected to the first sub-node of third node N3-1.

The first light-emission control transistor T51 has a control electrode electrically connected to the light-emission control terminal EM, a first electrode electrically connected to the first voltage terminal VDD1, and a second electrode electrically connected to the second node N2.

The second light-emission control transistor T61 has a control electrode electrically connected to the light-emission control terminal EM, a first electrode electrically connected to the first sub-node of third node N3-1, and a second electrode electrically connected to the first electrode L11 of the first light emitting sub-element.

The first initialization transistor T11 has a control electrode electrically connected to the first reset signal terminal Reset1, a first electrode electrically connected to the first initialization signal terminal Vinit1, and a second electrode electrically connected to the first sub-node of first node N1-1.

The second initialization transistor T71 has a control electrode electrically connected to the second reset signal terminal Reset2, a first electrode electrically connected to the first electrode L11 of the first light emitting sub-element, and a second electrode electrically connected to the second initialization signal terminal Vinit2.

The first capacitor C1 may include a first plate C1a and a second plate C1b. The first plate C1a of the first capacitor C1 is electrically connected to a first electrode of the first light-emission control transistor T51, and the second plate C1b of the first capacitor C1 is electrically connected to the first sub-node of first node N1-1.

The second driving transistor T32 has a control electrode electrically connected to the second sub-node of first node N1-2, a first electrode electrically connected to the second node N2, and a second electrode electrically connected to the second sub-node of third node N3-2.

The second compensation transistor T22 has a control electrode electrically connected to the third scanning signal terminal Gate2, a first electrode electrically connected to the second sub-node of third node N3-2, and a second electrode electrically connected to the second sub-node of first node N1-2.

The third light-emission control transistor T52 has a control electrode electrically connected to the light-emission control terminal EM, a first electrode electrically connected to the second voltage terminal VDD2, and a second electrode electrically connected to the second node N2.

The fourth light-emission control transistor T62 has a control electrode electrically connected to the light-emission control terminal EM, a first electrode electrically connected to the second sub-node of third node N3-2, and a second electrode electrically connected to the first electrode L21 of the second light emitting sub-element.

The third initialization transistor T12 has a control electrode electrically connected to the first reset signal terminal Reset1, a first electrode electrically connected to the second sub-node of first node N1-2, and a second electrode electrically connected to the first initialization signal terminal Vinit1.

The fourth initialization transistor T72 has a control electrode electrically connected to the second reset signal terminal Reset2, a first electrode electrically connected to the first electrode L21 of the second light emitting sub-element, and a second electrode electrically connected to the second initialization signal terminal Vinit2.

The second capacitor C2 may include a third plate C2a and a fourth plate C2b. The third plate C2a of the second capacitor C2 is electrically connected to the first electrode of the third light-emission control transistor T52, and the fourth plate C2b of the second capacitor C2 is electrically connected to the second sub-node of first node N1-2.

A second electrode of the first light emitting sub-element is electrically connected to a third voltage terminal, and a second electrode of the second light emitting sub-element is electrically connected to a fourth voltage terminal. The third voltage terminal and the fourth voltage terminal are used to provide low voltages.

In embodiments of the present disclosure, the first initialization signal terminal Vinit1 and the second initialization signal terminal Vinit2 may provide the same or different initialization signals.

In embodiments of the present disclosure, the first reset signal terminal Reset1 and the second reset signal terminal Reset2 may provide the same or different reset signals.

In embodiments of the present disclosure, the transistors in the pixel circuit may be P-type transistors, N-type transistors, or a combination of a plurality of transistors including P-type transistors and N-type transistors.

In embodiments of the present disclosure, the transistors in the pixel circuit may be oxide thin-film transistors, low-temperature poly-silicon transistors, thin film transistors, or a combination thereof.

FIG. 4B shows an equivalent circuit diagram of a pixel circuit according to some embodiments of the present disclosure.

In some embodiments of the present disclosure, as shown in FIG. 4A, the first light-emission control sub-circuit 511 including the first light-emission control transistor T51 and the third light-emission control sub-circuit 513 including the third light-emission control transistor T52 may share the same transistor. For example, the first light-emission control transistor T51 and the third light-emission control transistor T52 may be shared to form a light-emission control transistor T5 shown in FIG. 4B.

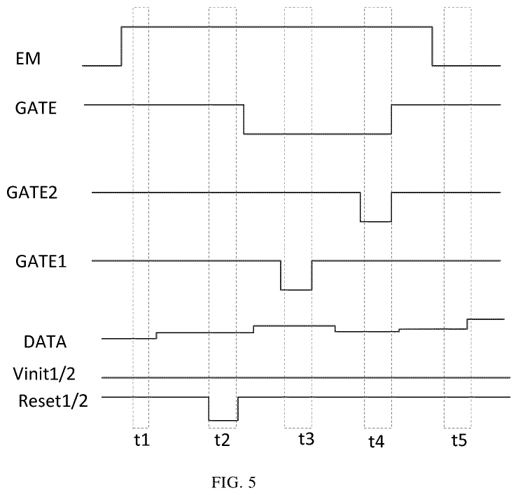

The difference from the embodiments in FIG. 4A is that the light-emission control transistor T5 in FIG. 4B provides a light-emission control signal to the first sub-pixel driving circuit and the second sub-pixel driving circuit simultaneously, and the first capacitor C1 and the second capacitor C2 are connected to the light-emission control transistor T5 in a different way. For example, the first capacitor C1 may include a first plate C1a and a second plate C1b, the first plate C1a of the first capacitor C1 is electrically connected to a first electrode of the light-emission control transistor T5, and the second plate C1b of the first capacitor C1 is electrically connected to the first sub-node of first node N1-1. The second capacitor C2 may include a third plate C2a and a fourth plate C2b, the third plate C2a of the second capacitor C2 is electrically connected to the first electrode of the light-emission control transistor T5, and the fourth plate C2b of the second capacitor C2 is electrically connected to the second sub-node of first node N1-2. The other transistors may be connected in the same way as the corresponding transistors in FIG. 4A. FIG. 5 shows a working sequence diagram of at least one embodiment of a driving method for the pixel shown in FIG. 4A.

Exemplarily, in some embodiments of the present disclosure, referring to FIG. 3 to FIG. 5, an operation of the pixel circuit may include five stages in sequence as follows.

In a first time period t1, in response to a light-emission control signal of the light-emission control terminal EM, the first sub-pixel SP1 and the second sub-pixel SP2 stop emitting light, and the first sub-pixel driving circuit DX1 and the second sub-pixel driving circuit DX2 start to reset.

In a second time period t2, in response to a first reset signal of the first reset signal terminal Reset1, the first initialization sub-circuit 711 and the third initialization sub-circuit 713 are turned on, so that the first initialization signal from the first initialization signal terminal Vinit1 is transmitted to the first sub-node of first node N1-1 and the second sub-node of first node N1-2 respectively. The first time period t1 and the second time period t2 are in a reset stage of an image frame, and the first time period t1 is before the second time period t2.

In a third time period t3, in response to a first scanning signal Gate and a second scanning signal Gate1, the data writing sub-circuit 21 and the first compensation sub-circuit 411 are turned on, so that a first data sub-signal DL11 from the data signal terminal Data is transmitted to the first sub-node of first node N1-1.

In a fourth time period t4, in response to the first scanning signal Gate and a third scanning signal Gate2, the data writing sub-circuit 21 and the second compensation sub-circuit 412 are turned on, so that a second data sub-signal DL12 from the data signal terminal Data is transmitted to the second sub-node of first node N1-2. The third time period t3 and the fourth time period t4 are in a writing stage of an image frame, the fourth time period t4 is after the third time period t3, and the fourth time period t4 does not overlap with the third time period t3.

In a case that the data writing sub-circuit is turned on, by controlling the first compensation sub-circuit 411 and the second compensation sub-circuit 412 to turn on in different time periods, the data signal provided by the same data signal line may be written to the first sub-pixel driving circuit and the second sub-pixel driving circuit respectively in two different time periods. Since the third time period t3 and the fourth time period t4 do not overlap each other, the data signals of the two sub-pixel driving circuits do not interfere with each other, and the purpose of providing the data signal to two different sub-pixels may be achieved. For example, the first data sub-signal DL11 may be provided to the first sub-pixel driving circuit in the third time period t3, and the second data sub-signal DL12 may be provided to the second sub-pixel driving circuit in the fourth time period t4.

In a fifth time period t5, in response to a light-emission control signal of the light-emission control terminal, the first light-emission control sub-circuit 511, the second light-emission control sub-circuit 512, the third light-emission control sub-circuit 513 and the fourth light-emission control sub-circuit 514 are all turned on, and the first light emitting sub-element L1 and the second light emitting sub-element L2 may emit light.

Exemplarily, the first data sub-signal DL11 may be the same as or different from the second data sub-signal DL12, so that a light-emission state of the first light emitting sub-element L1 may be the same as or different from a light-emission state of the second light emitting sub-element L2.

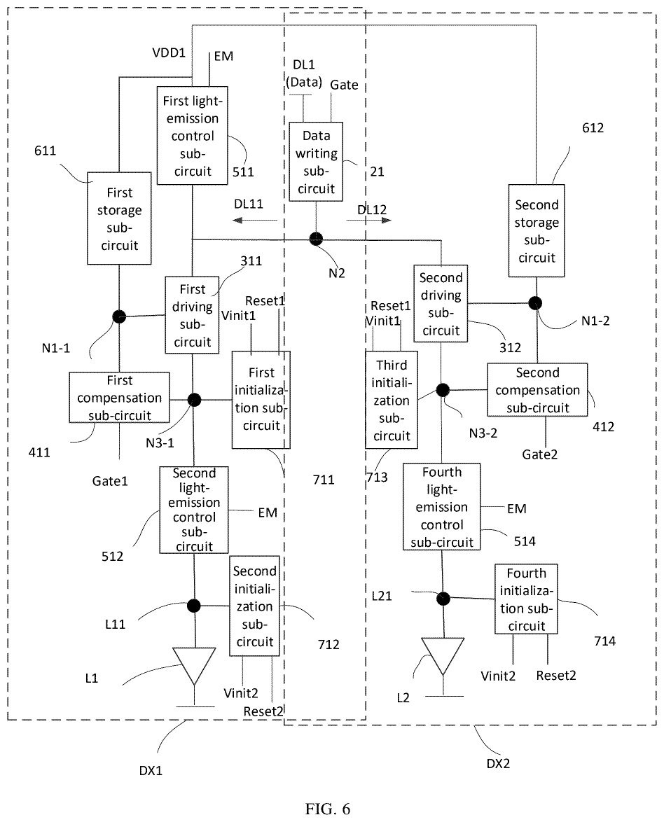

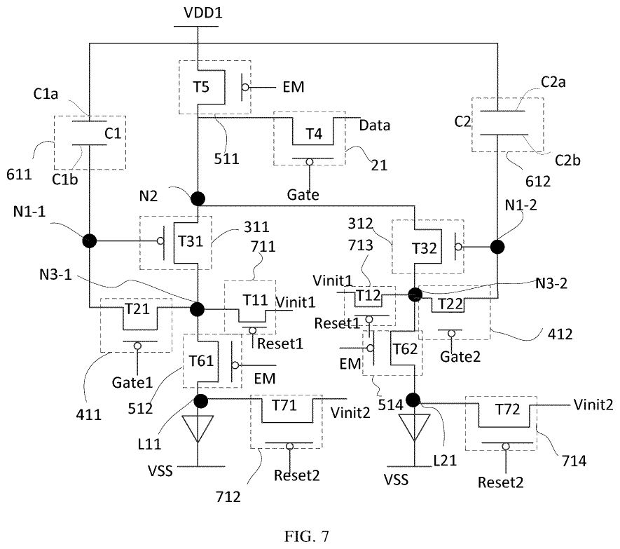

FIG. 6 shows a structural block diagram of a pixel circuit according to some embodiments of the present disclosure; FIG. 7 shows an equivalent circuit diagram of a pixel circuit according to some embodiments of the present disclosure.

Exemplarily, in some embodiments of the present disclosure, referring to FIG. 6, the pixel driving circuit includes a first sub-pixel driving circuit DX1 and a second sub-pixel driving circuit DX2, and the first sub-pixel driving circuit DX1 and the second sub-pixel driving circuit DX2 share a data writing sub-circuit 21 and a first light-emission control sub-circuit 511. The data writing sub-circuit 21 is coupled to the data signal terminal Data, the first scanning signal terminal Gate and the second node N2, and the data signal terminal Data is coupled to the first data signal line DL1. The data writing sub-circuit 21 is configured to write a data signal received at the data signal terminal Data to the second node N2 in response to a first scanning signal received at the first scanning signal terminal Gate. The first sub-pixel driving circuit DX1 and the second sub-pixel driving circuit DX2 are coupled to the second node N2, and the data writing sub-circuit 21 may write a first data sub-signal DL11 to the first sub-pixel driving circuit DX1 through the second node N2 and write a second data sub-signal DL12 to the second sub-pixel driving circuit DX2 through the second node N2. The first light-emission control sub-circuit 511 is coupled to the first voltage terminal VDD1, the light-emission control terminal EM and the second node N2. The first light-emission control sub-circuit 511 is configured to write a first voltage received at the first voltage terminal VDD respectively to the first sub-pixel driving circuit and the second sub-pixel driving circuit through the second node in response to a light-emission control signal received at the light-emission control terminal EM.

The driving circuits of adjacent sub-pixels may share at least part of the circuit, such as a data writing sub-circuit and a first light-emission control sub-circuit. The shared circuit includes at least some shared transistors. For example, the data writing sub-circuit may include a data writing transistor, and the first light-emission control sub-circuit may include a first light-emission control transistor. Through the design of adjacent sub-pixel driving circuits sharing a transistor, the number of transistors and the number of via holes may be reduced, which helps improve the yield of display substrate process section and also helps the design and layout of subsequent high-resolution product.

Exemplarily, continuing to refer to FIG. 6, the first sub-pixel driving circuit DX1 may further include a first driving sub-circuit 311 and a first compensation sub-circuit 411. The first driving sub-circuit 311 is coupled to the first sub-node of first node N1-1, the second node N2, and the first sub-node of third node N3-1. The first driving sub-circuit 311 is configured to generate a first driving current in response to a voltage of the first sub-node of first node N1-1, and the first driving current is used to drive the first light emitting sub-element L1 to emit light. The first compensation sub-circuit 411 is coupled to the second scanning signal terminal Gate1, the first sub-node of first node N1-1, and the first sub-node of third node N3-1. The first compensation sub-circuit 411 is configured to transmit a first data sub-signal DL11 from the data signal terminal Data to the first sub-node of first node N1-1 in response to a second scanning signal received at the second scanning signal terminal Gate1. The second sub-pixel driving circuit DX2 may further include a second driving sub-circuit 312 and a second compensation sub-circuit 412. The second driving sub-circuit 312 is coupled to the second sub-node of first node N1-2, the second node N2, and the second sub-node of third node N3-2. The second driving sub-circuit 312 is configured to generate a second driving current in response to a voltage of the second sub-node of first node N1-2, and the second driving current is used to drive the second light emitting sub-element L2 to emit light. The second compensation sub-circuit 412 is coupled to the third scanning signal terminal Gate2, the second sub-node of first node N1-2, and the second sub-node of third node N3-2. The second compensation sub-circuit 412 is configured to transmit a second data sub-signal DL12 from the data signal terminal Data to the second sub-node of first node N1-2 in response to a third scanning signal received at the third scanning signal terminal Gate2.

Exemplarily, the data writing sub-circuit 21, the first light-emission control sub-circuit 511, the first driving sub-circuit 311 and the second driving sub-circuit 312 are all coupled to the second node N2. The data writing sub-circuit 21 may write the data signal to the first driving sub-circuit 311 and the second driving sub-circuit 312 respectively through the second node N2, and the first light-emission control sub-circuit 511 may write the first voltage to the first sub-pixel driving circuit and the second sub-pixel driving circuit respectively through the second node. By sharing the data writing sub-circuit and the first light light-emission control sub-circuit, the number of wires, the number of transistors and the number of via holes in the driving circuit may be reduced, which helps save the wiring space and achieve a narrow-bezel display substrate. Furthermore, the reduction of transistors and via holes may also help improve the yield of the display substrate.

Exemplarily, continuing to refer to FIG. 6, the first sub-pixel driving circuit DX1 may further include a first storage sub-circuit 611, which is coupled to the first sub-node of first node N1-1 and the first voltage terminal VDD1. The first storage sub-circuit 611 may be used to store a storage voltage in the first sub-pixel driving circuit. The second sub-pixel driving circuit DX2 may further include a second storage sub-circuit 612, which is coupled to the second sub-node of first node N1-2 and the first voltage terminal VDD1. The second storage sub-circuit is configured to store a storage voltage in the second sub-pixel driving circuit.

Exemplarily, continuing to refer to FIG. 6, the first sub-pixel driving circuit DX1 may further include a first initialization sub-circuit 711, a second initialization sub-circuit 712 and a second light-emission control sub-circuit 512. The first initialization sub-circuit 711 is coupled to the first reset signal terminal Reset1, the first initialization signal terminal Vinit1, and the first sub-node of third node N3-1. The first initialization sub-circuit 711 is configured to transmit a first initialization signal received at the first initialization signal terminal Vinit1 sequentially to the first sub-node of third node N3-1 and the first sub-node of first node N1-1 to initialize a potential of the first sub-node of first node N1-1 in response to a first reset signal received at the first reset signal terminal Reset1. The second initialization sub-circuit 712 is coupled to the second reset signal terminal Reset2, the second initialization signal terminal Vinit2, and the first electrode L11 of the first light emitting sub-element L1. The second initialization sub-circuit 712 is configured to transmit a second initialization signal received at the second initialization signal terminal Vinit2 to the first electrode L11 of the first light emitting sub-element L1 to initialize a potential of the first electrode L11 of the first light emitting sub-element L1 in response to a second reset signal received at the second reset signal terminal Reset2. The second light-emission control sub-circuit 512 is coupled to the first sub-node of third node N3-1, the light-emission control terminal EM, and the first electrode L11 of the first light emitting sub-element L1. The second light-emission control sub-circuit 512 is configured to output a first driving current transmitted to the first sub-node of third node N3-1 to the first light emitting sub-element in response to a light-emission control signal received at the light-emission control terminal EM.

Exemplarily, continuing to refer to FIG. 6, the second sub-pixel driving circuit DX2 may further include a third initialization sub-circuit 713, a fourth initialization sub-circuit 714 and a fourth light-emission control sub-circuit 514. The third initialization sub-circuit 713 is coupled to the first reset signal terminal Reset1, the first initialization signal terminal Vinit1 and the second sub-node of third node N3-2. The third initialization sub-circuit 713 is configured to transmit a first initialization signal received at the first initialization signal terminal Vinit1 sequentially to the second sub-node of third node N3-2 and the second sub-node of first node N1-2 to initialize a potential of the second sub-node of first node N1-2 in response to a first reset signal received at the first reset signal terminal Reset1. The fourth initialization sub-circuit 714 is coupled to the second reset signal terminal Reset2, the second initialization signal terminal Vinit2, and the first electrode L21 of the second light emitting sub-element L2. The fourth initialization sub-circuit 714 is configured to transmit a second initialization signal received at the second initialization signal terminal Vinit2 to the first electrode L21 of the second light emitting sub-element L2 to initialize a potential of the first electrode L21 of the second light emitting sub-element L2 in response to a second reset signal received at the second reset signal terminal Reset2. The fourth light-emission control sub-circuit 514 is coupled to the second sub-node of third node N3-2, the light-emission control terminal EM, and the first electrode L21 of the second light emitting sub-element L2. The second light-emission control sub-circuit 514 is configured to output a second driving current transmitted to the second sub-node of third node N3-2 to the second light emitting sub-element L2 in response to a light-emission control signal received at the light-emission control terminal EM.

Through the design of the driving circuits of two adjacent sub-pixels sharing a data writing sub-circuit, a first light-emission control sub-circuit and a data signal line, on the one hand, the number of data signal lines may be reduced, and the wiring space is saved, which helps achieve a narrow bezel of the display substrate; on the other hand, reducing the number of data signal lines may help reduce the number of supporting IC chips and lower costs. Furthermore, adjacent sub-pixel driving circuits may share at least some transistors, such as a data writing transistor, so that the number of transistors and the number of via holes may be reduced, which helps improve the yield of display substrate process section and also helps the layout of subsequent high-resolution product.

Exemplarily, in some embodiments of the present disclosure, referring to FIG. 6 and FIG. 7, the first sub-pixel driving circuit DX1 and the second sub-pixel driving circuit share a data writing sub-circuit 21 and a first light-emission control sub-circuit 511. The data writing sub-circuit 21 includes a data writing transistor T4, which has a control electrode coupled to the first scanning signal terminal Gate, a first electrode coupled to the second node N2 and a second electrode coupled to the data signal terminal Data. The first light-emission control sub-circuit 511 includes a light-emission control transistor T5, which has a control electrode coupled to the light-emission control terminal EM, a first electrode coupled to the first voltage terminal VDD1 and a second electrode coupled to the second node N2.

Exemplarily, continuing to refer to FIG. 6 and FIG. 7, in the first sub-pixel driving circuit DX1, the first driving sub-circuit 311 includes a first driving transistor T31, the first compensation sub-circuit includes a first compensation transistor T21, the second light-emission control sub-circuit 512 includes a second light-emission control transistor T61, the first initialization sub-circuit 711 includes a first initialization transistor T11, the second initialization sub-circuit 712 includes a second initialization transistor T71, and the first storage sub-circuit 611 includes a first capacitor C1.

In the second sub-pixel driving circuit DX2, the second driving sub-circuit 312 includes a second driving transistor T32, the second compensation sub-circuit 412 includes a second compensation transistor T22, the fourth light-emission control sub-circuit 514 includes a fourth light-emission control transistor T62, the third initialization sub-circuit 713 includes a third initialization transistor T12, the fourth initialization sub-circuit 714 includes a fourth initialization transistor T72, and the second storage sub-circuit 612 includes a second capacitor C2.

The first driving transistor T31 has a control electrode electrically connected to the first sub-node of first node N1-1, a first electrode electrically connected to the second node N2, and a second electrode electrically connected to the first sub-node of third node N3-1.

The first compensation transistor T21 has a control electrode electrically connected to the second scanning signal terminal Gate1, a first electrode electrically connected to the first sub-node of first node N1-1, and a second electrode electrically connected to the first sub-node of third node N3-1.

The second light-emission control transistor T61 has a control electrode electrically connected to the light-emission control terminal EM, a first electrode electrically connected to the first sub-node of third node N3-1, and a second electrode electrically connected to the first electrode L11 of the first light emitting sub-element.

The first initialization transistor T11 has a control electrode electrically connected to the first reset signal terminal Reset1, a first electrode electrically connected to the first sub-node of third node N3-1, and a second electrode electrically connected to the first initialization signal terminal Vinit1.

The second initialization transistor T71 has a control electrode electrically connected to the second reset signal terminal Reset2, a first electrode electrically connected to the first electrode L11 of the first light emitting sub-element, and a second electrode electrically connected to the second initialization signal terminal Vinit2.

The first capacitor C1 may include a first plate C1a and a second plate C1b. The first plate C1a of the first capacitor C1 is electrically connected to the first electrode of the first light-emission control transistor T51, and the second plate C1b of the first capacitor C1 is electrically connected to the first sub-node of first node N1-1.

The second driving transistor T32 has a control electrode electrically connected to the second sub-node of first node N1-2, a first electrode electrically connected to the second node N2, and a second electrode electrically connected to the second sub-node of third node N3-2.

The second compensation transistor T22 has a control electrode electrically connected to the third scanning signal terminal Gate2, a first electrode electrically connected to the second sub-node of third node N3-2, and a second electrode electrically connected to the second sub-node of first node N1-2.

The fourth light-emission control transistor T62 has a control electrode electrically connected to the light-emission control terminal EM, a first electrode electrically connected to the second sub-node of third node N3-2, and a second electrode electrically connected to the first electrode L21 of the second light emitting sub-element.

The third initialization transistor T12 has a control electrode electrically connected to the first reset signal terminal Reset1, a first electrode electrically connected to the first initialization signal terminal Vinit1, and a second electrode electrically connected to the second sub-node of third node N3-2.

The fourth initialization transistor T72 has a control electrode electrically connected to the second reset signal terminal Reset2, a first electrode electrically connected to the first electrode L21 of the second light emitting sub-element, and a second electrode electrically connected to the second initialization signal terminal Vinit2.

The second capacitor C2 may include a third plate C2a and a fourth plate C2b. The third plate C2a of the second capacitor C2 is electrically connected to the first electrode of the first light-emission control transistor T5, and the fourth plate C2b of the second capacitor C2 is electrically connected to the second sub-node of first node N1-2.

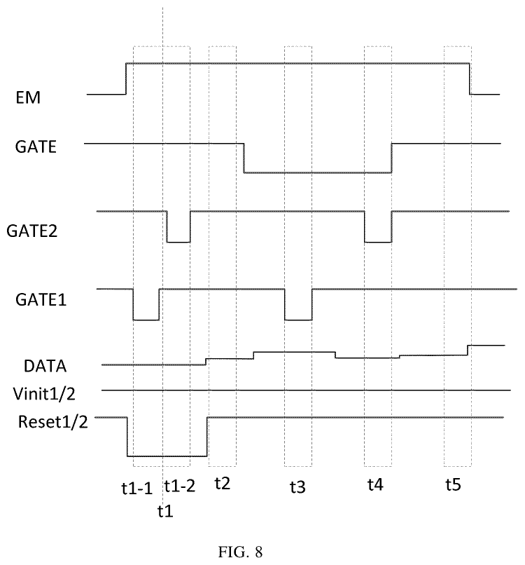

FIG. 8 shows a working sequence diagram of at least one embodiment of a driving method for the pixel shown in FIG. 7.

Exemplarily, in some embodiments of the present disclosure, referring to FIG. 6 to FIG. 8, an operation of the pixel circuit may include the following stages in sequence.

In a first sub-stage of first time period t1-1, in response to a first reset signal Reset1 and a second scanning signal Gate1, the first initialization sub-circuit 711 and the first compensation sub-circuit 411 are turned on, so that a first initialization signal from the first initialization signal terminal Vinit1 is output to the first sub-node of first node N1-1.

In a second sub-stage of first time period t1-2, in response to the first reset signal Reset1 and a third scanning signal Gate3, the third initialization sub-circuit 713 and the second compensation sub-circuit 412 are turned on, so that a first initialization signal from the first initialization signal terminal Vinit1 is output to the second sub-node of first node N1-2.

The first sub-stage of first time period t1-1 and the second sub-stage of first time period t1-2 are in a reset stage of an image frame, the first sub-stage of first time period t1-1 is before the second sub-stage of first time period t1-2, and the first sub-stage of first time period t1-1 does not overlap with the second sub-stage of first time period t1-2.

Through timing control, the first initialization signal may be sequentially written to the first sub-node of first node N1-1 and the second sub-node of first node N1-2 in different time periods to achieve voltage reset.

In a third time period t3, in response to a first scanning signal Gate and a second scanning signal Gate1, the data writing sub-circuit 21 and the first compensation sub-circuit 411 are turned on, so that a first data sub-signal DL11 from the data signal terminal Data is transmitted to the first sub-node of first node N1-1.

In a fourth time period t4, in response to the first scanning signal Gate and a third scanning signal Gate2, the data writing sub-circuit 21 and the second compensation sub-circuit 412 are turned on, so that a second data sub-signal DL12 from the data signal terminal Data is transmitted to the second sub-node of first node N1-2. The third time period t3 and the fourth time period t4 are in a writing stage of an image frame, the fourth time period T4 is after the third time period T3, and the fourth time period T4 does not overlap with the third time period T3.

In a case that the data writing sub-circuit is turned on, by controlling the first compensation sub-circuit 411 and the second compensation sub-circuit 412 to turn on in different time periods, the data signal provided by the same data signal line may be written to the first sub-pixel driving circuit and the second sub-pixel driving circuit respectively in two different time periods. Since the third time period t3 and the fourth time period t4 do not overlap each other, the data signals of the two sub-pixel driving circuits do not interfere with each other, and the purpose of providing the data signal to two different sub-pixels may be achieved. For example, the first data sub-signal DL11 may be provided to the first sub-pixel driving circuit in the third time period t3, and the second data sub-signal DL12 may be provided to the second sub-pixel driving circuit in the fourth time period t4.

In a fifth time period, in response to a light-emission control signal of the light-emission control terminal, the first light-emission control sub-circuit 511, the second light-emission control sub-circuit 512, the third light-emission control sub-circuit 513 and the fourth light-emission control sub-circuit 514 are turned on, and the first light emitting sub-element L1 and the second light emitting sub-element L2 emit light.

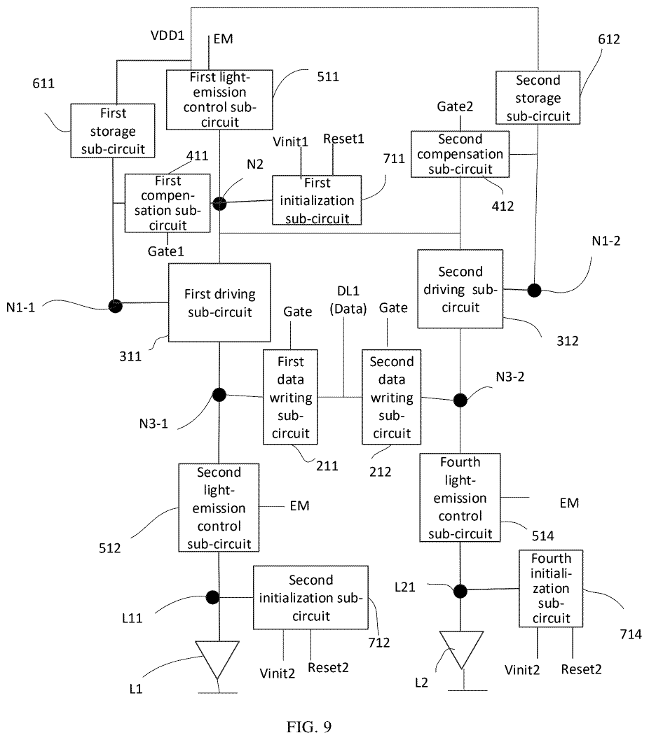

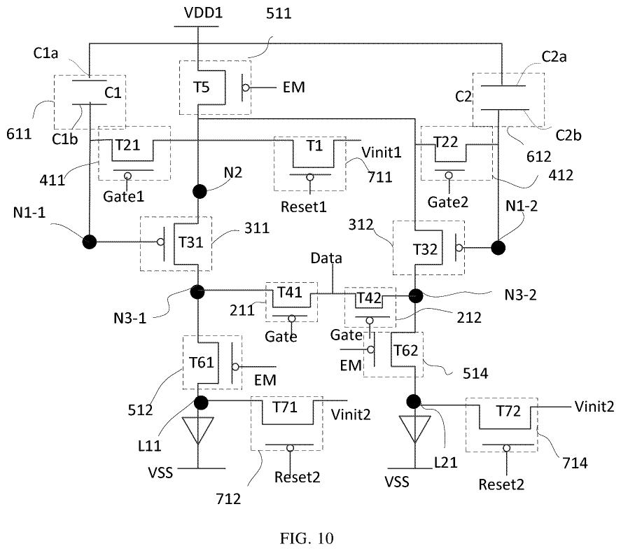

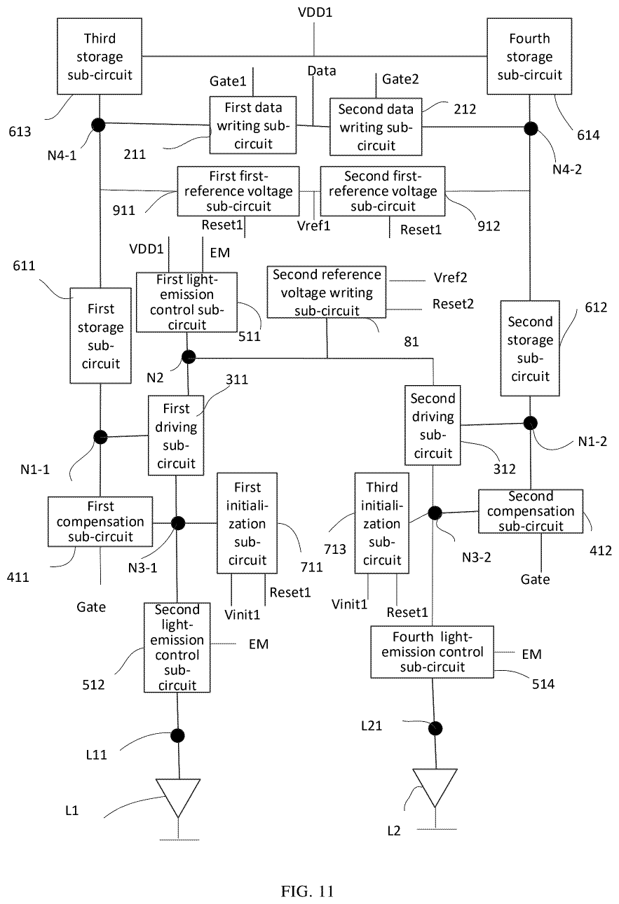

FIG. 9 shows a structural block diagram of a pixel circuit according to some embodiments of the present disclosure. FIG. 10 shows an equivalent circuit diagram of a pixel circuit according to some embodiments of the present disclosure.

Exemplarily, in some embodiments of the present disclosure, referring to FIG. 9, the first sub-pixel driving circuit and the second sub-pixel driving circuit share a first light-emission control sub-circuit 511 and a first initialization sub-circuit 711. The first light-emission control sub-circuit 511 is coupled to the first voltage terminal VDD1, the light-emission control terminal EM and the second node N2. The first light-emission control sub-circuit 511 is configured to write a first voltage received at the first voltage terminal VDD1 to the second node N2 in response to a light-emission control signal received at the light-emission control terminal EM. The first sub-pixel driving circuit and the second sub-pixel driving circuit are coupled at the second node N2, and the first light-emission control sub-circuit 511 may write a first voltage to the first sub-pixel driving circuit and the second sub-pixel driving circuit respectively through the second node N2. The first initialization sub-circuit 711 is coupled to the first reset signal terminal Reset1, the first initialization signal terminal Vinit1 and the second node N2. The first initialization sub-circuit 711 is configured to transmit a first initialization signal received at the first initialization signal terminal Vinit1 to the second node N2 to initialize a potential of the second node N2 in response to a first reset signal received at the first reset signal terminal Reset1.

The first sub-pixel driving circuit and the second sub-pixel driving circuit share at least some transistors, so that the number of transistors in the driving circuit may be reduced, which helps improve product resolution and yield.

Exemplarily, in some embodiments of the present disclosure, continuing to refer to FIG. 9, the first sub-pixel driving circuit may further include a first data writing sub-circuit 211, which is coupled to the data signal terminal Data, the first scanning signal terminal Gate and the first sub-node of third node N3-1. The first data writing sub-circuit 211 is configured to write a data signal received at the data signal terminal Data to the first sub-node of third node N3-1 in response to a first scanning signal received at the first scanning signal terminal Gate. The second sub-pixel driving circuit may further include a second data writing sub-circuit 212, which is coupled to the data signal terminal Data, the first scanning signal terminal Gate and the second sub-node of third node N3-2. The second data writing sub-circuit 212 is configured to write a data signal received at the data signal terminal Data to the second sub-node of third node N3-2 in response to a first scanning signal received at the first scanning signal terminal Gate. The data signal terminal coupled to the first data writing sub-circuit 211 and the data signal terminal coupled to the second data writing sub-circuit 212 may be coupled to the same data signal line, such as the first data signal line DL1. That is to say, the first sub-pixel driving circuit and the second sub-pixel driving circuit may share the data signal line, so that the number of data signal lines may be reduced, which helps save the wiring space and IC chips, achieve a narrow-bezel display substrate, and lower costs.

Exemplarily, continuing to refer to FIG. 9, the first sub-pixel driving circuit includes a first storage sub-circuit 611, a first compensation sub-circuit 411 and a first driving sub-circuit 311. The first storage sub-circuit 611 is coupled to the first sub-node of first node N1-1 and the first voltage terminal VDD1. The first compensation sub-circuit 411 is coupled to the second scanning signal terminal Gate1, the first sub-node of first node N1-1, and the second node N2. The first compensation sub-circuit 411 is configured to transmit a first data sub-signal from the data signal terminal Data to the first sub-node of first node N1-1 in response to a second scanning signal received at the second scanning signal terminal Gate1. The first driving sub-circuit 311 is coupled to the first sub-node of first node N1-1, the second node N2, and the first sub-node of third node N3-1. The second sub-pixel driving circuit includes a second storage sub-circuit 612, a second compensation sub-circuit 412 and a second driving sub-circuit 312. The second storage sub-circuit 612 is coupled to the second sub-node of first node N1-2 and the first voltage terminal VDD1, that is, the first storage sub-circuit 611 and the second storage sub-circuit 612 are coupled at the first voltage terminal VDD1. The second compensation sub-circuit 412 is coupled to the third scanning signal terminal Gate2, the second sub-node of first node N1-2, and the second node N2. The second compensation sub-circuit 412 is configured to transmit a second data sub-signal from the data signal terminal Data to the second sub-node of first node N1-2 in response to a third scanning signal received at the third scanning signal terminal Gate2. The second driving sub-circuit 312 is coupled to the second sub-node of first node N1-2, the second node N2, and the second sub-node of third node N3-2. The second driving sub-circuit 312 is configured to generate a second driving current in response to a voltage of the second sub-node of first node N1-2, and the second driving current is used to drive the second light emitting sub-element to emit light.

Exemplarily, the first sub-pixel driving circuit may further include a second light-emission control sub-circuit 512 and a second initialization sub-circuit 712. The second light-emission control sub-circuit 512 is coupled to the light-emission control terminal EM, the first sub-node of third node N3-1, and the first electrode L11 of the first light emitting sub-element. The second initialization sub-circuit 712 is coupled to the second reset signal terminal Reset2, the first electrode L11 of the first light emitting sub-element, and the second initialization signal terminal Vinit2. The second sub-pixel driving circuit may further include a fourth light-emission control sub-circuit 514 and a fourth initialization sub-circuit 714. The fourth light-emission control sub-circuit 514 is coupled to the light-emission control terminal EM, the second sub-node of third node N3-2, and the first electrode L21 of the second light emitting sub-element. The fourth initialization sub-circuit 714 is coupled to the second reset signal terminal Reset2, the first electrode L21 of the second light emitting sub-element, and the second initialization signal terminal Vinit2.

Exemplarily, in some embodiments of the present disclosure, referring to FIG. 10, the first light-emission control sub-circuit 511 includes a light-emission control transistor T5, which has a control electrode coupled to the light-emission control terminal EM, a first electrode coupled to the first voltage terminal VDD1 and a second electrode coupled to the second node N2.

The first initialization sub-circuit 711 includes an initialization transistor T1, which has a control electrode coupled to the first reset signal terminal Reset1, a first electrode coupled to the second node N2 and a second electrode coupled to the first initialization signal terminal Vinit1.

The first data writing sub-circuit 211 includes a first data writing transistor T41, and the second data writing sub-circuit 212 includes a second data writing transistor T42. The first data writing transistor T41 has a control electrode coupled to the first scanning signal terminal Gate, a first electrode coupled to the first sub-node of third node N3-1, and a second electrode coupled to the first electrode of the second data writing transistor T42. The second data writing transistor T42 has a control electrode coupled to the first scanning signal terminal Gate and a second electrode coupled to the second sub-node of third node N3-2.

Exemplarily, the first storage sub-circuit 611 may further include a first capacitor C1, the first compensation sub-circuit 411 may further include a first compensation transistor T21, the first driving sub-circuit 311 may further include a first driving transistor T31, the second light-emission control sub-circuit 512 may further include a second light-emission control transistor T61, and the second initialization sub-circuit 712 may further include a second initialization transistor T71.

Exemplarily, the second storage sub-circuit 612 may further include a second capacitor C2, the second compensation sub-circuit 412 may further include a second compensation transistor T22, the second driving sub-circuit 312 may further include a second driving transistor T32, the fourth light-emission control sub-circuit 514 may further include a fourth light-emission control transistor T62, and the fourth initialization sub-circuit 714 may further include a fourth initialization transistor T72.

Exemplarily, in some embodiments of the present disclosure, a timing sequence of the equivalent circuit diagram in FIG. 10 may be the same as that in FIG. 8, which will not be repeated here.

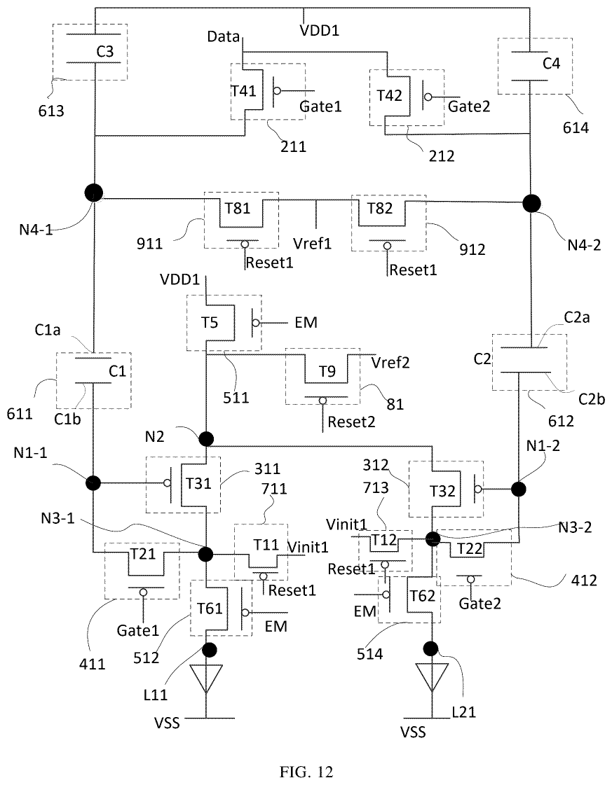

FIG. 11 shows a structural block diagram of a pixel circuit according to some embodiments of the present disclosure. FIG. 12 shows an equivalent circuit diagram of a pixel circuit according to some embodiments of the present disclosure.

Exemplarily, in some embodiments of the present disclosure, referring to FIG. 11, the first sub-pixel driving circuit and the second sub-pixel driving circuit share a first light-emission control sub-circuit 511 and a second reference voltage writing sub-circuit 81. The first light-emission control sub-circuit 511 is coupled to the first voltage terminal VDD1, the light-emission control terminal EM and the second node N2. The first light-emission control sub-circuit 511 is configured to write a first voltage received at the first voltage terminal VDD to the second node N2 in response to a light-emission control signal received at the light-emission control terminal EM. The second reference voltage writing sub-circuit 81 is coupled to the second reset signal terminal Reset2, the second reference voltage terminal Vref2 and the second node N2. The second reference voltage writing sub-circuit 81 is configured to write a second reference voltage received at the second reference voltage terminal Vref2 to the second node N2 in response to a second reset signal received at the second reset signal terminal Reset2.

Exemplarily, continuing to refer to FIG. 11, the first sub-pixel driving circuit further includes a first data writing sub-circuit 211, a first storage sub-circuit 611 and a third storage sub-circuit 613. The first data writing sub-circuit 211 is coupled to the data signal terminal Data, the second scanning signal terminal Gate1, and the first sub-node of fourth node N4-1. The first data writing sub-circuit 211 is configured to write a data signal received at the data signal terminal Data to the first sub-node of fourth node N4-1 in response to a second scanning signal received at the second scanning signal terminal Gate1. The first storage sub-circuit 611 is coupled to the first sub-node of first node N1-1 and the first sub-node of fourth node N4-1. The third storage sub-circuit 613 is coupled to the first sub-node of fourth node N4-1 and the first voltage terminal VDD1. The second sub-pixel driving circuit further includes a second data writing sub-circuit 212, a second storage sub-circuit 612 and a fourth storage sub-circuit 614. The second data writing sub-circuit 212 is coupled to the data signal terminal Data, the third scanning signal terminal Gate2, and the second sub-node of fourth node N4-2. The second data writing sub-circuit 212 is configured to write a data signal received at the data signal terminal Data to the second sub-node of fourth node N4-2 in response to a third scanning signal received at the third scanning signal terminal Gate2. The second storage sub-circuit 612 is coupled to the second sub-node of first node N1-2 and the second sub-node of fourth node N4-2. The fourth storage sub-circuit 614 is coupled to the second sub-node of fourth node N4-2 and the first voltage terminal VDD1.

Exemplarily, the first data writing sub-circuit 211 and the second data writing sub-circuit 212 share a data wire. As a result, the number of data signal lines may be reduced, which helps achieve a narrow bezel, and also helps reduce the number of driver IC and lower costs.

The pixel driving circuit further includes a first first-reference voltage sub-circuit 911 and a second first-reference voltage sub-circuit 912. The first first-reference voltage sub-circuit 911 is coupled to the first sub-node of fourth node N4-1, the first reset signal terminal Reset1 and the first reference voltage signal terminal Vref1. The first first-reference voltage writing sub-circuit 911 is configured to write a first reference voltage received at the first reference signal terminal Vref1 to the first sub-node of fourth node N4-1 in response to a first reset signal received at the first reset signal terminal Reset1. The second first-reference voltage sub-circuit 912 is coupled to the second sub-node of fourth node N4-2, the first reset signal terminal Reset1 and the first reference voltage signal terminal Vref1. The second first-reference voltage sub-circuit 912 is configured to write a first reference voltage received at the first reference voltage signal terminal Vref1 to the second sub-node of fourth node N4-2 in response to a first reset signal received at the first reset signal terminal Reset1.

Exemplarily, the first sub-pixel driving circuit may further include a first compensation sub-circuit 411, a first driving sub-circuit 311, a first initialization sub-circuit 711 and a second light-emission control sub-circuit 512. The first compensation sub-circuit 411 is coupled to the first scanning signal terminal Gate, the first sub-node of first node N1-1, and the first sub-node of third node N3-1. The first driving sub-circuit 311 is coupled to the first sub-node of first node N1-1, the second node N2, and the first sub-node of third node N3-1. The first initialization sub-circuit 711 is coupled to the first reset signal terminal Reset1, the first sub-node of third node N3-1, and the first initialization signal terminal Vinit1. The second light-emission control sub-circuit 512 is coupled to the light-emission control terminal EM, the first sub-node of third node N3-1, and the first electrode L11 of the first light emitting sub-element.

The second sub-pixel driving circuit DX2 may further include a second compensation sub-circuit 412, a second driving sub-circuit 312, a third initialization sub-circuit 713 and a fourth light-emission control sub-circuit 514. The second compensation sub-circuit 412 is coupled to the first scanning signal terminal Gate, the second sub-node of first node N1-2, and the second sub-node of third node N3-2. The second driving sub-circuit 312 is coupled to the second sub-node of first node N1-2, the second node N2, and the second sub-node of third node N3-2. The third initialization sub-circuit 713 is coupled to the first reset signal terminal Reset1, the second sub-node of third node N3-2, and the first initialization signal terminal Vinit1. The fourth light-emission control sub-circuit 514 is coupled to the light-emission control terminal EM, the second sub-node of third node N3-2, and the first electrode L21 of the second light emitting sub-element.

Exemplarily, referring to FIG. 11 and FIG. 12, the first light-emission control sub-circuit 511 includes a light-emission control transistor T5, the second reference voltage writing sub-circuit 81 includes a second reference voltage writing transistor T9, the first data writing sub-circuit 211 includes a first data writing transistor T41, the first storage sub-circuit 611 includes a first capacitor C1, the third storage sub-circuit 613 includes a third capacitor C3, the first first-reference voltage sub-circuit 911 includes a first first-reference voltage sub-transistor T81, the second first-reference voltage writing sub-circuit 912 include a second first-reference voltage sub-transistor T82, the first compensation sub-circuit 411 includes a first compensation transistor T21, the first driving sub-circuit 311 includes a first driving transistor T31, the first initialization sub-circuit 711 includes a first initialization transistor T11, the second light-emission control sub-circuit 512 includes a second light-emission control transistor T61, the second compensation sub-circuit 412 includes a second compensation transistor T22, the second driving sub-circuit 312 includes a second driving transistor T32, the third initialization sub-circuit 713 includes a third initialization transistor T12, and the fourth light-emission control sub-circuit 514 includes a fourth light-emission control transistor T62.

Exemplarily, the first first-reference voltage sub-transistor T81 has a control electrode coupled to the first reset signal terminal Reset1, a first electrode coupled to the first sub-node of fourth node N4-1, and a second electrode coupled to the first reference voltage line Vref1. The second first-reference voltage sub-transistor T82 has a control electrode coupled to the first reset signal terminal Reset1, a first electrode coupled to the first reference voltage line Vref1, and a second electrode coupled to the second sub-node of fourth node N4-2.

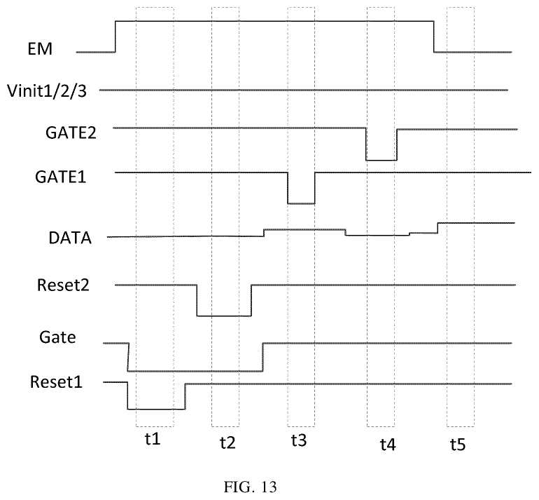

FIG. 13 shows a working sequence diagram of at least one embodiment of a driving method for the pixel shown in FIG. 12.

Exemplarily, in some embodiments of the present disclosure, referring to FIG. 11 to FIG. 13, the operation of the pixel circuit may include the following stages in sequence.

In a first time period t1, in response to a first scanning signal provided by the first scanning signal terminal Gate and a first reset signal provided by the first reset signal terminal Reset1, the first initialization sub-circuit 711, the first compensation sub-circuit 411, the third initialization sub-circuit 713, the second compensation sub-circuit 412, the first first-reference voltage sub-circuit 911 and the second first-reference voltage sub-circuit 912 are all turned on to charge the first sub-node of first node N1-1 and the second sub-node of first node N1-2.

In a second time period t2, in response to a second reset signal provided by the second reset signal terminal Reset2 and a first scanning signal provided by the first scanning signal terminal Gate, the second reference voltage writing sub-circuit 81, the first compensation sub-circuit 411 and the second compensation sub-circuit 412 are all turned on, so that a second reference voltage from the second reference voltage line Vref2 is transmitted to the first sub-node of first node N1-1 and the second sub-node of first node N1-2 respectively.

In a third time period t3, in response to a second scanning signal provided by the second scanning signal terminal Gate1, the first data writing sub-circuit 211 is turned on, so that a data signal from the data signal line is transmitted to the first sub-node of fourth node N4-1; and the data signal is written to the first sub-node of first node N1-1 by using a bootstrap effect of the capacitor (i.e., a voltage between two ends of the capacitor may not change instantaneously, and when a voltage increases on one end of the capacitor, the other end also changes to maintain a voltage difference).

In a fourth time period t4, in response to a third scanning signal at the third scanning signal terminal Gate2, the second data writing sub-circuit 212 is turned on, so that a data signal from the data signal line is transmitted to the second sub-node of fourth node N4-2; and the data signal is written to the second sub-node of first node N1-2 by using the bootstrap effect of the capacitor.

In a fifth time period, in response to a light-emission control signal at the light-emission control terminal, the first light-emission control sub-circuit 511, the second light-emission control sub-circuit 512 and the fourth light-emission control sub-circuit 514 are all turned on, and the first light emitting sub-element L1 and the second light emitting sub-element L2 emit light.

By using a voltage jump-based data signal writing method, it is possible to instantaneously write data signals to the first sub-node of first node N1-1 and the second sub-node of first node N1-2, which may improve the situation of insufficient charging of the display substrate. For example, it may solve an insufficient charging time caused by an increase in the driving frequency of a high-resolution display substrate.

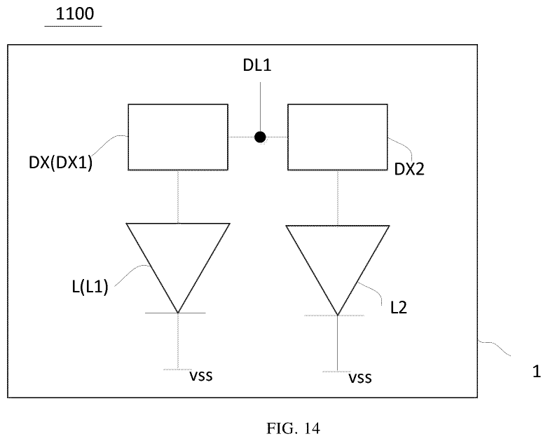

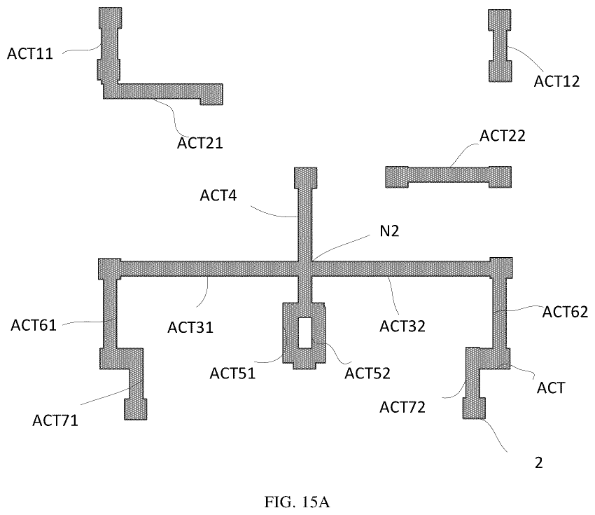

FIG. 14 shows a structural block diagram of a display substrate according to some embodiments of the present disclosure.

Referring to FIG. 14, exemplarily, the present disclosure provides a display substrate 1100. The display substrate 1100 includes: a base substrate 1; a pixel circuit DX on the base substrate 1, where the pixel circuit DX includes a first sub-pixel driving circuit DX1 and a second sub-pixel driving circuit DX2; and a light emitting element L on the base substrate, where the light emitting element includes a first light emitting sub-element L1 and a second light emitting sub-element L2, the first light emitting sub-element L1 is coupled to the first sub-pixel driving circuit DX1, and the second light emitting sub-element L2 is coupled to the second sub-pixel driving circuit DX2. The first sub-pixel driving circuit DX1 and the second sub-pixel driving circuit DX2 may share a data signal line.

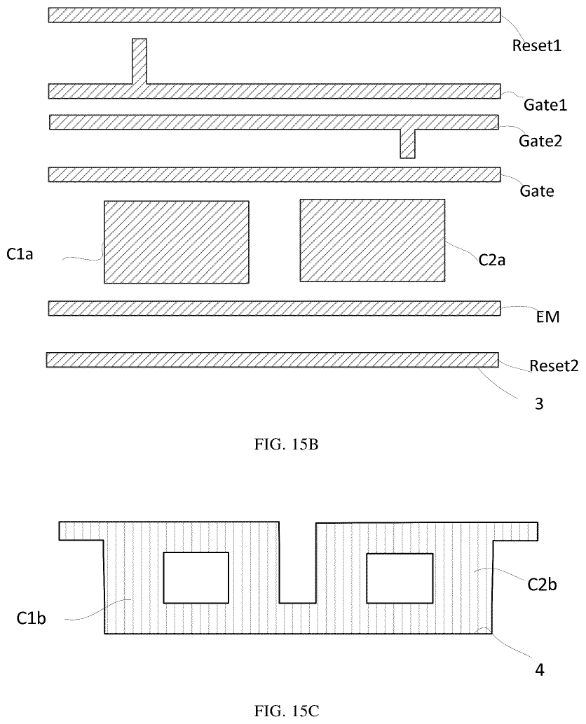

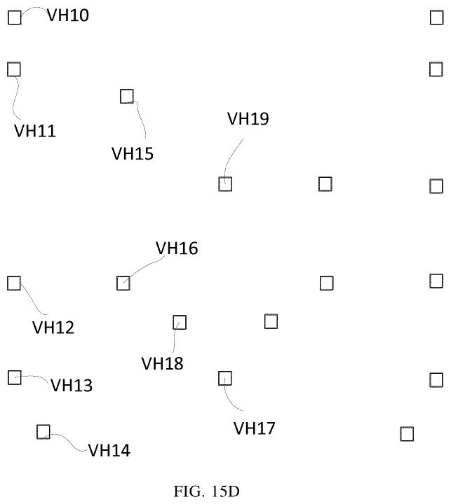

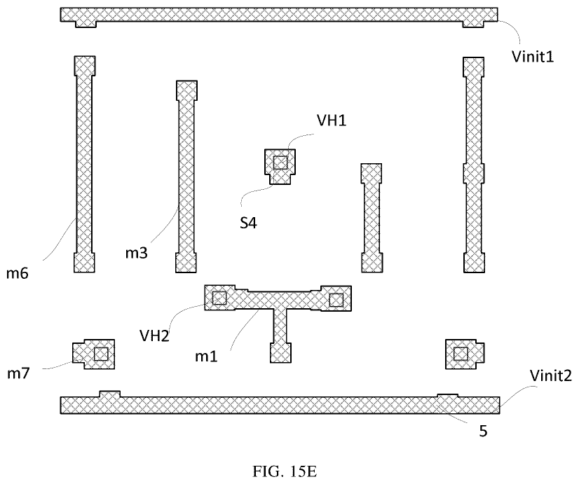

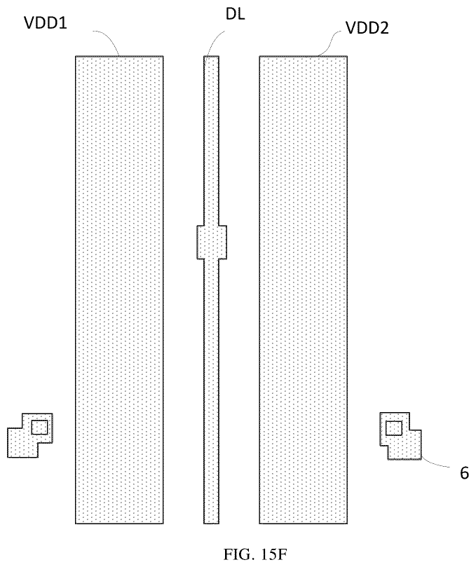

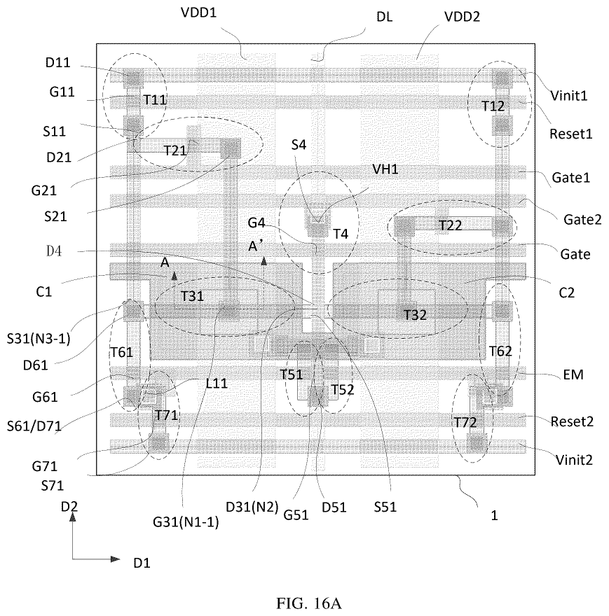

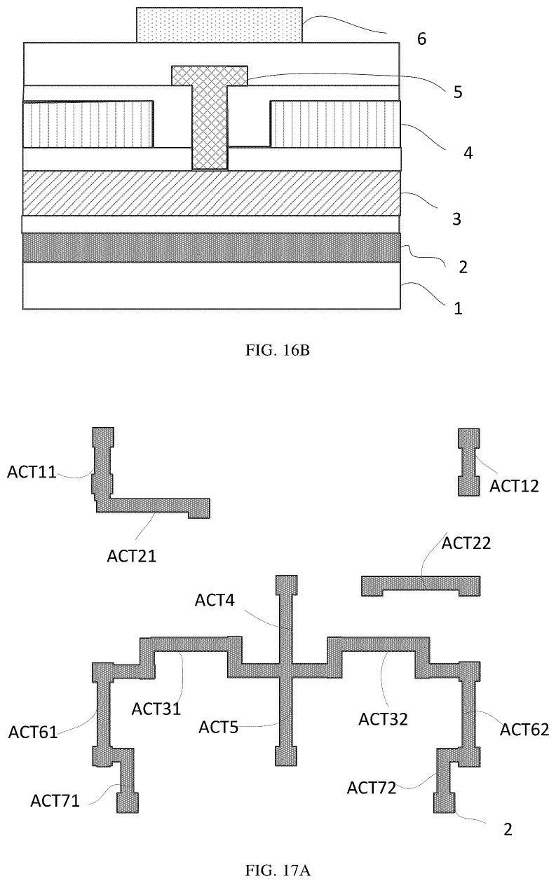

FIG. 15A shows a schematic diagram of a planar structure of a first semiconductor layer in a pixel circuit according to exemplary embodiments of the present disclosure; FIG. 15B shows a schematic diagram of a planar structure of a first conductive layer in a pixel circuit according to exemplary embodiments of the present disclosure; FIG. 15C shows a schematic diagram of a planar structure of a second conductive layer in a pixel circuit according to exemplary embodiments of the present disclosure; FIG. 15D shows a schematic diagram of some via holes according to exemplary embodiments of the present disclosure; FIG. 15E shows a schematic diagram of a planar structure of a third conductive layer in a pixel circuit according to exemplary embodiments of the present disclosure; FIG. 15F shows a schematic diagram of a planar structure of a fourth conductive layer in a pixel circuit according to exemplary embodiments of the present disclosure; FIG. 16A shows a schematic diagram of a planar structure of a combination of the first semiconductor layer, the first conductive layer, the second conductive layer, the third conductive layer and the fourth conductive layer in a pixel circuit according to exemplary embodiments of the present disclosure; FIG. 16B shows a schematic partial cross-sectional view of the pixel circuit according to embodiments of the present disclosure, taken along line AA′ in FIG. 16A.

Exemplarily, referring to FIG. 1 and FIG. 15A to FIG. 16A, in some embodiments of the present disclosure, the display substrate 1100 includes: a base substrate 1; a plurality of sub-pixels SP on the base substrate 1, where the plurality of sub-pixels SP are arranged in an array in a first direction and a second direction; and a plurality of pixel circuits DX used to drive the plurality of sub-pixels SP. The plurality of sub-pixels SP include a first sub-pixel SP1 and a second sub-pixel SP2, which are adjacent in the first direction or the second direction. The plurality of pixel circuits DX include a first sub-pixel driving circuit DX1 used to drive the first sub-pixel SP1 and a second sub-pixel driving circuit DX2 used to drive the second sub-pixel SP2. The first direction intersects with the second direction.

Referring to FIG. 16B, the display substrate 1100 includes: a first semiconductor layer 2 on the base substrate 1; a first conductive layer 3 on a side of the first semiconductor layer 2 away from the base substrate 1; a second conductive layer 4 on a side of the first conductive layer 3 away from the base substrate 1; a third conductive layer 5 on a side of the second conductive layer 4 away from the base substrate 1; and a fourth conductive layer 6 on a side of the third conductive layer 4 away from the base substrate 1.

The display substrate 110 further includes a first scanning signal line Gate extending in the first direction D1 and a data signal line DL extending in the second direction D2. The first scanning signal line Gate is located in the first conductive layer 3, and the data signal line DL is located in the fourth conductive layer 6.

Exemplarily, the first sub-pixel driving circuit DX1 and the second sub-pixel driving circuit DX2 share a data writing sub-circuit 21 and a data signal line DL. The data writing sub-circuit 21 includes a data writing transistor T4, and the data writing transistor T4 includes a data writing active layer ACT4, a control electrode G4 and a second electrode S4. The data writing active layer ACT4 is located in the first semiconductor layer 2, and the second electrode S4 is located in the third conductive layer 5.

An orthographic projection of the data writing active layer ACT4 on the base substrate 1 overlaps at least partially with an orthographic projection of the first scanning signal line Gate on the base substrate 1, and a portion of the data writing active layer ACT4 overlapping with the first scanning signal line Gate is the control electrode G4 of the data writing transistor 21. The second electrode S4 of the data writing transistor is electrically connected to the data signal line DL through a first via hole VH1 and electrically connected to a second electrode region of the data writing active layer ACT4 through a nineteenth via hole VH19.

Through the design of adjacent sub-pixels sharing a data signal line and a data writing transistor, the wiring space may be saved, which helps achieve a narrow bezel, and the number of IC chips may be reduced, which may help lower costs. Furthermore, sharing at least some transistors may reduce the number of transistors and the number of via holes of the display substrate, which helps improve the yield of the display substrate and the layout of subsequent high-resolution product.

The first sub-pixel driving circuit DX1 further includes a first driving sub-circuit 311, a first compensation sub-circuit 411, a first light-emission control sub-circuit 511, a first storage sub-circuit 611, a first initialization sub-circuit 711, a second initialization sub-circuit 712 and a second light-emission control sub-circuit 512. The first driving sub-circuit 311 includes a first driving transistor T31, the first compensation sub-circuit 411 includes a first compensation transistor T21, the first light-emission control sub-circuit 511 includes a first light-emission control transistor T51, the first storage sub-circuit 611 includes a first capacitor C1, the first initialization sub-circuit 711 includes a first initialization transistor T11, the second initialization sub-circuit 712 includes a second initialization transistor T71, and the second light-emission control sub-circuit 512 includes a second light-emission control transistor T61.

The second sub-pixel driving circuit DX2 further includes a second driving sub-circuit 312, a second compensation sub-circuit 412, a third light-emission control sub-circuit 513, a second storage sub-circuit 612, a third initialization sub-circuit 713, a fourth initialization sub-circuit 714 and a fourth light-emission control sub-circuit 514. The second driving sub-circuit 312 includes a second driving transistor T32, the second compensation sub-circuit 412 includes a second compensation transistor T22, the third light-emission control sub-circuit 513 includes a third light-emission control transistor T52, the second storage sub-circuit 611 includes a second capacitor C2, the third initialization sub-circuit 713 includes a third initialization transistor T12, the fourth initialization sub-circuit 714 includes a fourth initialization transistor T72, and the fourth light-emission control sub-circuit 514 includes a fourth light-emission control transistor T62.

Exemplarily, the plurality of transistors in the first sub-pixel driving circuit DX1 and the plurality of transistors in the second sub-pixel driving circuit DX2 may be mirrored on left and right sides of the data signal line. It should be noted that although adjacent sub-pixel driving circuits are shown as being mirrored on left and right sides in the embodiment of the present disclosure, embodiments of the present disclosure are not limited to this. The adjacent sub-pixel driving circuits may also be mirrored on upper and lower sides.

Exemplarily, the plurality of transistors may include an active layer ACT, and the active layer ACT may be located in the first semiconductor layer 2. An orthographic projection of the active layer ACT on the base substrate overlaps at least partially with an orthographic projection of the first conductive layer 2 on the base substrate, and a portion of the active layer ACT overlapping with the projection of the first conductive layer 2 may form the control electrodes of the plurality of transistors.

For example, the first driving transistor T31 includes a first driving active layer ACT31, and the second driving transistor T32 includes a second driving active layer ACT32. The first driving active layer ACT31 and the second driving active layer ACT32 extend in straight lines in the first direction respectively, and the first driving active layer ACT31 and the second driving active layer ACT32 are symmetrical with respect to the data signal line DL.

Exemplarily, the first light-emission control transistor T51 includes a first light-emission control active layer ACT51, and the third light-emission control transistor T52 includes a third light-emission control active layer ACT52. At least part of the first light-emission control active layer ACT51 and the third light-emission control active layer ACT52 may be located on both sides of the data signal line.

Exemplarily, the data writing active layer ACT4, the first driving active layer ACT31, the second driving active layer ACT32, the first light-emission control active layer ACT51 and the third light-emission control active layer ACT52 may intersect at the second node N2.

The display substrate may further include a second scanning signal line Gate1, a third scanning signal line Gate2, a first initialization signal line Vinit1, a second initialization signal line Vinit2, a first reset signal line Reset1, a second reset signal line Reset2 and a light-emission control line EM that extend in the first direction, as well as a first power line VDD1 and a second power line VDD2 that extend in the second direction. The second scanning signal line Gate1, the third scanning signal line Gate2, the first reset signal line Reset1, the second reset signal line Reset2 and the light-emission control line EM are located in the first conductive layer 3, the first initialization signal line Vinit1 and the second initialization signal line Vinit2 are located in the third conductive layer 5, and the first power line VDD1 and the second power line VDD2 are located in the fourth conductive layer 6. The data signal line DL may be located between the first power line VDD1 and the second power line VDD2.

Exemplarily, the first capacitor C1 may include a first plate C1a and a second plate C1b, and the second capacitor C2 includes a third plate C2a and a fourth plate C2b. The first plate C1a and the third plate C2a are located in the first conductive layer 3 and spaced apart in the first direction. The second plate C1b and the fourth plate C2b are located in the second conductive layer 4 and electrically connected to each other.

The connection methods of the plurality of transistors will be described below by taking the plurality of transistors in the first sub-pixel driving circuit as an example.

Exemplarily, the first initialization transistor T11 may include a first initialization active layer ACT11, a control electrode G11, a first electrode D11 and a second electrode S11. The first initialization active layer ACT11 extends in the second direction, and a portion of the first initialization active layer ACT11 overlapping with the first reset signal line Reset1 is the control electrode G11 of the first initialization transistor T11. The first electrode D11 of the first initialization transistor T11 is electrically connected to the first initialization signal line Vinit1 through a tenth via hole VH10.

Exemplarily, the first compensation transistor T21 may include a first compensation active layer ACT21, a control electrode G21, a first electrode D21 and a second electrode S21. The first compensation active layer ACT21 extends in the first direction, and a portion of the first compensation active layer ACT21 overlapping with the second scanning signal line Gate1 is the control electrode G21 of the first compensation transistor T21. The first electrode D21 of the first compensation transistor T21 and the second electrode S11 of the first initialization transistor T11 are electrically connected to the first sub-node of third node N3-1 through an eleventh via hole VH11, a twelfth via hole VH12 and a sixth conductive transfer portion m6. The second electrode S21 of the first compensation transistor T21 is electrically connected to the first sub-node of first node N1-1 through a fifteenth via hole VH15, a sixteenth via hole VH16 and a third conductive transfer portion m3. The third conductive transfer portion m3 is located in the third conductive layer 5.

The first driving transistor T31 further includes a control electrode G31, a first electrode D31 and a second electrode S31. A portion of the active layer ACT31 of the first driving transistor T31 overlapping with the first plate C1a is the control electrode of the first driving transistor T31, the first electrode D31 of the first driving transistor T31 is electrically connected to the second node N2, and the second electrode S31 of the first driving transistor T31 is electrically connected to the first sub-node of third node N3-1.

The data writing transistor T4 further includes a first electrode D4, which is electrically connected to the second node N2.

The first light-emission control transistor T51 further includes a control electrode G51, a first electrode D51 and a second electrode S51. A portion of the active layer ACT51 of the first light-emission control transistor T51 overlapping with the light-emission control line EM is the control electrode G51 of the first light-emission control transistor T51. The first electrode D51 of the first light-emission control transistor T51 is electrically connected to the first power line VDD1 through a second via hole VH2, a seventeenth via hole VH17 and a first conductive transfer portion m1. The first electrode D51 of the first light-emission control transistor T51 may further be electrically connected to the second plate C1b through an eighteenth via hole VH18. The second electrode S51 of the first light-emission control transistor T51 is electrically connected to the second node N2.

The second light-emission control transistor T61 further includes an active layer ACT61, a control electrode G61, a first electrode D61 and a second electrode S61. A portion of the active layer ACT61 of the second light-emission control transistor T61 overlapping with the light-emission control line EM is the control electrode of the second light-emission control transistor T61. The first electrode D61 of the second light-emission control transistor T61 is electrically connected to the first sub-node of third node N3-1 through a twelfth via hole VH12, and the second electrode S61 of the second light-emission control transistor T61 is electrically connected to the first electrode L11 of the first light emitting sub-element through a thirteenth via hole VH13 and a seventh conductive transfer portion m7.

The second initialization transistor T71 further includes an active layer ACT71, a control electrode G71, a first electrode D71 and a second electrode S71. A portion of the active layer ACT71 of the second initialization transistor T71 overlapping with the second reset signal line Reset2 is the control electrode G71 of the second initialization transistor T71. The first electrode D71 of the second initialization transistor T71 is electrically connected to the first electrode L11 of the first light emitting sub-element through a thirteenth via hole VH13 and a seventh conductive transfer portion m7, and the second electrode S71 of the second initialization transistor T71 is electrically connected to the second initialization signal line Vinit2 through a fourteenth via hole VH14.

Exemplarily, the transistors in the second sub-pixel driving circuit may be connected in the same way as the corresponding transistors in the first sub-pixel driving circuit, which will not be repeated here.

It should be noted that although the pixel circuit shown in the embodiments of the present disclosure is a 7T1C driving circuit, the present disclosure is not limited to this. The embodiments of the present disclosure are also applicable to other known driving circuits, such as 3T1C, 5T1C, 5T2C, 8T2C and other driving circuits.

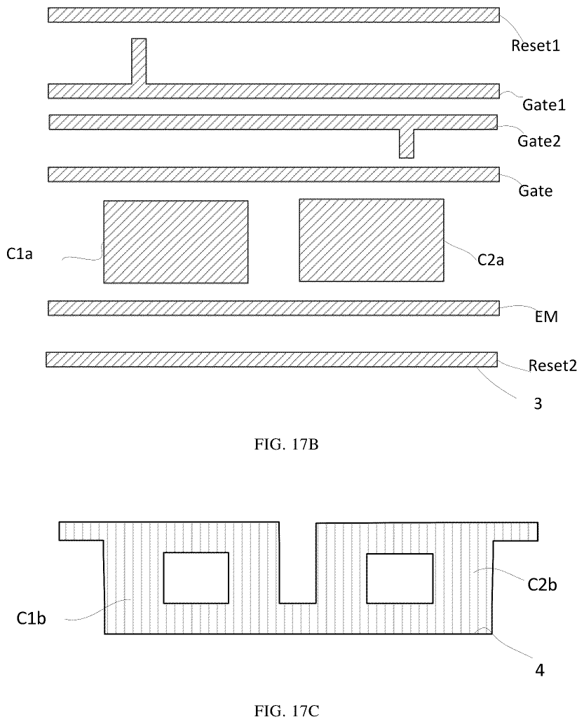

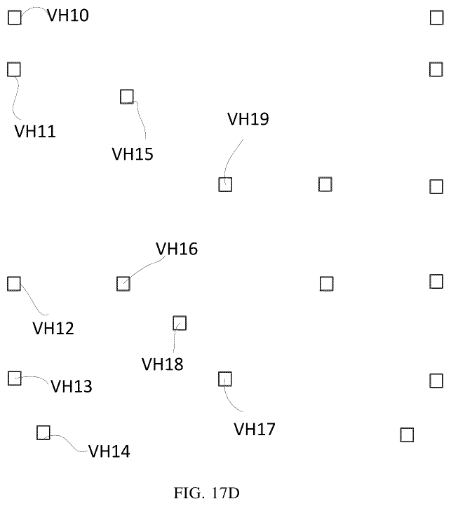

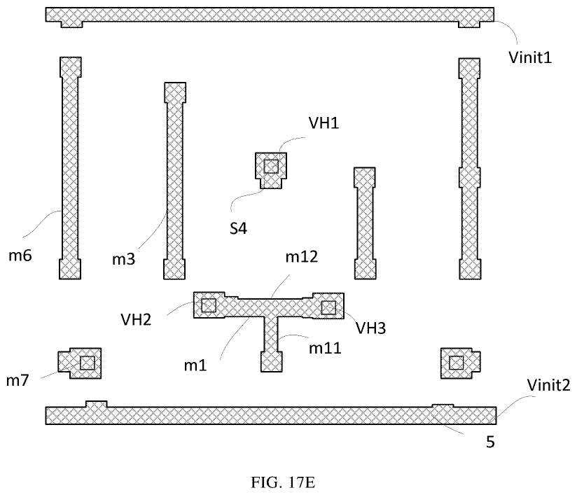

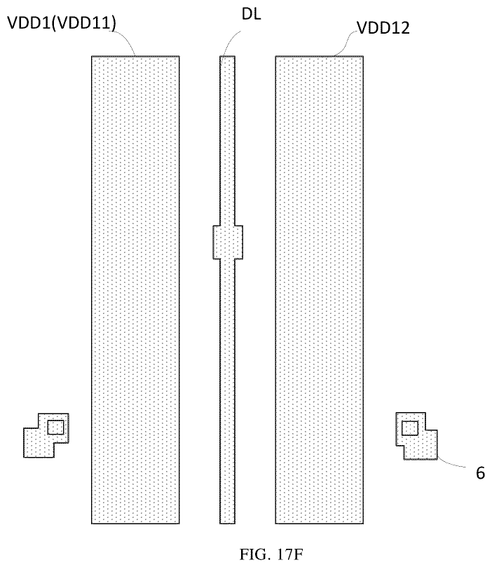

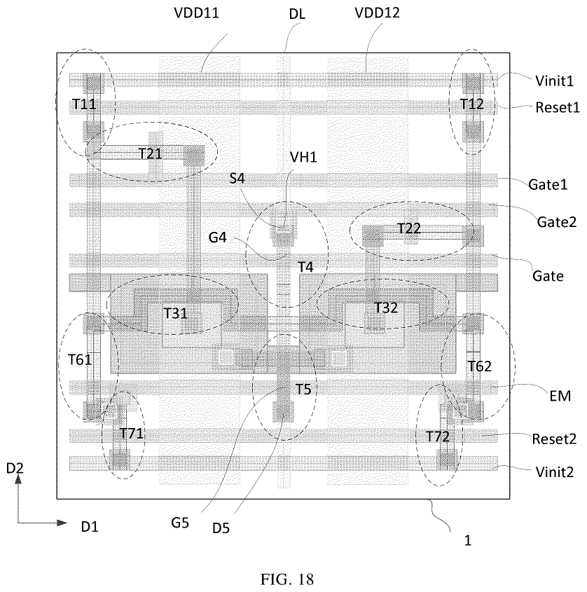

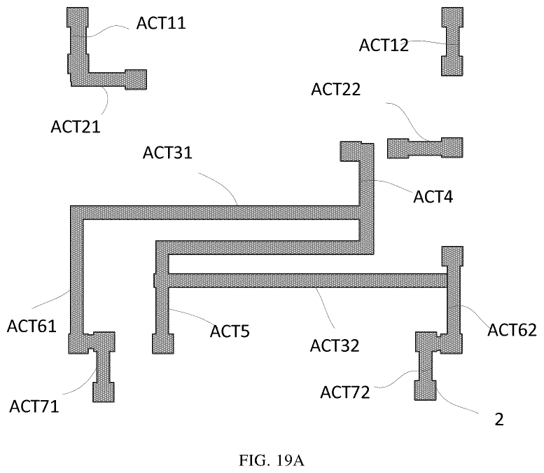

FIG. 17A shows a schematic diagram of a planar structure of a first semiconductor layer in a pixel circuit according to exemplary embodiments of the present disclosure; FIG. 17B shows a schematic diagram of a planar structure of a first conductive layer in a pixel circuit according to exemplary embodiments of the present disclosure; FIG. 17C shows a schematic diagram of a planar structure of a second conductive layer in a pixel circuit according to exemplary embodiments of the present disclosure; FIG. 17D shows a schematic diagram of some via holes according to exemplary embodiments of the present disclosure; FIG. 17E shows a schematic diagram of a planar structure of a third conductive layer in a pixel circuit according to exemplary embodiments of the present disclosure; FIG. 17F shows a schematic diagram of a planar structure of a fourth conductive layer in a pixel circuit according to exemplary embodiments of the present disclosure; FIG. 18 shows a schematic diagram of a planar structure of a combination of the first semiconductor layer, the first conductive layer, the second conductive layer, the third conductive layer and the fourth conductive layer in a pixel circuit according to exemplary embodiments of the present disclosure.

Exemplarily, in some embodiments of the present disclosure, referring to FIG. 1 and FIG. 17A to FIG. 18, the first sub-pixel driving circuit DX1 and the second sub-pixel driving circuit DX2 share a data writing sub-circuit, a data signal line DL and a first light-emission control sub-circuit.

The display substrate 1100 includes: a first semiconductor layer 2 on the base substrate 1; a first conductive layer 3 on a side of the first semiconductor layer 2 away from the base substrate 1; a second conductive layer 4 on a side of the first conductive layer 3 away from the base substrate 1; a third conductive layer 5 on a side of the second conductive layer 4 away from the base substrate 1; and a fourth conductive layer 6 on a side of the third conductive layer 4 away from the base substrate 1.

The display substrate may further include a first scanning signal line Gate, a second scanning signal line Gate1, a third scanning signal line Gate2, a first initialization signal line Vinit1, a second initialization signal line Vinit2, a first reset signal line Reset1, a second reset signal line Reset2 and a light-emission control line EM that extend in the first direction, as well as a first power line VDD1 and a data signal line DL that extend in the second direction. The first scanning signal line Gate, the second scanning signal line Gate1, the third scanning signal line Gate2, the first reset signal line Reset1, the second reset signal line Reset2 and the light-emission control line EM are located in the first conductive layer 3, the first initialization signal line Vinit1 and the second initialization signal line Vinit2 are located in the third conductive layer 5, and the first power line VDD1 and the data signal line DL are located in the fourth conductive layer 6.

The data writing sub-circuit includes a data writing transistor T4, and the data writing transistor T4 includes a data writing active layer ACT4, a control electrode G4 and a second electrode S4. The data writing active layer ACT4 is located in the first semiconductor layer 2, and the second electrode S4 is located in the third conductive layer 5. An orthographic projection of the data writing active layer ACT4 on the base substrate 1 overlaps at least partially with an orthographic projection of the first scanning signal line Gate on the base substrate 1, and a portion of the data writing active layer ACT4 overlapping with the first scanning signal line Gate is the control electrode G4 of the data writing transistor 21. The second electrode S4 of the data writing transistor is electrically connected to the data signal line DL through the first via hole VH1 and electrically connected to the second electrode region of the data writing active layer ACT4 through the nineteenth via hole VH19.

The first light-emission control sub-circuit 511 includes a light-emission control transistor T5, and the light-emission control transistor T5 includes a light-emission control active layer ACT5, a control electrode G5 and a first electrode D5. The light-emission control active layer ACT5 is located in the first semiconductor layer 2, and the first electrode D5 of the light-emission control transistor is located in the third conductive layer 5. The display substrate further includes a light-emission control line EM extending in the first direction. An orthographic projection of the light-emission control active layer ACT5 on the base substrate overlaps at least partially with an orthographic projection of the light-emission control line EM on the base substrate, and a portion of the light-emission control active layer ACT5 overlapping with the light-emission control line EM is the control electrode of the light-emission control transistor T5.

Exemplarily, the data writing active layer ACT4 and the light-emission control active layer ACT5 extend continuously in the second direction D2. An orthographic projection of the data writing active layer ACT4 on the base substrate and an orthographic projection of the light-emission control active layer ACT5 on the base substrate both overlap at least partially with the orthographic projection of the data signal line DL on the base substrate, or both fall within the orthographic projection of the data signal line DL on the base substrate.

Through the design of adjacent sub-pixels sharing a data signal line, a data writing transistor and a first light light-emission control transistor, the wiring space may be saved, which helps achieve a narrow bezel, and the IC chips may be reduced, which helps lower costs. Furthermore, sharing at least some transistors may reduce the number of transistors and the number of via holes of the display substrate, which helps improve the yield of display substrate and the layout of subsequent high-resolution product.

The display substrate further includes a first conductive transfer portion m1, which is located in the third conductive layer 5. The first electrode D5 of the first light-emission control transistor is electrically connected to the first power line VDD1 through the first conductive transfer portion m1.

The first power line VDD1 includes a first power sub-line VDD11 and a second power sub-line VDD12, which are spaced apart in the first direction and extend in the second direction. The first conductive transfer portion m1 is electrically connected to the first power sub-line VDD11 through a second via hole VH2 and electrically connected to the second power sub-line VDD12 through a third via hole VH3.

The first conductive transfer portion m1 includes a first conductive transfer sub-portion m11 and a second conductive transfer sub-portion m12. The first conductive transfer sub-portion m11 extends in the second direction, and the second conductive transfer sub-portion m12 extends in the first direction. An orthographic projection of the first conductive transfer sub-portion m11 on the base substrate overlaps at least partially with the orthographic projection of the light-emission control active layer ACT5 on the base substrate, an orthographic projection of the second via hole VH2 on the base substrate falls within an orthographic projection of a first end of the second conductive transfer sub-portion m12 on the base substrate, and an orthographic projection of the third via hole VH3 on the base substrate falls within an orthographic projection of a second end of the second conductive transfer sub-portion m12 on the base substrate.

Exemplarily, the orthographic projection of the data signal line DL on the base substrate falls within a gap between an orthographic projection of the first power sub-line VDD11 on the base substrate and an orthographic projection of the second power sub-line VDD12 on the base substrate.

The first sub-pixel driving circuit DX1 further includes a first driving sub-circuit 311, a first compensation sub-circuit 411, a first storage sub-circuit 611, a first initialization sub-circuit 711, a second initialization sub-circuit 712 and a second light-emission control sub-circuit 512. The first driving sub-circuit 311 includes a first driving transistor T31, the first compensation sub-circuit 411 includes a first compensation transistor T21, the first storage sub-circuit 611 includes a first capacitor C1, the first initialization sub-circuit 711 includes a first initialization transistor T11, the second initialization sub-circuit 712 includes a second initialization transistor T71, and the second light-emission control sub-circuit 512 includes a second light-emission control transistor T61.

The second sub-pixel driving circuit DX2 further includes a second driving sub-circuit 312, a second compensation sub-circuit 412, a second storage sub-circuit 612, a third initialization sub-circuit 713, a fourth initialization sub-circuit 714 and a fourth light-emission control sub-circuit 514. The second driving sub-circuit 312 includes a second driving transistor T32, the second compensation sub-circuit 412 includes a second compensation transistor T22, the second storage sub-circuit 611 includes a second capacitor C2, the third initialization sub-circuit 713 includes a third initialization transistor T12, the fourth initialization sub-circuit 714 includes a fourth initialization transistor T72, and the fourth light-emission control sub-circuit 514 includes a fourth light-emission control transistor T62.

Exemplarily, the first driving transistor T31 includes a first driving active layer ACT31, and the second driving transistor T32 includes a second driving active layer ACT32. The first driving active layer ACT31 and the second driving active layer ACT32 extend in polygonal lines.

Exemplarily, the first driving transistor T31, the first compensation transistor T21, the first capacitor C1, the first initialization transistor T11, the second initialization transistor T71, the second light-emission control transistor T61, the second driving transistor T32, the second compensation transistor T22, the second capacitor C2, the third initialization transistor T12, the fourth initialization transistor T72 and the fourth light-emission control transistor T62 in the display substrate in embodiments of FIG. 18 may be arranged in the same way as the corresponding transistors and capacitors of the display substrate in the embodiments of FIG. 16A, which will not be repeated here.

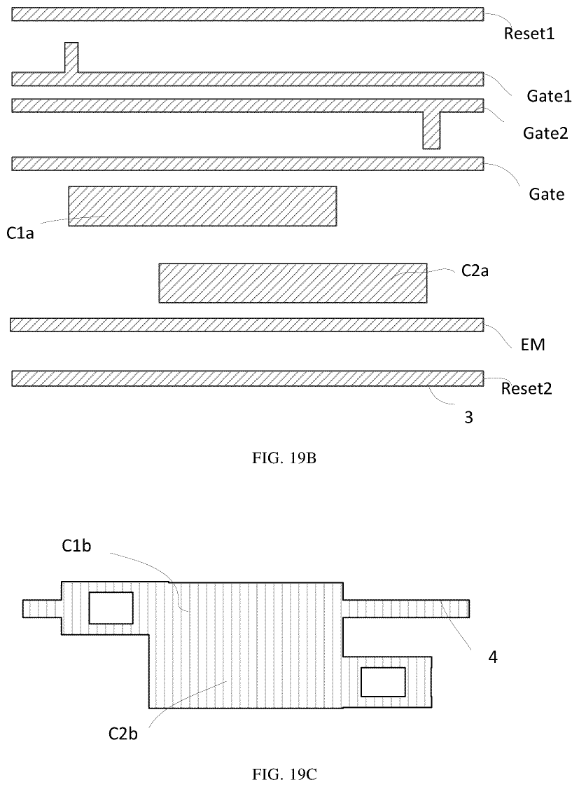

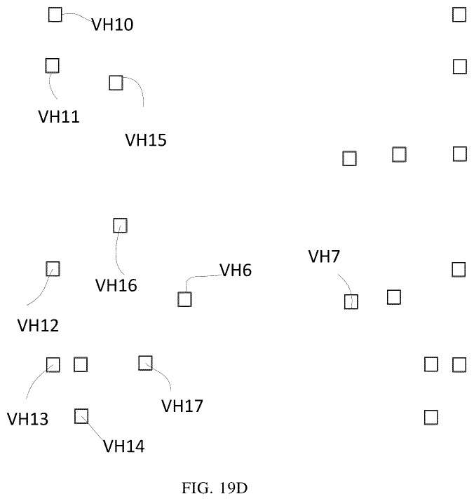

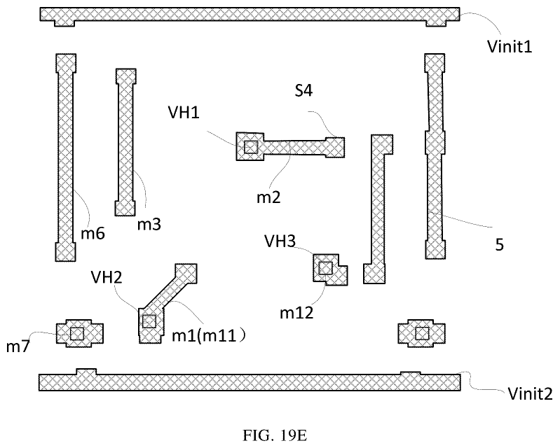

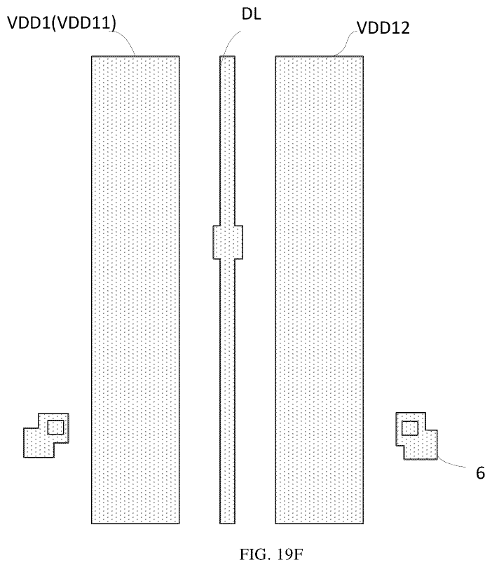

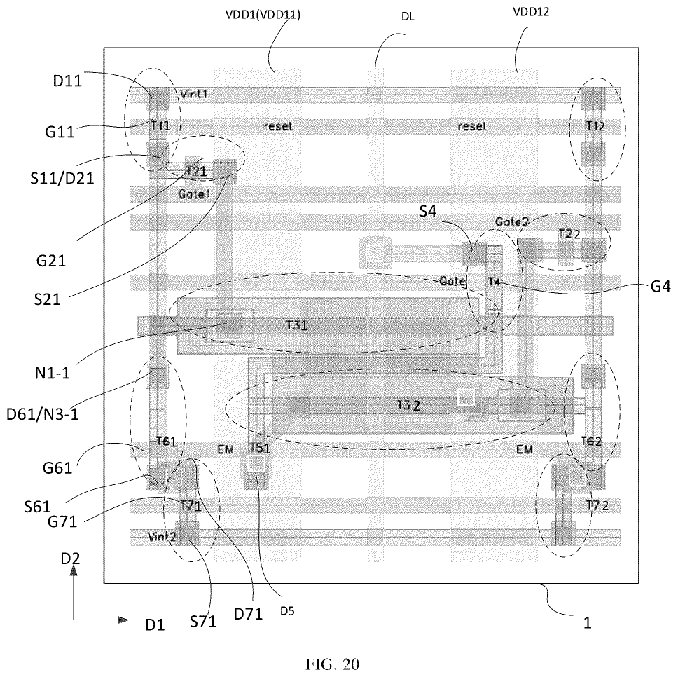

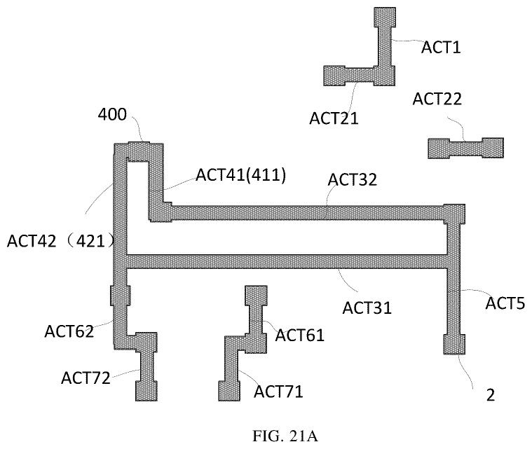

FIG. 19A shows a schematic diagram of a planar structure of a first semiconductor layer in a pixel circuit according to exemplary embodiments of the present disclosure; FIG. 19B shows a schematic diagram of a planar structure of a first conductive layer in a pixel circuit according to exemplary embodiments of the present disclosure; FIG. 19C shows a schematic diagram of a planar structure of a second conductive layer in a pixel circuit according to exemplary embodiments of the present disclosure; FIG. 19D shows a schematic diagram of some via holes according to exemplary embodiments of the present disclosure; FIG. 19E shows a schematic diagram of a planar structure of a third conductive layer in a pixel circuit according to exemplary embodiments of the present disclosure; FIG. 19F shows a schematic diagram of a planar structure of a fourth conductive layer in a pixel circuit according to exemplary embodiments of the present disclosure; FIG. 20 shows a schematic diagram of a planar structure of a combination of the first semiconductor layer, the first conductive layer, the second conductive layer, the third conductive layer and the fourth conductive layer in a pixel circuit according to exemplary embodiments of the present disclosure.

Exemplarily, in some embodiments of the present disclosure, referring to FIG. 1 and FIG. 19A to FIG. 20, the first sub-pixel driving circuit DX1 and the second sub-pixel driving circuit DX2 share a data writing sub-circuit 21, a data signal line DL and a first light-emission control sub-circuit 511.

The display substrate 1100 includes: a first semiconductor layer 2 on the base substrate 1; a first conductive layer 3 on a side of the first semiconductor layer 2 away from the base substrate 1; a second conductive layer 4 on a side of the first conductive layer 3 away from the base substrate 1; a third conductive layer 5 on a side of the second conductive layer 4 away from the base substrate 1; and a fourth conductive layer 6 on a side of the third conductive layer 4 away from the base substrate 1.

The display substrate may further include a first scanning signal line Gate, a second scanning signal line Gate1, a third scanning signal line Gate2, a first initialization signal line Vinit1, a second initialization signal line Vinit2, a first reset signal line Reset1, a second reset signal line Reset2 and a light-emission control line EM that extend in the first direction, as well as a first power line VDD1 and a data signal line DL that extend in the second direction. The first scanning signal line Gate, the second scanning signal line Gate1, the third scanning signal line Gate2, the first reset signal line Reset1, the second reset signal line Reset2 and the light-emission control line EM are located in the first conductive layer 3, the first initialization signal line Vinit1 and the second initialization signal line Vinit2 are located in the third conductive layer 5, and the first power line VDD1 and the data signal line DL are located in the fourth conductive layer 6.

The data writing sub-circuit 21 includes a data writing transistor T4, and the data writing transistor T4 includes a data writing active layer ACT4, a control electrode G4 and a second electrode S4. The data writing active layer ACT4 is located in the first semiconductor layer 2, and the second electrode S4 is located in the third conductive layer 5. An orthographic projection of the data writing active layer ACT4 on the base substrate 1 overlaps at least partially with an orthographic projection of the first scanning signal line Gate on the base substrate 1, and a portion of the data writing active layer ACT4 overlapping with the first scanning signal line Gate is the control electrode G4 of the data writing transistor 21. The orthographic projection of the data writing active layer ACT4 on the base substrate may not overlap with the orthographic projection of the data signal line on the base substrate. The second electrode S4 of the data writing transistor is electrically connected to the data signal line DL through a second conductive transfer portion m2 and the first via hole VH1.

The first light-emission control sub-circuit 511 includes a light-emission control transistor T5, and the light-emission control transistor T5 includes a light-emission control active layer ACT5, a control electrode G5 and a first electrode D5. The light-emission control active layer ACT5 is located in the first semiconductor layer 2, and the first electrode D5 of the light-emission control transistor is located in the third conductive layer 5. The display substrate further includes a light-emission control line EM extending in the first direction. An orthographic projection of the light-emission control active layer ACT5 on the base substrate overlaps at least partially with an orthographic projection of the light-emission control line EM on the base substrate, and a portion of the light-emission control active layer ACT5 overlapping with the light-emission control line EM is the control electrode of the light-emission control transistor T5.

Through the design of adjacent sub-pixels sharing a data signal line, a data writing transistor and a first light-emission control transistor, the wiring space may be saved, which helps achieve a narrow bezel, and the IC chips may be reduced, which helps lower costs. Furthermore, sharing at least some transistors may reduce the number of transistors and the number of via holes of the display substrate, which helps improve the yield of display substrate and the layout of subsequent high-resolution product.

Exemplarily, the first sub-pixel driving circuit DX1 includes a first driving sub-circuit 311, the first driving sub-circuit 311 includes a first driving transistor T31, and the first driving transistor T31 includes a first driving active layer ACT31. The second sub-pixel driving circuit DX2 includes a second driving sub-circuit 312, the second driving sub-circuit 312 includes a second driving transistor T32, and the second driving transistor T32 includes a second driving active layer ACT32. The first driving active layer ACT31 extends in a straight line in the first direction, and the second driving active layer ACT32 extends in a straight line in the first direction. The first driving active layer ACT31 and the second driving active layer ACT32 are spaced apart in the second direction.

Exemplarily, the data writing active layer ACT4, the light-emission control active layer ACT5, the first driving active layer ACT31 and the second driving active layer ACT32 are electrically connected to each other.

By designing the active layer of the driving transistor to extend in a straight line, the consistency of the length and width of each driving transistor may be ensured, which helps improve a performance consistency of the driving transistors, thereby enhancing a grayscale uniformity of the display substrate.

The display substrate further includes a first conductive transfer portion m1, which is located in the third conductive layer 5. The first electrode D5 of the first light-emission control transistor is electrically connected to the first power line VDD1 through the second via hole VH2 and the first conductive transfer portion m1. The first power line VDD1 includes a first power sub-line VDD11 and a second power sub-line VDD12, which are spaced apart in the first direction and extend in the second direction.

Exemplarily, the data writing active layer ACT4 extends in the second direction, the first light-emission control active layer ACT5 extends in the second direction, and the data writing active layer ACT4 and the light-emission control active layer ACT5 are spaced apart in the first direction. An orthographic projection of the data writing active layer ACT4 on the base substrate falls within an orthographic projection of the second power sub-line VDD12 on the base substrate, and an orthographic projection of the light-emission control active layer ACT5 on the base substrate falls within an orthographic projection of the first power sub-line VDD11 on the base substrate.

Exemplarily, the second electrode S4 of the data writing transistor is electrically connected to the data signal line DL through the second conductive transfer portion m2 and the first via hole VH1.

Exemplarily, the first sub-pixel driving circuit DX1 includes a first storage sub-circuit 611, the first storage sub-circuit 611 includes a first capacitor C1, and the first capacitor C1 includes a first plate C1a and a second plate C1b. The second sub-pixel driving circuit DX2 includes a second storage sub-circuit 612, the second storage sub-circuit 612 includes a second capacitor C2, and the second capacitor C2 includes a third plate C2a and a fourth plate C2b. The first plate C1a and the third plate C2a are located in the first conductive layer 3. The first plate C1a and the third plate C2a are spaced apart in the second direction and overlap at least partially with each other in the first direction. The second plate C1b and the fourth plate C2b are located in the second conductive layer and electrically connected to each other.

The first conductive transfer portion m1 includes a first conductive transfer sub-portion m11 and a second conductive transfer sub-portion m12. A first end of the first conductive transfer sub-portion m11 is electrically connected to the first power sub-line VDD11 through the second via hole VH2, and a second end of the first conductive transfer sub-portion m11 is electrically connected to the second plate C1b through a sixth via hole VH2. The second conductive transfer sub-portion m12 is electrically connected to the second power sub-line VDD12 through the third via hole VH3 and electrically connected to the fourth plate C2b through a seventh via hole VH7. Any two of an orthographic projection of the second conductive transfer sub-portion m12 on the base substrate, an orthographic projection of the fourth plate C2b on the base substrate and an orthographic projection of the second power sub-line VDD12 on the base substrate overlap at least partially with each other. Since the second plate C1b and the fourth plate C2b are electrically connected to each other, the first power sub-line VDD11 and the second power sub-line VDD12 may be electrically connected through the first conductive transfer portion m1, the second plate C1b and the fourth plate C2b.

The first sub-pixel driving circuit DX1 further includes a first compensation sub-circuit 411, a first initialization sub-circuit 711, a second initialization sub-circuit 712 and a second light-emission control sub-circuit 512. The first compensation sub-circuit 411 includes a first compensation transistor T21, the first initialization sub-circuit 711 includes a first initialization transistor T11, the second initialization sub-circuit 712 includes a second initialization transistor T71, and the second light-emission control sub-circuit 512 includes a second light-emission control transistor T61.

The second sub-pixel driving circuit DX2 further includes a second compensation sub-circuit 412, a third initialization sub-circuit 713, a fourth initialization sub-circuit 714 and a fourth light-emission control sub-circuit 514. The second compensation sub-circuit 412 includes a second compensation transistor T22, the third initialization sub-circuit 713 includes a third initialization transistor T12, the fourth initialization sub-circuit 714 includes a fourth initialization transistor T72, and the fourth light-emission control sub-circuit 514 includes a fourth light-emission control transistor T62.

Exemplarily, the first initialization transistor T11 may include a first initialization active layer ACT11, a control electrode G11, a first electrode D11 and a second electrode S11. The first initialization active layer ACT11 extends in the second direction, and a portion of the first initialization active layer ACT11 overlapping with the first reset signal line Reset1 is the control electrode G11 of the first initialization transistor T11. The first electrode D11 of the first initialization transistor T11 is electrically connected to the first initialization signal line Vinit1 through the tenth via hole VH10.

Exemplarily, the first compensation transistor T21 may include a first compensation active layer ACT21, a control electrode G21, a first electrode D21 and a second electrode S21. The first compensation active layer ACT21 extends in the first direction, and a portion of the first compensation active layer ACT21 overlapping with the second scanning signal line Gate1 is the control electrode G21 of the first compensation transistor T21. The first electrode D21 of the first compensation transistor T21 and the second electrode S11 of the first initialization transistor T11 are electrically connected to the first sub-node of third node N3-1 through the eleventh via hole VH11, the twelfth via hole VH12 and the sixth conductive transfer portion m6. The second electrode S21 of the first compensation transistor T21 is electrically connected to the first sub-node of first node N1-1 through the fifteenth via hole VH15, the sixteenth via hole VH16 and the third conductive transfer portion m3. The third conductive transfer portion m3 is located in the third conductive layer 5.

The second light-emission control transistor T61 further includes an active layer ACT61, a control electrode G61, a first electrode D61 and a second electrode S61. A portion of the active layer ACT61 of the second light-emission control transistor T61 overlapping with the light-emission control line EM is the control electrode of the second light-emission control transistor T61. The first electrode D61 of the second light-emission control transistor T61 is electrically connected to the first sub-node of third node N3-1 through the twelfth via hole VH12. The second electrode S61 of the second light-emission control transistor T61 is electrically connected to the first electrode L11 of the first light emitting sub-element through the thirteenth via hole VH13 and the seventh conductive transfer portion m7.

The second initialization transistor T71 further includes an active layer ACT71, a control electrode G71, a first electrode D71 and a second electrode S71. A portion of the active layer ACT71 of the second initialization transistor T71 overlapping with the second reset signal line Reset2 is the control electrode G71 of the second initialization transistor T71. The first electrode D71 of the second initialization transistor T71 is electrically connected to the first electrode L11 of the first light emitting sub-element through the thirteenth via hole VH13 and the seventh conductive transfer portion m7. The second electrode S71 of the second initialization transistor T71 is electrically connected to the second initialization signal line Vinit2 through the fourteenth via hole VH14.

Exemplarily, in the display substrate in the embodiments of FIG. 20, the second compensation transistor T22, the third initialization transistor T12, the fourth initialization transistor T72 and the fourth light-emission control transistor T62 may be connected in the same or corresponding manner as the first compensation transistor T21, the first initialization transistor T11, the second initialization transistor T71 and the second light-emission control transistor T61, which will not be repeated here.

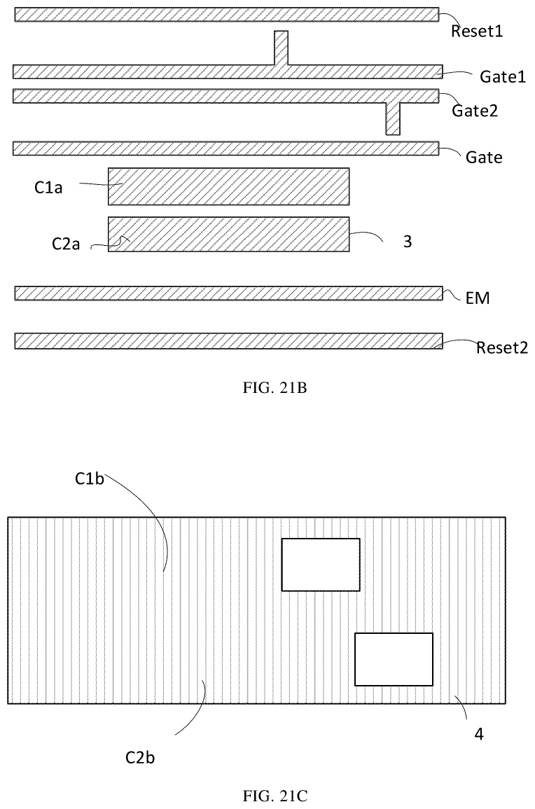

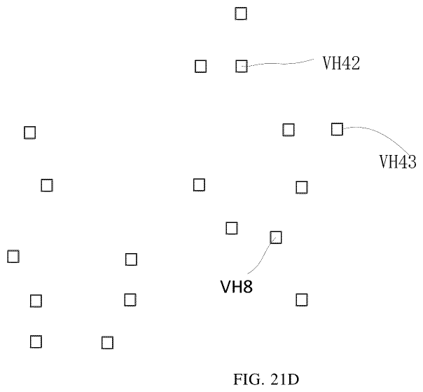

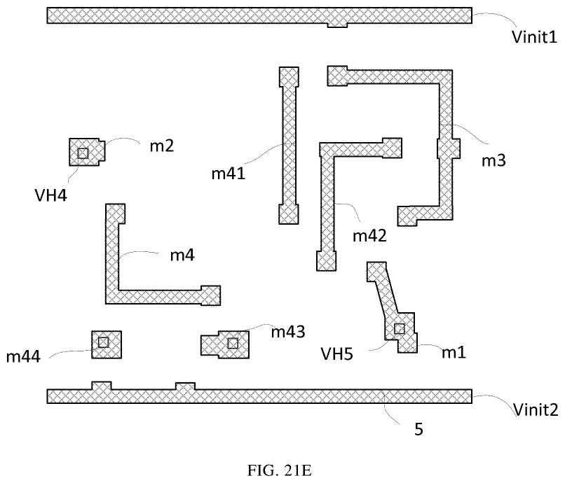

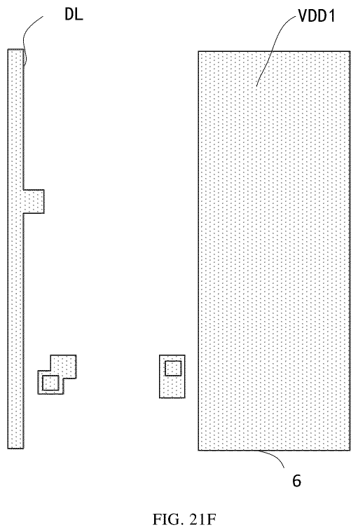

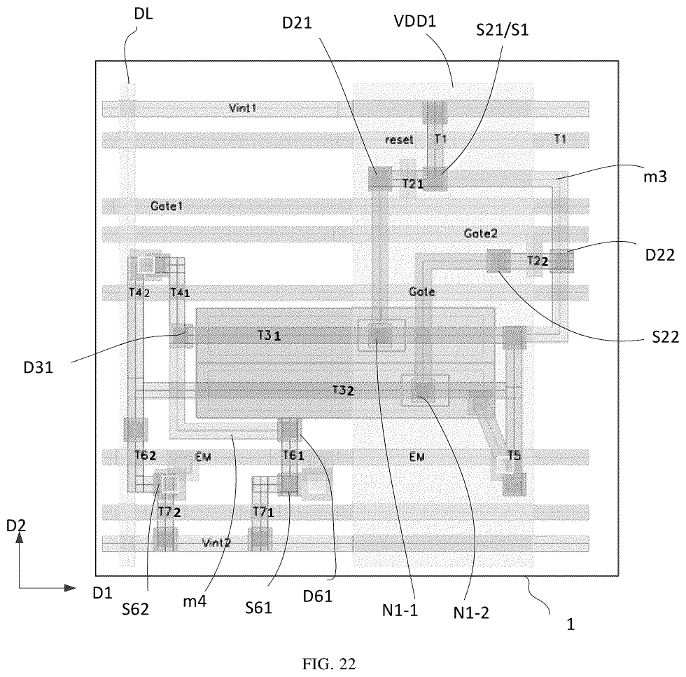

FIG. 21A shows a schematic diagram of a planar structure of a first semiconductor layer in a pixel circuit according to exemplary embodiments of the present disclosure; FIG. 21B shows a schematic diagram of a planar structure of a first conductive layer in a pixel circuit according to exemplary embodiments of the present disclosure; FIG. 21C shows a schematic diagram of a planar structure of a second conductive layer in a pixel circuit according to exemplary embodiments of the present disclosure; FIG. 21D shows a schematic diagram of some via holes according to exemplary embodiments of the present disclosure; FIG. 21E shows a schematic diagram of a planar structure of a third conductive layer in a pixel circuit according to exemplary embodiments of the present disclosure; FIG. 21F shows a schematic diagram of a planar structure of a fourth conductive layer in a pixel circuit according to exemplary embodiments of the present disclosure; FIG. 22 shows a schematic diagram of a planar structure of a combination of the first semiconductor layer, the first conductive layer, the second conductive layer, the third conductive layer and the fourth conductive layer in a pixel circuit according to exemplary embodiments of the present disclosure.

Exemplarily, in some embodiments of the present disclosure, referring to FIG. 1 and FIG. 21A to FIG. 22, the display substrate 1100 includes: a base substrate 1; a plurality of sub-pixels SP on the base substrate 1, where the plurality of sub-pixels SP are arranged in an array in the first direction and the second direction; and a plurality of pixel circuits DX used to drive the plurality of sub-pixels SP. The plurality of sub-pixels SP include a first sub-pixel SP1 and a second sub-pixel SP2, which are adjacent to each other in the first direction or the second direction. The plurality of pixel circuits DX include a first sub-pixel driving circuit DX1 used to drive the first sub-pixel SP1 and a second sub-pixel driving circuit DX2 used to drive the second sub-pixel SP2. The first direction intersects with the second direction.

The display substrate 1100 includes: a first semiconductor layer 2 on the base substrate 1; a first conductive layer 3 on a side of the first semiconductor layer 2 away from the base substrate 1; a second conductive layer 4 on a side of the first conductive layer 3 away from the base substrate 1; a third conductive layer 5 on a side of the second conductive layer 4 away from the base substrate 1; and a fourth conductive layer 6 on a side of the third conductive layer 4 away from the base substrate 1.

The display substrate 1100 further includes a first reset signal line Reset1 and a light-emission control line EM that extend in the first direction D1, as well as a data signal line DL and a first power line VDD1 that extend in the second direction D2. The first reset signal line Reset1 and the light-emission control line EM are located in the first conductive layer 3, and the data signal line DL and the first power line VDD1 are located in the fourth conductive layer 6.

Exemplarily, the first sub-pixel driving circuit DX1 and the second sub-pixel driving circuit DX2 share a first initialization sub-circuit 711, a first light-emission control sub-circuit 511 and a data signal line DL. The first initialization sub-circuit 711 includes an initialization transistor T1, the initialization transistor T1 includes an initialization active layer ACT1 and a control electrode G1, and the initialization active layer ACT1 extends in the second direction. An orthographic projection of the initialization active layer ACT1 on the base substrate overlaps at least partially with an orthographic projection of the first reset signal line Reset1 on the base substrate, and a portion of the initialization active layer ACT1 overlapping with the first reset signal layer Reset1 is the control electrode G1 of the initialization transistor. The first light-emission control sub-circuit 511 includes a light-emission control transistor T5, the light-emission control transistor T5 includes a light-emission control active layer ACT5 and a first electrode D5, and the light-emission control active layer ACT5 extends in the second direction. An orthographic projection of the light-emission control active layer ACT5 on the base substrate falls within an orthographic projection of the first power line VDD1 on the base substrate. The first electrode D1 of the light-emission control transistor is electrically connected to the first power line VDD1 through the first conductive transfer portion m1 and a fifth via hole VH5.

Exemplarily, the first sub-pixel driving circuit DX1 includes a first data writing sub-circuit 211, the first data writing sub-circuit 211 includes a first data writing transistor T41, and the first data writing transistor T41 includes a first data writing active layer ACT41 and a second electrode S41. The second sub-pixel driving circuit DX2 includes a second data writing sub-circuit 212, the second data writing sub-circuit 212 includes a second data writing transistor T42, and the second data writing transistor includes a second data writing active layer ACT42 and a first electrode D42. The first data writing active layer ACT41 includes a body portion 411 extending in the second direction, and the second data writing active layer ACT42 includes a body portion 421 extending in the second direction. The first data writing active layer ACT41 and the second data writing active layer ACT42 share a lap portion 400, and the lap portion 400 extends in the first direction. The second electrode S41 of the first data writing transistor and the first electrode D42 of the second data writing transistor are electrically connected to the data signal line DL through the second conductive transfer portion m2 and a fourth via hole VH4.

Through the design of sharing a data signal line, the number of wires in the pixel driving circuit may be reduced and the wiring space may be saved, which helps a narrow-bezel display, and further, the number of IC chips may be reduced, which helps lower costs.

Exemplarily, the first sub-pixel driving circuit DX1 includes a first compensation sub-circuit, the first compensation sub-circuit includes a first compensation transistor T21, and the first compensation transistor T21 includes a first compensation active layer ACT21. The second sub-pixel driving circuit DX2 includes a second compensation sub-circuit, the second compensation sub-circuit includes a second compensation transistor T22, and the second compensation transistor T22 includes a second compensation active layer ACT22. The first compensation active layer ACT21 and the second compensation active layer ACT22 extend in the first direction, and are spaced apart in the first direction and the second direction.

Exemplarily, the first sub-pixel driving circuit DX1 includes a first storage sub-circuit, the first storage sub-circuit includes a first capacitor C1, and the first capacitor C1 includes a first plate C1a and a second plate C1b. The second sub-pixel driving circuit includes a second storage sub-circuit, the second storage sub-circuit includes a second capacitor C2, and the second capacitor C2 includes a third plate C2a and a fourth plate C2b. The first plate C1a and the third plate C2a are located in the first conductive layer 3 and spaced apart in the second direction. The second plate C1b and the fourth plate C2b are located in the second conductive layer and electrically connected to each other.

Exemplarily, the first conductive transfer portion m1 is electrically connected to the first power line VDD1 through the fifth via hole VH5 and electrically connected to the fourth plate C2b through the eighth via hole VH8.

Exemplarily, the display substrate further includes a third conductive transfer portion m3 in the third conductive layer 5. The first compensation transistor T21 includes a first electrode D21 and a second electrode S21, and the second compensation transistor T22 includes a first electrode D22 and a second electrode S22. The second electrode S21 of the first compensation transistor T21 is electrically connected to the first electrode D22 of the second compensation transistor T22 through a via hole VH42, a via hole VH43 and the third conductive transfer portion m3. The first electrode D21 of the first compensation transistor T21 is electrically connected to the first sub-node of first node N1-1 through a forty-first conductive transfer portion m41. The second electrode S22 of the second compensation transistor T22 is electrically connected to the second sub-node of first node N1-2 through a forty-second conductive transfer portion m42.

Exemplarily, the first sub-pixel driving circuit DX1 includes a first driving sub-circuit, the first driving sub-circuit includes a first driving transistor T31, and the first driving transistor T31 includes a first driving active layer ACT31. The second sub-pixel driving circuit DX2 includes a second driving sub-circuit, the second driving sub-circuit includes a second driving transistor T32, and the second driving transistor T32 includes a second driving active layer ACT32. The first driving active layer ACT31 extends in a straight line in the first direction, the second driving active layer ACT32 extends in a straight line in the first direction, and the first driving active layer ACT31 and the second driving active layer ACT32 are spaced apart in the second direction. The first light-emission control active layer ACT5, the first driving active layer ACT31 and the second driving active layer ACT32 are electrically connected to each other.

By designing the active layer of the driving transistor to extend in a straight line, the consistency of the length and width of each driving transistor may be ensured, which helps improve a performance consistency of the driving transistors, thereby enhancing a grayscale uniformity of the display substrate.

The first sub-pixel driving circuit DX1 includes a second light-emission control sub-circuit, the second light-emission control sub-circuit includes a second light-emission control transistor T61, and the second light-emission control transistor T61 includes a second light-emission control active layer ACT61, a first electrode D61 and a second electrode S61. The first electrode D61 of the second light-emission control transistor is electrically connected to the first electrode D31 of the first driving transistor T31 through a fourth conductive transfer portion m4. The second electrode S61 of the second light-emission control transistor is electrically connected to the first electrode of the first light emitting element through a forty-third conductive transfer portion m43.

The second sub-pixel driving circuit DX2 includes a fourth light-emission control sub-circuit, the fourth light-emission control sub-circuit includes a fourth light-emission control transistor T62, and the fourth light-emission control transistor T62 includes a fourth light-emission control active layer ACT62 and a second electrode S62. The second light-emission control active layer ACT61 and the fourth light-emission control active layer ACT62 extend in the second direction and are spaced apart in the first direction. The second electrode S62 of the fourth light-emission control transistor T62 is electrically connected to the first electrode of the second light emitting element through a forty-fourth conductive transfer portion m44. Referring to FIG. 1, at least some embodiments of the present disclosure further provide a display device. The display device 1000 may include the display substrate as described above.

The display device may include any device or product having a display function. For example, the display device may be a smart phone, a mobile phone, an e-book reader, a desktop computer (PC), a laptop PC, a netbook PC, a personal digital assistant (PDA), a portable multimedia player (PMP), a digital audio player, a mobile medical device, a camera, a wearable device (e.g., a headset, an electronic apparel, an electronic bracelet, an electronic necklace, an electronic accessory, an electronic tattoo, or a smart watch), a television, and the like.

It should be understood that the display panel and the display device according to embodiments of the present disclosure have all the features and advantages of the display substrate described above, for which specific reference may be made to the description above, and will not be repeated here. Some embodiments of the general technical concept of the present disclosure have been shown and illustrated. However, it may be understood by those ordinary skilled in the art that changes may be made to these embodiments without departing from the principles and spirit of the general technical concept, and the scope of the present disclosure is defined by claims and their equivalents.

1. A pixel circuit, comprising:
a first sub-pixel driving circuit configured to drive a first sub-pixel; and a second sub-pixel driving circuit configured to drive a second sub-pixel; wherein the first sub-pixel comprises a first light emitting sub-element, the second sub-pixel comprises a second light emitting sub-element, and the second sub-pixel is adjacent to the first sub-pixel in a first direction or a second direction intersecting with the first direction, wherein the pixel circuit further comprises a first data signal line configured to provide a data signal to the first sub-pixel driving circuit and the second sub-pixel driving circuit, wherein the data signal comprises a first data sub-signal generated by the first data signal line in a third time period and a second data sub-signal generated by the first data signal line in a fourth time period, and the third time period does not overlap with the fourth time period.

2. The pixel circuit according to claim 1, wherein the pixel circuit comprises a data writing sub-circuit, the data writing sub-circuit is coupled to a data signal terminal, a first scanning signal terminal and a second node, the data signal terminal is coupled to the first data signal line, and the data writing sub-circuit is configured to write a data signal received at the data signal terminal to the second node in response to a first scanning signal received at the first scanning signal terminal; and
wherein the first sub-pixel driving circuit and the second sub-pixel driving circuit are coupled to the second node, and the data writing sub-circuit is configured to write the first data sub-signal to the first pixel driving sub-circuit through the second node and write the second data sub-signal to the second sub-pixel driving circuit through the second node.

3. The pixel circuit according to claim 2, wherein the first sub-pixel driving circuit comprises:
a first driving sub-circuit, wherein the first driving sub-circuit is coupled to a first sub-node of first node, the second node and a first sub-node of third node, the first driving sub-circuit is configured to generate a first driving current in response to a voltage of the first sub-node of first node, and the first driving current is configured to drive the first light emitting sub-element to emit light; and
a first compensation sub-circuit, wherein the first compensation sub-circuit is coupled to a second scanning signal terminal, the first sub-node of first node and the first sub-node of third node, and the first compensation sub-circuit is configured to transmit the first data sub-signal from the data signal terminal to the first sub-node of first node in response to a second scanning signal received at the second scanning signal terminal.

4. The pixel circuit according to claim 3, wherein the second sub-pixel driving circuit comprises:
a second driving sub-circuit, wherein the second driving sub-circuit is coupled to a second sub-node of first node, the second node and a second sub-node of third node, the second driving sub-circuit is configured to generate a second driving current in response to a voltage of the second sub-node of first node, and the second driving current is configured to drive the second light emitting sub-element to emit light; and
a second compensation sub-circuit, wherein the second compensation sub-circuit is coupled to a third scanning signal terminal, the second sub-node of first node and the second sub-node of third node, and the second compensation sub-circuit is configured to transmit the second data sub-signal from the data signal terminal to the second sub-node of first node in response to a third scanning signal received at the third scanning signal terminal.

5. The pixel circuit according to claim 4, wherein the data writing sub-circuit, the first driving sub-circuit and the second driving sub-circuit are coupled to the second node.

6. The pixel circuit according to claim 1, wherein the first sub-pixel driving circuit further comprises:
a first light-emission control sub-circuit, wherein the first light-emission control sub-circuit is coupled to a first voltage terminal, a light-emission control terminal and a second node, and the first light-emission control sub-circuit is configured to write a first voltage received at the first voltage terminal to the second node in response to a light-emission control signal received at the light-emission control terminal; and
a first storage sub-circuit, wherein the first storage sub-circuit is coupled to a first sub-node of first node and the first voltage terminal; and
wherein the second sub-pixel driving circuit further comprises:
a third light-emission control sub-circuit, wherein the third light-emission control sub-circuit is coupled to a second voltage terminal, a light-emission control terminal and the second node, and the third light-emission control sub-circuit is configured to write a second voltage received at the second voltage terminal to the second node in response to a light-emission control signal received at the light-emission control terminal; and
a second storage sub-circuit, wherein the second storage sub-circuit is coupled to a second sub-node of first node and the second voltage terminal,
wherein the data writing sub-circuit comprises a data writing transistor, and the data writing transistor has a control electrode coupled to the first scanning signal terminal, a first electrode coupled to the second node, and a second electrode coupled to the data signal terminal;
wherein the first light-emission control sub-circuit comprises a first light-emission control transistor, and the first light-emission control transistor has a control electrode coupled to the light-emission control terminal, a first electrode coupled to the first voltage terminal, and a second electrode coupled to the second node; and
wherein the third light-emission control sub-circuit comprises a third light-emission control transistor, and the third light-emission control transistor has a control electrode coupled to the light-emission control terminal, a first electrode coupled to the second voltage terminal, and a second electrode coupled to the second node.

7. The pixel circuit according to claim 1, wherein the pixel circuit comprises:
a first light-emission control sub-circuit, wherein the first light-emission control sub-circuit is coupled to a first voltage terminal, a light-emission control terminal and a second node, and the first light-emission control sub-circuit is configured to write a first voltage received at the first voltage terminal to the first sub-pixel driving circuit and the second sub-pixel driving circuit respectively through the second node in response to a light-emission control signal received at the light-emission control terminal;
a first storage sub-circuit, wherein the first storage sub-circuit is coupled to a first sub-node of first node and the first voltage terminal, and the first storage sub-circuit is configured to store a storage voltage in the first sub-pixel driving circuit; and
a second storage sub-circuit, wherein the second storage sub-circuit is coupled to a second sub-node of first node and the first voltage terminal, and the second storage sub-circuit is configured to store a storage voltage in the second sub-pixel driving circuit,
wherein the data writing sub-circuit comprises a data writing transistor, and the data writing transistor has a control electrode coupled to the first scanning signal terminal, a first electrode coupled to the second node, and a second electrode coupled to the data signal terminal; and
wherein the first light-emission control sub-circuit comprises a light-emission control transistor, and the light-emission control transistor has a control electrode coupled to the light-emission control terminal, a first electrode coupled to the first voltage terminal, and a second electrode coupled to the second node,
wherein the first sub-pixel driving circuit further comprises:
a first initialization sub-circuit, wherein the first initialization sub-circuit is coupled to a first reset signal terminal, a first initialization signal terminal and a first sub-node of first node, and the first initialization sub-circuit is configured to transmit a first initialization signal received at the first initialization signal terminal to the first sub-node of first node to initialize a potential of the first sub-node of first node in response to a first reset signal received at the first reset signal terminal;
a second initialization sub-circuit, wherein the second initialization sub-circuit is coupled to a second reset signal terminal, a second initialization signal terminal, and a first electrode of the first light emitting sub-element, and the second initialization sub-circuit is configured to transmit a second initialization signal received at the second initialization signal terminal to the first electrode of the first light emitting sub-element to initialize a potential of the first electrode of the first light emitting sub-element in response to a second reset signal received at the second reset signal terminal; and
a second light-emission control sub-circuit, wherein the second light-emission control sub-circuit is coupled to a first sub-node of third node, a light-emission control terminal, and the first electrode of the first light emitting sub-element, and the second light-emission control sub-circuit is configured to output a first driving current transmitted to the first sub-node of third node to the first light emitting sub-element in response to a light-emission control signal received at the light-emission control terminal,
wherein the second sub-pixel driving circuit further comprises:
a third initialization sub-circuit, wherein the third initialization sub-circuit is coupled to a first reset signal terminal, a first initialization signal terminal, and a second sub-node of first node, and the third initialization sub-circuit is configured to transmit a first initialization signal received at the first initialization signal terminal to the second sub-node of first node to initialize a potential of the second sub-node of first node in response to a first reset signal received at the first reset signal terminal;
a fourth initialization sub-circuit, wherein the fourth initialization sub-circuit is coupled to a second reset signal terminal, a second initialization signal terminal, and a first electrode of the second light emitting sub-element, and the fourth initialization sub-circuit is configured to transmit a second initialization signal received at the second initialization signal terminal to the first electrode of the second light emitting sub-element to initialize a potential of the first electrode of the second light emitting sub-element in response to a second reset signal received at the second reset signal terminal; and
a fourth light-emission control sub-circuit, wherein the fourth light-emission control sub-circuit is coupled to a second sub-node of third node, a light-emission control terminal, and the first electrode of the second light emitting element, and the fourth light-emission control sub-circuit is configured to output a second driving current transmitted to the second sub-node of third node to the second light emitting sub-element in response to a light-emission control signal received at the light-emission control terminal.

8. (canceled)

9. (canceled)

10. (canceled)

11. (canceled)

12. The pixel circuit according to claim 1, wherein the pixel circuit comprises:
a first light-emission control sub-circuit, wherein the first light-emission control sub-circuit is coupled to a first voltage terminal, a light-emission control terminal and a second node, the first light-emission control sub-circuit is configured to write a first voltage received at the first voltage terminal to the second node in response to a light-emission control signal received at the light-emission control terminal, wherein the first sub-pixel driving circuit and the second sub-pixel driving circuit are coupled at the second node, and the first light-emission control sub-circuit is configured to write the first voltage to the first sub-pixel driving circuit and the second sub-pixel driving circuit respectively through the second node; and
a first initialization sub-circuit, wherein the first initialization sub-circuit is coupled to a first reset signal terminal, a first initialization signal terminal and the second node, and the first initialization sub-circuit is configured to transmit a first initialization signal received at the first initialization signal terminal to the second node to initialize a potential of the second node in response to a first reset signal received at the first reset signal terminal,
wherein the first sub-pixel driving circuit further comprises:
a first data writing sub-circuit, wherein the first data writing sub-circuit is coupled to a data signal terminal, a first scanning signal terminal and a first sub-node of third node, and the first data writing sub-circuit is configured to write a data signal received at the data signal terminal to the first sub-node of third node in response to a first scanning signal received at the first scanning signal terminal; and
wherein the second sub-pixel driving circuit further comprises:
a second data writing sub-circuit, wherein the second data writing sub-circuit is coupled to a data signal terminal, a first scanning signal terminal and a second sub-node of third node, the second data writing sub-circuit is configured to write a data signal received at the data signal terminal to the second sub-node of third node in response to a first scanning signal received at the first scanning signal terminal,
wherein the data signal terminal coupled to the first data writing sub-circuit is coupled to the same data signal line as the data signal terminal coupled to the second data writing sub-circuit,
wherein the first sub-pixel driving circuit comprises:
a first storage sub-circuit, wherein the first storage sub-circuit is coupled to a first sub-node of first node and the first voltage terminal;
a first compensation sub-circuit, wherein the first compensation sub-circuit is coupled to a second scanning signal terminal, the first sub-node of first node, and the second node, and the first compensation sub-circuit is configured to transmit the first data sub-signal from the data signal terminal to the first sub-node of first node in response to a second scanning signal received at the second scanning signal terminal; and
a first driving sub-circuit, wherein the first driving sub-circuit is coupled to the first sub-node of first node, the second node, and the first sub-node of third node, the first driving sub-circuit is configured to generate a first driving current in response to a voltage of the first sub-node of first node, and the first driving current is configured to drive the first light emitting sub-element to emit light; and
wherein the second sub-pixel driving circuit comprises:
a second storage sub-circuit, wherein the second storage sub-circuit is coupled to a second sub-node of first node and the first voltage terminal, and the first storage sub-circuit and the second storage sub-circuit are coupled at the first voltage terminal;
a second compensation sub-circuit, wherein the second compensation sub-circuit is coupled to a third scanning signal terminal, the second sub-node of first node, and the second node, and the second compensation sub-circuit is configured to transmit the second data sub-signal from the data signal terminal to the second sub-node of first node in response to a third scanning signal received at the third scanning signal terminal; and
a second driving sub-circuit, wherein the second driving sub-circuit is coupled to the second sub-node of first node, the second node, and the second sub-node of third node, the second driving sub-circuit is configured to generate a second driving current in response to a voltage of the second sub-node of first node, and the second driving current is configured to drive the second light emitting sub-element to emit light,
wherein the first light-emission control sub-circuit comprises a light-emission control transistor, and the light-emission control transistor has a control electrode coupled to the light-emission control terminal, a first electrode coupled to the first voltage terminal, and a second electrode coupled to the second node;
wherein the first initialization sub-circuit comprises an initialization transistor, and the initialization transistor has a control electrode coupled to the first reset signal terminal, a first electrode coupled to the second node, and a second electrode coupled to the first initialization signal terminal; and
wherein the first data writing sub-circuit comprises a first data writing transistor, the second data writing sub-circuit comprises a second data writing transistor,
wherein the first data writing transistor has a control electrode coupled to the first scanning signal terminal, a first electrode coupled to the first sub-node of third node, and a second electrode coupled to a first electrode of the second data writing transistor, and the second data writing transistor has a control electrode coupled to the first scanning signal terminal and a second electrode coupled to the second sub-node of third node.

13. (canceled)

14. (canceled)

15. (canceled)

16. The pixel circuit according to claim 1, wherein the pixel circuit comprises:
a first light-emission control sub-circuit, wherein the first light-emission control sub-circuit is coupled to a first voltage terminal, a light-emission control terminal and a second node, the first light-emission control sub-circuit is configured to write a first voltage received at the first voltage terminal to the second node in response to a light-emission control signal received at the light-emission control terminal, wherein the first sub-pixel driving circuit and the second sub-pixel driving circuit are electrically connected at the second node, and the first light-emission control sub-circuit is configured to write the first voltage to the first sub-pixel driving circuit through the second node and write the first voltage to the second sub-pixel driving circuit through the second node; and
a second reference voltage writing sub-circuit, wherein the second reference voltage writing sub-circuit is coupled to a second reset signal terminal, a second reference voltage terminal and the second node, and the second reference voltage writing sub-circuit is configured to write a second reference voltage received at the second reference voltage terminal to the second node in response to a second reset signal received at the second reset signal terminal;
wherein the first sub-pixel driving circuit further comprises:
a first data writing sub-circuit, wherein the first data writing sub-circuit is coupled to a data signal terminal, a second scanning signal terminal and a first sub-node of fourth node, and the first data writing sub-circuit is configured to write a data signal received at the data signal terminal to the first sub-node of fourth node in response to a second scanning signal received at the second scanning signal terminal;
a first storage sub-circuit, wherein the first storage sub-circuit is coupled to a first sub-node of first node and the first sub-node of fourth node; and
a third storage sub-circuit, wherein the third storage sub-circuit is coupled to the first sub-node of fourth node and the first voltage terminal;
wherein the second sub-pixel driving circuit further comprises:
a second data writing sub-circuit, wherein the second data writing sub-circuit is coupled to a data signal terminal, a third scanning signal terminal and a second sub-node of third node, the second data writing sub-circuit is configured to write a data signal received at the data signal terminal to the second sub-node of third node in response to a third scanning signal received at the third scanning signal terminal;
a second storage sub-circuit, wherein the second storage sub-circuit is coupled to a second sub-node of first node and a second sub-node of fourth node; and
a fourth storage sub-circuit, wherein the fourth storage sub-circuit is coupled to the second sub-node of fourth node and the first voltage terminal;
wherein the first data writing sub-circuit and the second data writing sub-circuit share the same data wire;
wherein the pixel driving circuit further comprises:
a first first-reference voltage writing sub-circuit, wherein the first first-reference voltage writing sub-circuit is coupled to the first sub-node of fourth node, the second reset signal terminal and a first reference voltage signal terminal, and the first first-reference voltage writing sub-circuit is configured to write a first reference voltage received at the first reference voltage signal terminal to the first sub-node of fourth node in response to a second reset signal received at the second reset signal terminal; and
a second first-reference voltage writing sub-circuit, wherein the second first-reference voltage writing sub-circuit is coupled to the second sub-node of fourth node, the second reset signal terminal and the first reference voltage signal terminal, and the second first-reference voltage writing sub-circuit is configured to write a first reference voltage received at the first reference voltage signal terminal to the second sub-node of fourth node in response to a second reset signal received at the second reset signal terminal.

17. A pixel driving method applied to the pixel circuit according to claim 1, wherein the pixel driving method comprises:
in a third time period, turning on a data writing sub-circuit and a first compensation sub-circuit in response to a first scanning signal and a second scanning signal, so that a first data sub-signal from a data signal terminal is transmitted to a first sub-node of first node; and
in a fourth time period, turning on the data writing sub-circuit and a second compensation sub-circuit in response to the first scanning signal and a third scanning signal, so that a second data sub-signal from the data signal terminal is transmitted to a second sub-node of first node,
wherein the third time period and the fourth time period are in a writing stage of an image frame, the fourth time period is after the third time period, and the fourth time period does not overlap with the third time period.

18. The pixel driving method according to claim 17, further comprising:
in a first time period, allowing a first sub-pixel and a second sub-pixel to stop emitting light, and starting to reset a first sub-pixel driving circuit and a second sub-pixel driving circuit, in response to a light-emission control signal of a light-emission control terminal; and
in a second time period, turning on a first initialization sub-circuit and a third initialization sub-circuit in response to a first reset signal at the first reset signal terminal, so that a first initialization signal from the first initialization signal terminal is transmitted to a first sub-node of first node and a second sub-node of first node respectively,
wherein the first time period and the second time period are in a reset stage of an image frame, the first time period is before the second time period, the second time period is between the first time period and the third time period, and the first time period, the second time period and the third time period do not overlap with each other, or
in a first sub-stage of first time period, turning on a first initialization sub-circuit and a first compensation sub-circuit in response to a first reset signal and the second scanning signal, so that a first initialization signal from a first initialization signal terminal is output to the first sub-node of first node; in a second sub-stage of first time period, turning on a third initialization sub-circuit and a second compensation sub-circuit in response to the first reset signal and the third scanning signal, so that the first initialization signal from the first initialization signal terminal is output to the second sub-node of first node, wherein the first sub-stage of first time period and the second sub-stage of first time period are in a reset stage of an image frame, the first sub-stage of first time period is before the second sub-stage of first time period, and the first sub-stage of first time period does not overlap with the second sub-stage of first time period.

19. (canceled)

20. A display substrate, comprising:
a base substrate;
the pixel circuit according to claim 1 on the base substrate, wherein the pixel circuit comprises a first sub-pixel driving circuit and a second sub-pixel driving circuit; and
a light emitting element on the base substrate, wherein the light emitting element comprises a first light emitting sub-element coupled to the first sub-pixel driving circuit and a second light emitting sub-element coupled to the second sub-pixel driving circuit.

21. A display substrate, comprising:
a base substrate;
a plurality of sub-pixels on the base substrate, wherein the plurality of sub-pixels are arranged in an array in a first direction and a second direction on the base substrate; and
a plurality of pixel circuits configured to drive the plurality of sub-pixels,
wherein the plurality of sub-pixels comprise a first sub-pixel and a second sub-pixel, and the first sub-pixel is adjacent to the second sub-pixel in the first direction or the second direction, the plurality of pixel circuits comprise a first sub-pixel driving circuit configured to drive the first sub-pixel and a second sub-pixel driving circuit configured to drive the second sub-pixel, and the first direction intersects with the second direction;
wherein the display substrate comprises a first semiconductor layer on the base substrate, a first conductive layer on a side of the first semiconductor layer away from the base substrate, a third conductive layer on a side of the first conductive layer away from the base substrate, and a fourth conductive layer on a side of the third conductive layer away from the base substrate; the display substrate further comprises a first scanning signal line extending in the first direction and a data signal line extending in the second direction, the first scanning signal line is located in the first conductive layer, and the data signal line is located in the fourth conductive layer;
wherein the first sub-pixel driving circuit and the second sub-pixel driving circuit share a data writing sub-circuit and a data signal line, the data writing sub-circuit comprises a data writing transistor, the data writing transistor comprises a data writing active layer, a control electrode and a second electrode, the data writing active layer is located in the first semiconductor layer, and the second electrode is located in the third conductive layer; and
wherein an orthographic projection of the data writing active layer on the base substrate overlaps at least partially with an orthographic projection of the first scanning signal line on the base substrate, a portion of the data writing active layer overlapping with the first scanning signal line is the control electrode of the data writing transistor, and the second electrode of the data writing transistor is electrically connected to the data signal line through a first via hole.

22. The display substrate according to claim 21, wherein the first sub-pixel driving circuit and the second sub-pixel driving circuit share a first light-emission control sub-circuit, the first light-emission control sub-circuit comprises a light-emission control transistor, the light-emission control transistor comprises a light-emission control active layer, a control electrode and a first electrode, the light-emission control active layer is located in the first semiconductor layer, and the first electrode of the light-emission control transistor is located in the third conductive layer;
wherein the display substrate further comprises a light-emission control line extending in the first direction, an orthographic projection of the light-emission control active layer on the base substrate overlaps at least partially with an orthographic projection of the light-emission control line on the base substrate, and a portion of the light-emission control active layer overlapping with the light-emission control line is the control electrode of the light-emission control transistor; and
wherein the display substrate further comprises a first conductive transfer portion in the third conductive layer, the first electrode of the light-emission control transistor is electrically connected to a first power line through the first conductive transfer portion,
wherein the first power line comprises a first power sub-line and a second power sub-line, the first power sub-line and the second power sub-line are spaced apart in the first direction and extend in the second direction, and the first conductive transfer portion is electrically connected to the first power sub-line through a second via hole and electrically connected to the second power sub-line through a third via hole,
wherein the data writing active layer and the light-emission control active layer extend continuously in the second direction;
wherein each of an orthographic projection of the data writing active layer on the base substrate and an orthographic projection of the first light-emission control active layer on the base substrate overlaps at least partially with an orthographic projection of the data signal line on the base substrate; and
wherein the orthographic projection of the data signal line on the base substrate falls within a gap between an orthographic projection of the first power sub-line on the base substrate and an orthographic projection of the second power sub-line on the base substrate,
wherein the first conductive transfer portion comprises a first conductive transfer sub-portion extending in the second direction and a second conductive transfer sub-portion extending in the first direction,
an orthographic projection of the first conductive transfer sub-portion on the base substrate overlaps at least partially with the orthographic projection of the light-emission control active layer on the base substrate,
an orthographic projection of the second via hole on the base substrate falls within an orthographic projection of a first end of the second conductive transfer sub-portion on the base substrate, and an orthographic projection of the third via hole on the base substrate falls within an orthographic projection of a second end of the second conductive transfer sub-portion on the base substrate,
wherein the first sub-pixel driving circuit comprises a first driving sub-circuit, the first driving sub-circuit comprises a first driving transistor, and the first driving transistor comprises a first driving active layer; the second sub-pixel driving circuit comprises a second driving sub-circuit, the second driving sub-circuit comprises a second driving transistor, and the second driving transistor comprises a second driving active layer; and
wherein the first driving active layer and the second driving active layer extend in polygonal lines in the first direction respectively, and
the first driving active layer and the second driving active layer are symmetrical with respect to the data signal line,
wherein the display substrate further comprises a second conductive layer between the first conductive layer and the third conductive layer;
wherein the first sub-pixel driving circuit comprises a first storage sub-circuit, the first storage sub-circuit comprises a first capacitor, and the first capacitor comprises a first plate and a second plate; the second sub-pixel driving circuit comprises a second storage sub-circuit, the second storage sub-circuit comprises a second capacitor, and the second capacitor comprises a third plate and a fourth plate; and
wherein the first plate and the third plate are located in the first conductive layer and spaced apart in the first direction, and the second plate and the fourth plate are located in the second conductive layer and electrically connected to each other.

23. (canceled)

24. (canceled)

25. The display substrate according to claim 21, wherein the data writing active layer extends in the second direction, the light-emission control active layer extends in the second direction, and the data writing active layer is spaced apart from the light-emission control active layer in the first direction; and
wherein an orthographic projection of the data writing active layer on the base substrate falls within an orthographic projection of the second power sub-line on the base substrate, and an orthographic projection of the light-emission control active layer on the base substrate falls within an orthographic projection of the first power sub-line on the base substrate,
wherein the first sub-pixel driving circuit comprises a first driving sub-circuit, the first driving sub-circuit comprises a first driving transistor, and the first driving transistor comprises a first driving active layer; the second sub-pixel driving circuit comprises a second driving sub-circuit, the second driving sub-circuit comprises a second driving transistor, and the second driving transistor comprises a second driving active layer;
wherein the first driving active layer extends in a straight line in the first direction, the second driving active layer extends in a straight line in the first direction, and the first driving active layer is spaced apart from the second driving active layer in the second direction; and
wherein the light-emission control active layer, the first driving active layer and the second driving active layer are electrically connected to each other,
wherein the display substrate further comprises a second conductive layer between the first conductive layer and the third conductive layer;
wherein the first sub-pixel driving circuit comprises a first storage sub-circuit, the first storage sub-circuit comprises a first capacitor, and the first capacitor comprises a first plate and a second plate; the second sub-pixel driving circuit comprises a second storage sub-circuit, the second storage sub-circuit comprises a second capacitor, and the second capacitor comprises a third plate and a fourth plate; and
wherein the first plate and the third plate are located in the first conductive layer and spaced apart in the second direction and overlap at least partially with each other in the first direction, and the second plate and the fourth plate are located in the second conductive layer and electrically connected to each other,
wherein the first conductive transfer portion comprises a first conductive transfer sub-portion and a second conductive transfer sub-portion,
wherein a first end of the first conductive transfer sub-portion is electrically connected to the first power sub-line through a second via hole, a second end of the first conductive transfer sub-portion is electrically connected to the second plate through a sixth via hole, the second conductive transfer portion is electrically connected to the second power sub-line through a third via hole and electrically connected to the fourth plate through a seventh via hole,
wherein any two of an orthographic projection of the second conductive transfer sub-portion on the base substrate, an orthographic projection of the fourth plate on the base substrate and an orthographic projection of the second power sub-line on the base substrate overlap at least partially with each other.

26. (canceled)

27. (canceled)

28. (canceled)

29. (canceled)

30. (canceled)

31. A display substrate, comprising:
a base substrate;
a plurality of sub-pixels on the base substrate, wherein the plurality of sub-pixels are arranged in an array in a first direction and a second direction on the base substrate; and
a plurality of pixel circuits configured to drive the plurality of sub-pixels,
wherein the plurality of sub-pixels comprise a first sub-pixel and a second sub-pixel, and the first sub-pixel is adjacent to the second sub-pixel in the first direction or the second direction, the plurality of pixel circuits comprise a first sub-pixel driving circuit configured to drive the first sub-pixel and a second sub-pixel driving circuit configured to drive the second sub-pixel, and the first direction intersects with the second direction;
wherein the display substrate comprises a first semiconductor layer on the base substrate, a first conductive layer on a side of the first semiconductor layer away from the base substrate, a third conductive layer on a side of the first conductive layer away from the base substrate, and a fourth conductive layer on a side of the third conductive layer away from the base substrate;
wherein the display substrate further comprises a first reset signal line extending in the first direction, a light-emission control line extending in the first direction, a data signal line extending in the second direction and a first power line extending in the second direction, the first reset signal line and the light-emission control line are located in the first conductive layer, and the data signal line and the first power line are located in the fourth conductive layer;
wherein the first sub-pixel driving circuit and the second sub-pixel driving circuit share a first initialization sub-circuit and a first light-emission control sub-circuit,
wherein the first initialization sub-circuit comprises an initialization transistor, the initialization transistor comprises an initialization active layer extending in the second direction and a control electrode, an orthographic projection of the initialization active layer on the base substrate overlaps at least partially with an orthographic projection of the first reset signal line on the base substrate, and a portion of the initialization active layer overlapping with the first reset signal line is the control electrode of the initialization transistor; and
wherein the first light-emission control sub-circuit comprises a light-emission control transistor, the light-emission control transistor comprises a light-emission control active layer extending in the second direction and a first electrode, an orthographic projection of the light-emission active layer on the base substrate falls within an orthographic projection of the first power line on the base substrate, and the first electrode of the light-emission control transistor is electrically connected to the first power line through a first conductive transfer portion.

32. The display substrate according to claim 31, wherein the first sub-pixel driving circuit comprises a first data writing sub-circuit, the first data writing sub-circuit comprises a first data writing transistor, and the first data writing transistor comprises a first data writing active layer and a second electrode; the second sub-pixel driving circuit comprises a second data writing sub-circuit, the second data writing sub-circuit comprises a second data writing transistor, and the second data writing transistor comprises a second data writing active layer and a first electrode;
wherein the first data writing active layer comprises a body portion extending in the second direction, the second data writing active layer comprises a body portion extending in the second direction, and the first data writing active layer and the second data writing active layer share a lap portion extending in the first direction; and
wherein the second electrode of the first data writing transistor and the first electrode of the second data writing transistor are electrically connected to the data signal line through a fourth via hole,
wherein the first sub-pixel driving circuit comprises a first compensation sub-circuit, the first compensation sub-circuit comprises a first compensation transistor, and the first compensation transistor comprises a first compensation active layer;
wherein the second sub-pixel driving circuit comprises a second compensation sub-circuit, the second compensation sub-circuit comprises a second compensation transistor, and the second compensation transistor comprises a second compensation active layer; and
wherein the first compensation active layer and the second compensation active layer extend in the first direction, and the first compensation active layer and the second compensation active layer are spaced apart in the first direction and the second direction,
wherein the first sub-pixel driving circuit comprises a first storage sub-circuit, the first storage sub-circuit comprises a first capacitor, and the first capacitor comprises a first plate and a second plate; the second sub-pixel driving circuit comprises a second storage sub-circuit, the second storage sub-circuit comprises a second capacitor, and the second capacitor comprises a third plate and a fourth plate; and
wherein the first plate and the third plate are located in the first conductive layer and spaced apart in the second direction, and the second plate and the fourth plate are located in the second conductive layer and electrically connected to each other,
wherein the first conductive transfer portion is electrically connected to the first power line through a fifth via hole and electrically connected to the fourth plate through an eighth via hole; and
wherein the display substrate further comprises a third conductive transfer portion in the third conductive layer, the first compensation transistor comprises a second electrode, the second compensation transistor comprises a first electrode, and the second electrode of the first compensation transistor is electrically connected to the first electrode of the second compensation transistor through the third conductive transfer portion,
wherein the first sub-pixel driving circuit comprises a first driving sub-circuit, the first driving sub-circuit comprises a first driving transistor, and the first driving transistor comprises a first driving active layer; the second sub-pixel driving circuit comprises a second driving sub-circuit, the second driving sub-circuit comprises a second driving transistor, and the second driving transistor comprises a second driving active layer;
wherein the first driving active layer extends in a straight line in the first direction, the second driving active layer extends in a straight line in the first direction, and the first driving active layer and the second driving active layer are spaced apart in the second direction; and
wherein the light-emission control active layer, the first driving active layer and the second driving active layer are electrically connected to each other.

33. (canceled)

34. (canceled)

35. (canceled)

36. (canceled)

37. A display device, comprising the display substrate according to any one of claim 20.

38. A display device, comprising the display substrate according to claim 21.

39. A display device, comprising the display substrate according to claim 31.
